(19) United States
(12) Patent Application Publication
(10) Pub. No.: US 2026/0190616 A1
(43) Pub. Date: Jul. 2, 2026

(54) LIGHT-EMITTING DEVICE, DISPLAY APPARATUS INCLUDING THE LIGHT-EMITTING DEVICE, AND ELECTRONIC APPARATUS INCLUDING THE DISPLAY APPARATUS

(71) Applicant: Samsung Display Co., LTD., Yongin-si (KR)

(72) Inventors: Hyosup Shin, Yongin-si (KR); Minje Kim, Yongin-si (KR); Hyukgi Min, Yongin-si (KR); Seunghyun Lee, Yongin-si (KR); Jaeyong Lee, Yongin-si (KR); Minsoo Choi, Yongin-si (KR)

(21) Appl. No.: 19/395,105

(22) Filed: Nov. 20, 2025

(30) Foreign Application Priority Data
Dec. 31, 2024 (KR) 10-2024-0202486
Nov. 10, 2025 (KR) 10-2025-0168688

(51) Int. Cl. H10K 50/19; H10K 50/12; H10K 50/15; H10K 50/16; H10K 59/123; H10K 59/38; H10K 59/40; H10K 59/80; H10K 101/20

(52) U.S. Cl. CPC H10K 50/19; H10K 50/12; H10K 50/15; H10K 50/16; H10K 59/123; H10K 59/38; H10K 59/40; H10K 59/8793; H10K 2101/20

(57) ABSTRACT

Provided is a light-emitting device including a first electrode, a second electrode facing the first electrode, and an interlayer between the first electrode and the second electrode. The interlayer includes a first emission layer and a second emission layer that are sequentially stacked. The first emission layer and the second emission layer satisfy Condition 1:

$${GSP}_{1} < 10 mV / nm \leq {GSP}_{2} \qquad Condition 1$$

wherein, in Condition 1,
GSP₁ is a giant surface potential of the first emission layer, and
GSP₂ is a giant surface potential of the second emission layer.

This application claims priority to Korean Patent Application No. 10-2024-0202486, filed on Dec. 31, 2024, and Korean Patent Application No. 10-2025-0168688, filed on Nov. 10, 2025, and all the benefits accruing therefrom under 35 U.S.C. § 119, the content of which in its entirety is herein incorporated by reference.

### BACKGROUND

### 1. Field

One or more embodiments relate to a light-emitting device, a display apparatus including the light-emitting device, and an electronic apparatus including the display apparatus.

### 2. Description of the Related Art

Self-emissive devices (for example, organic light-emitting devices) among light-emitting devices have wide viewing angles, high contrast ratios, short response times, and excellent characteristics in terms of luminance, driving voltage, and response speed.

In an example, a light-emitting device may include a first electrode, a hole transport region, an emission layer, an electron transport region, and a second electrode that are sequentially arranged. Holes injected from the first electrode may move toward the emission layer through the hole transport region. Electrons injected from the second electrode may move toward the emission layer through the electron transport region. Carriers, such as these holes and electrons, recombine in the emission layer to produce excitons. As the excitons transition from an excited state to a ground state, light may be generated.

### SUMMARY

One or more embodiments include a light-emitting device having a long lifespan, a display apparatus having improved display quality by including the light-emitting device, and a high-quality electronic apparatus including the display apparatus.

Additional aspects will be set forth in part in the description which follows and, in part, will be apparent from the description, or may be learned by practice of the presented embodiments of the disclosure.

According to one or more embodiments, a light-emitting device includes a first electrode, a second electrode facing the first electrode, and an interlayer between the first electrode and the second electrode and including a first emission layer and a second emission layer that are sequentially stacked, wherein the first emission layer and the second emission layer satisfy Condition 1:

$${GSP}_{1} < 10 mV / nm \leq {GSP}_{2} \qquad Condition 1$$

wherein, in Condition 1,
GSP₁ is a giant surface potential of the first emission layer, and
GSP₂ is a giant surface potential of the second emission layer.

In an embodiment, the first emission layer may be arranged between the first electrode and the second emission layer, and the second emission layer may be arranged between the first emission layer and the second electrode.

In an embodiment, the first electrode may be an anode, and the second electrode may be a cathode.

In an embodiment, the first emission layer and the second emission layer may be in direct contact.

In an embodiment, the interlayer may include a first stack adjacent to the first electrode and a second stack adjacent to the second electrode, and at least one of the first stack or the second stack may include the first emission layer and the second emission layer that satisfy Condition 1.

In an embodiment, the interlayer may further include a hole transport region arranged between the first electrode and the first emission layer and an electron transport region arranged between the second emission layer and the second electrode.

In an embodiment, at least one of the first emission layer or the second emission layer may emit blue light.

In an embodiment, at least one of the first emission layer or the second emission layer may emit fluorescence or delayed fluorescence.

In an embodiment, in Condition 1, an absolute value of GSP₁ may be less than 10 mV/nm.

In an embodiment, at least one of the first emission layer or the second emission layer may include at least one type of dopant which contains boron.

In an embodiment, the first emission layer may include a first dopant containing boron, the second emission layer may include a second dopant containing boron, and the first dopant and the second dopant may be identical to or different from each other.

In an embodiment, at least one of the first emission layer or the second emission layer may include a host including a condensed group in which 3 to 5 benzene groups are condensed with each other.

In an embodiment, the first emission layer may include a first host including the condensed group, the second emission layer may include a second host including the condensed group, and the first host and the second host may be different from each other.

In an embodiment, the host may further include a carbazole group linked to the condensed group.

In an embodiment, the host may further include a C₃-C₂₀ cycloalkyl group that is linked to the condensed group and is unsubstituted or substituted with at least one R₁₀ₐ.

In an embodiment, the first emission layer and the second emission layer may satisfy Condition 1-1:

$$0 mV / nm \leq {GSP}_{1} < 10 mV / nm \leq {GSP}_{2} \qquad Condition 1 - 1$$

wherein, in Condition 1-1, GSP₁ and GSP₂ are each the same as those described in connection with Condition 1.

According to one or more embodiments, a display apparatus includes the light-emitting device including a first electrode, a second electrode facing the first electrode, and an interlayer arranged between the first electrode and the second electrode and including a first emission layer and a second emission layer that are sequentially stacked, and a thin-film transistor electrically linked to the first electrode, wherein the first emission layer and the second emission layer satisfy Condition 1:

$${GSP}_{1} < 10 mV / nm \leq {GSP}_{2} \qquad Condition 1$$

wherein, in Condition 1,
GSP₁ is a giant surface potential of the first emission layer, and
GSP₂ is a giant surface potential of the second emission layer.

In an embodiment, the display apparatus may further include a color filter, a color conversion layer, a touch screen layer, a polarizing layer, or a combination thereof.

According to one or more embodiments, an electronic apparatus includes the display apparatus and a processor which transmits a signal to the display apparatus.

In an embodiment, the electronic apparatus may be one of a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle gauge, a center information display (CID) in a vehicle, a head-up display for a vehicle, a room mirror display, a video wall including multiple displays tiled together, a theater or stadium screen, a phototherapy device, and a signboard.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating the movement of holes and electrons along with energy levels of an emission layer and adjacent layers thereof in a light-emitting device;

FIG. 2 is a diagram illustrating an emission zone together with the energy levels of FIG. 1;

FIG. 3 is a diagram illustrating an emission zone together with energy levels of emission layers and adjacent layers thereof when a light-emitting device includes two emission layers;

FIG. 4 is a diagram illustrating energy levels of each layer in a light-emitting device according to an embodiment and emission zones along with the movement of holes;

FIG. 5 is a diagram illustrating energy levels of each layer in a light-emitting device, which includes a single emission layer having a positive giant surface potential, and an emission zone along with the movement of holes and electrons;

FIG. 6 is a schematic cross-sectional view of a light-emitting device according to an embodiment;

FIG. 7 is a schematic cross-sectional view of a light-emitting device according to another embodiment;

FIG. 8 is a schematic view of a display apparatus including a light-emitting device according to an embodiment;

FIG. 9 is a schematic view of another display apparatus including a light-emitting device according to an embodiment;

FIG. 10 is a schematic perspective view of an electronic apparatus including a light-emitting device according to an embodiment;

FIG. 11 is a schematic diagram of the exterior of a vehicle as an electronic apparatus including a light-emitting device, according to an embodiment;

FIGS. 12A to 12C are each a diagram schematically illustrating the interior of the vehicle of FIG. 11;

FIG. 13 is a block diagram of an electronic apparatus including a display apparatus according to an embodiment; and

FIG. 14 is a schematic diagram of electronic apparatuses according to various embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, ±20%, ±10%, ±5% of the stated value, for example.

The term “substantially,” as used herein, means approximately or actually. The term “substantially equal” means approximately or actually equal. The term “substantially identical means approximately or actually identical. The term “substantially the same means approximately or actually the same. The term “substantially perpendicular means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise.

It is to be understood that if an element (e.g., a first element) is referred to, with or without the term “operatively” or “communicatively”, as “linked with”, “linked to”, “coupled with”, “coupled to”, “connected with”, or “connected to” another element (e.g., a second element), it means that the element may be coupled with the other element directly (e.g., wiredly), wirelessly, or via a third element.

When an organic material included in an emission layer arranged between two electrodes has a dipole and is therefore aligned in a certain direction, the electric field generated by the dipole may induce surface potential within the emission layer. In an example in which the emission layer is aligned in the direction that the dipole points to the two electrodes, the emission layer may be have a giant surface potential (GSP) characteristics. The GSP may be calculated from the variation in surface potential with the thickness of the emission layer using known methods such as linear fitting. The GSP may be determined by the structure of the organic material, the combination of organic materials, and the deposition conditions of the emission layer. While the surface potential of the emission layer may vary with its thickness, the GSP of the emission layer is minimally affected by thickness and may remain substantially constant. In a light-emitting device, when an emission layer is induced to be negatively charged in an anode direction and positively charged in a cathode direction, the GSP of the emission layer may be positive. In some aspects, in a light-emitting device, when an emission layer is induced to be positively charged in an anode direction and negatively charged in a cathode direction, the GSP of the emission layer may be negative. A negatively charged portion may have a relatively increased energy level due to electron repulsion, whereas a positively charged portion may have a relatively decreased energy level.

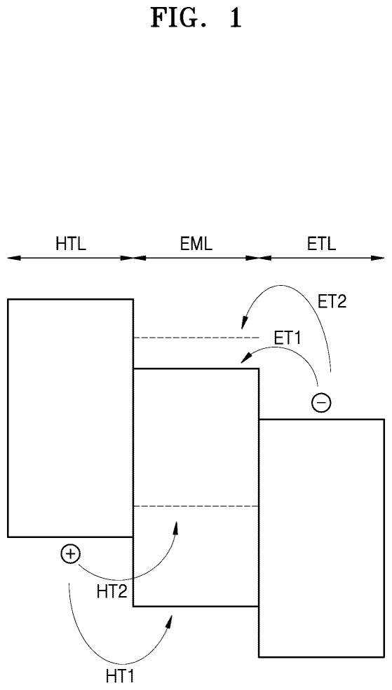

FIG. 1 is a diagram illustrating the movement of holes and electrons along with energy levels of an emission layer and adjacent layers thereof in a light-emitting device. In an example embodiment, a layer adjacent to an emission layer EML in an anode direction relative to the emission layer EML is a hole transport layer HTL, and a layer adjacent to the emission layer EML in a cathode direction relative to the emission layer EML is an electron transport layer ETL. The hole transport layer HTL is a non-limiting example of a layer adjacent to the emission layer EML in a hole transport region, and an electron-blocking layer may be further arranged between the hole transport layer HTL and the emission layer EML. The electron transport layer ETL is a non-limiting example of a layer adjacent to the emission layer EML in an electron transport region, and a hole-blocking layer may be further arranged between the electron transport layer ETL and the emission layer EML.

Referring to FIG. 1, holes may move from the hole transport layer HTL to the emission layer EML, and electrons may move from the electron transport layer ETL to the emission layer EML. The holes and the electrons may recombine in the emission layer EML to produce excitons, and the excitons may transition from an excited state to a ground state, thereby generating light in the emission layer EML.

The holes may be transported to a highest occupied molecular orbital (hereinafter referred to as HOMO) of a host in the emission layer EML along a first hole transport pathway HT1, or to HOMO of a dopant in the emission layer EML along a second hole transport pathway HT2.

The electrons may be transported to a lowest unoccupied molecular orbital (hereinafter referred to as LUMO) of a host in the emission layer EML along a first electron transport pathway ET1, or to LUMO of a dopant in the emission layer EML along a second electron transport pathway ET2.

For example, a blue fluorescent dopant tends to get decomposed by electrons, and thus it may be necessary to induce electrons to travel along the electron transport pathway ET1. Therefore, the blue fluorescent dopant may be selected from materials having a shallow LUMO energy level.

In some cases, the dopant may need to maintain its maximum emission wavelength as blue fluorescence, such that the HOMO energy level of the blue fluorescent dopant may also become shallow. Accordingly, in a blue fluorescent device, holes are induced to travel along the second hole transport pathway HT2 rather than the first hole transport pathway HT1, such that the holes tend to be trapped within the emission layer EML.

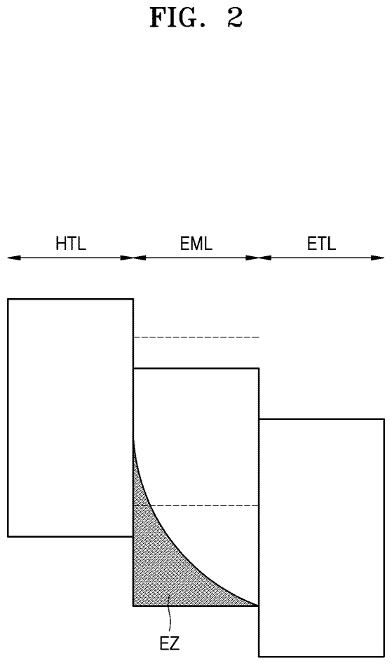

FIG. 2 is a diagram illustrating an emission zone together with the energy levels of FIG. 1.

Referring to FIGS. 1 and 2, as strong hole trapping is induced within the emission layer EML, an emission zone EZ may be narrowed such that most of the emission zone EZ is located adjacent to the interface between the hole transport layer HTL and the emission layer EML. As the emission zone EZ is narrowed, a concentration of triplet excitons increases, thereby accelerating triplet-polaron quenching (TPQ) or triplet-triplet annihilation (TTA). This can cause degradation, which reduces the lifespan of a blue fluorescent light-emitting device.

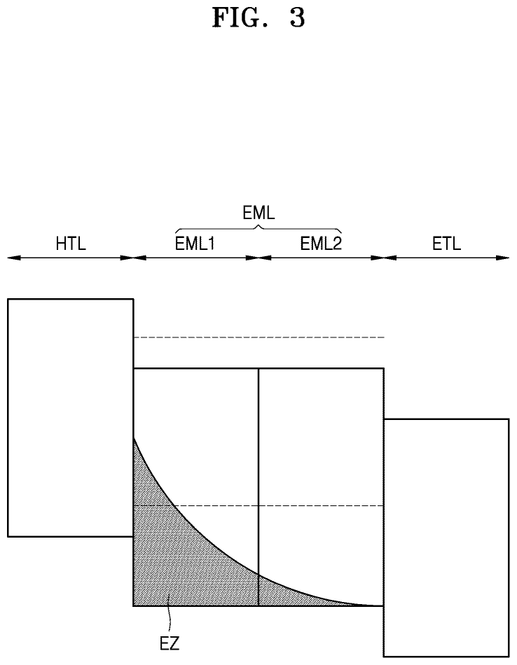

FIG. 3 is a diagram illustrating an emission zone EZ together with energy levels of emission layers and adjacent layers thereof when a light-emitting device includes two emission layers.

Referring to FIG. 3, the emission layer EML includes a first emission layer EML1 adjacent to the HTL, and a second emission layer EML2 adjacent to the electron transport layer ETL. Even if the second emission layer EML2 using the same material as the first emission layer EML1 is applied in a blue fluorescent light-emitting device, most of emission zones EZ may be located at the interface between the hole transport layer HTL and the first emission layer EML1 due to strong hole trapping at the interface between the hole transport layer HTL and the emission layer EML, resulting in a narrow emission zone EZ.

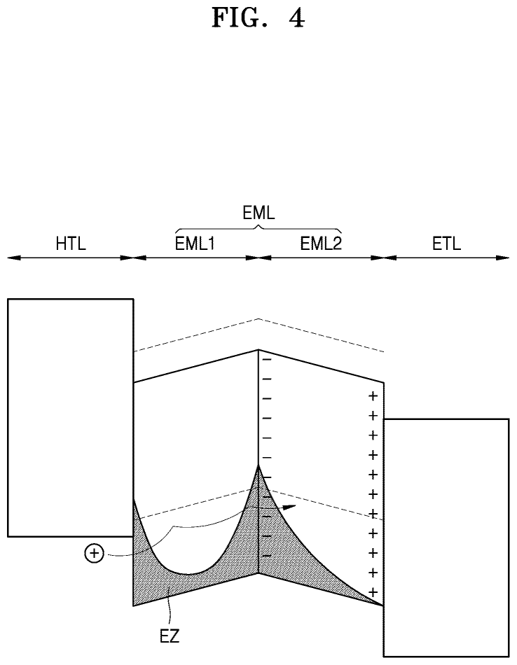

FIG. 4 is a diagram illustrating energy levels of each layer in a light-emitting device according to an embodiment and emission zones EZ along with the movement of holes.

Referring to FIG. 4, the second emission layer EML2 has a positive GSP such that a negative charge may be induced in an anode direction and a positive charge may be induced in a cathode direction. A negatively charged portion of the second emission layer EML2 and a portion of the first emission layer EML1 adjacent thereto may have a relatively increased energy level, and a positively charged portion of the second emission layer EML2 and a portion of the first emission layer EML1 that is relatively distant from the second emission layer EML2 may have a relatively decreased energy level.

Accordingly, holes moved from the hole transport layer HTL to the emission layer EML may move relatively far away from the interface between the hole transport layer HTL and the emission layer EML. Therefore, even if hole trapping is induced at the interface between the hole transport layer HTL and the first emission layer EML1 and/or the interface between the first emission layer EML1 and the second emission layer EML2 due to a shallow HOMO energy level of a blue fluorescent dopant, the emission zone EZ within the emission layer EML may be relatively wide. The implementation of such a wide emission zone EZ may reduce a concentration of triplet excitons, and as a result of reducing degradation of triplet excitons, a blue fluorescent light-emitting device may have an improved lifespan.

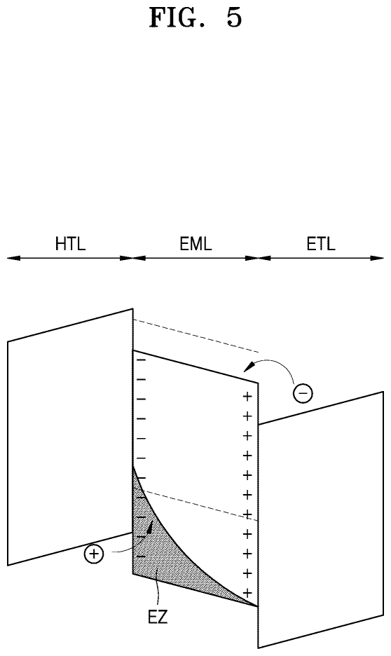

FIG. 5 is a diagram illustrating energy levels of each layer in a light-emitting device, which includes a single emission layer having a positive GSP, and an emission zone EZ along with the movement of holes and electrons.

Referring to FIG. 5, a single emission layer EML has a positive GSP such that a negative charge may be induced in an anode direction and a positive charge may be induced in a cathode direction. A negatively charged portion of the emission layer EML and a portion of the hole transport layer HTL adjacent thereto may have a relatively increased energy level, and a positively charged portion of the emission layer EML and a portion of the electron transport layer ETL adjacent thereto may have a relatively decreased energy level.

As the HOMO energy level of a dopant becomes deeper towards the interface between the emission layer EML and the electron transport layer ETL, it may be more difficult for the holes trapped at the interface between the hole transport layer HTL and the emission layer EML to move towards the interface between the emission layer EML and the electron transport layer ETL. Therefore, even if a single emission layer EML with a positive GSP is applied, the emission zone EZ may be narrow.

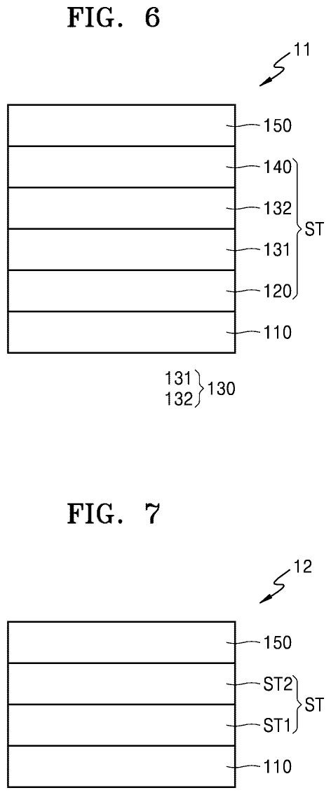

FIG. 6 is a schematic cross-sectional view of a light-emitting device according to an embodiment.

Referring to FIG. 6, a light-emitting device 11 includes: a first electrode 110; a second electrode 150 facing the first electrode 110; and an interlayer between the first electrode 110 and the second electrode 150 and including a first emission layer 131 and a second emission layer 132 that are sequentially stacked. The term “interlayer” as used herein refers to a single layer and/or a plurality of layers arranged between the first electrode 110 and the second electrode 150 of the light-emitting device 11. The interlayer may further include a hole transport region arranged between the first electrode 110 and the first emission layer 131. The interlayer may further include an electron transport region 140 arranged between the second emission layer 132 and the second electrode 150.

The hole transport region 120, the first emission layer 131, the second emission layer 132, and the electron transport region 140 may be collectively referred to as a stack ST. In an example in which the interlayer includes a plurality of stacks ST, the light-emitting device 11 may be a tandem light-emitting device. A plurality of stacks ST may be referred to as a first stack, a second stack, and the like, and a tandem light-emitting device may further include charge generation layers (CGLs) arranged between the plurality of STs. Although one stack ST is illustrated in FIG. 6, a tandem light-emitting device will be described with reference to FIG. 7.

FIG. 7 is a schematic cross-sectional view of a light-emitting device according to another embodiment.

Referring to FIG. 7, a light-emitting device 12 includes: a first electrode 110; a second electrode 150 facing the first electrode 110; and an interlayer between the first electrode 110 and the second electrode 150. The interlayer may include a plurality of stacks ST. A plurality of stacks ST may include a first stack ST1 and a second stack ST2. An embodiment in which a plurality of stacks ST include two stacks ST is illustrated, but the plurality of stacks ST may include three stacks ST, four stacks ST, five stacks ST, or six or more stacks ST. The interlayer may further include a charge generation layer arranged between the first stack ST1 and the second stack ST2. Each of the first stack ST1 and the second stack ST2 may sequentially include a hole transport region, an emission layer, and an electron transport region from the direction adjacent to the first electrode 110. In an embodiment, the first stack ST1 may be substantially identical to the stack ST described with reference to FIG. 6. That is, the first stack ST1 may have a two-layer emission layer structure. In one or more embodiments, the second stack ST2 may be substantially identical to the stack ST described by referring to FIG. 6. That is, the second stack ST2 may have a two-layer emission layer structure. In one or more embodiments, each of the first stack ST1 and the second stack ST2 may be substantially identical to the stack ST described with reference to FIG. 6. That is, each of the first stack ST1 and the second stack ST2 may have a two-layer emission layer structure. A more detailed description of FIG. 6 will be provided below.

An aspect provides a light-emitting device including: a first electrode; a second electrode facing the first electrode; and an interlayer between the first electrode and the second electrode and including a first emission layer and a second emission layer that are sequentially stacked, wherein the first emission layer and the second emission layer satisfy Condition 1:

$${GSP}_{1} < 10 mV / nm \leq {GSP}_{2} \qquad Condition 1$$

wherein, in Condition 1,
GSP₁ is a giant surface potential of the first emission layer, and
GSP₂ is a giant surface potential of the second emission layer.

As long as the light-emitting device according to an embodiment satisfies Condition 1, materials for forming the first emission layer and the second emission layer are not particularly limited.

Condition 1 may include Conditions 1A and 1B:

$${GSP}_{1} < 10 mV / nm \qquad Condition 1 A$$

### Condition 1B

10 mV/nm s GSP₂.

In Condition 1A, GSP₁ is a giant surface potential of the first emission layer, and

In Condition 1B, GSP₂ is a giant surface potential of the second emission layer.

Not only does the second emission layer have a positive GSP, but it also satisfies Condition 1B, such that an emission zone may be effectively widened and the lifespan of the light-emitting device may be effectively improved.

By having the first emission layer satisfying Condition 1A, an emission zone may be effectively widened and the lifespan of the light-emitting device may be effectively improved as described with reference to FIGS. 4 and 5.

Therefore, since the light-emitting device according to an embodiment satisfies both Conditions 1A and 1B, it may have an effectively improved lifespan.

In an embodiment, the first emission layer may be adjacent to the first electrode, and the second emission layer may be adjacent to the second electrode. The first emission layer may be arranged between the first electrode and the second emission layer, and the second emission layer may be arranged between the first emission layer and the second electrode. The first electrode may be an anode, and the second electrode may be a cathode.

In an embodiment, the first emission layer and the second emission layer may be in direct contact with each other. That is, in an embodiment where the light-emitting device is a tandem light-emitting device, the first emission layer is an emission layer located in a first stack, and the second emission layer is an emission layer located in a second stack, not the first stack.

In an embodiment, the interlayer may include a first stack adjacent to the first electrode and a second stack adjacent to the second electrode, and at least one of the first stack or the second stack may include the first emission layer and the second emission layer that satisfy Condition 1. In an embodiment, the first stack may include both the first emission layer and the second emission layer. In one or more embodiments, the second stack may include both the first emission layer and the second emission layer. In one or more embodiments, the first stack may include an emission layer 1a and an emission layer 2a sequentially stacked from the first electrode, and the second stack may include an emission layer 1b and an emission layer 2b sequentially stacked from the first electrode, wherein the emission layer 1a and the emission layer 2a may satisfy Condition 1-a, and the emission layer 1b and the emission layer 2b may satisfy Condition 1-b:

$${GSP}_{1 a} < 10 mV / nm \leq {GSP}_{2 a} \qquad Condition 1 - a$$

$${GSP}_{1 b} < 10 mV / nm \leq {GSP}_{2 b} . \qquad Condition 1 - b$$

In Condition 1-a,
GSP₁ₐ is a giant surface potential of the emission layer 1a included in the first stack, and

GSP₂ₐ is a giant surface potential of the emission layer 2a included in the first stack, and
in Condition 1-b,
GSP_{1b} is a giant surface potential of the emission layer 1b included in the second stack, and
GSP_{2b} is a giant surface potential of the emission layer 2b included in the second stack.

In an embodiment, the interlayer may further include at least one of a hole transport region arranged between the first electrode and the first emission layer and an electron transport region arranged between the second emission layer and the second electrode. The hole transport region may include a hole injection layer, a hole transport layer, an emission auxiliary layer, an electron blocking layer, or any combination thereof. the electron transport region may include a hole blocking layer, an electron transport layer, an electron injection layer, or any combination thereof. For example, the first emission layer may be in direct contact with the hole transport layer or the electron blocking layer in the hole transport region, and the second emission layer may be in direct contact with the electron transport layer or the hole blocking layer in the electron transport region.

In an embodiment, at least one of the first emission layer or the second emission layer may emit blue light. For example, each of the first emission layer and the second emission layer may emit blue light.

In an embodiment, at least one of the first emission layer or the second emission layer may emit fluorescence or delayed fluorescence. For example, each of the first emission layer and the second emission layer may emit fluorescence or delayed fluorescence. Each of the first emission layer and the second emission layer may emit fluorescence.

In an embodiment, the GSP of the second emission layer (i.e., GSP₂ in Condition 1) may be in a range of about 10 mV/nm to about 100 mV/nm. For example, the GSP₂ in Condition 1 may be in a range of about 11 mV/nm to about 90 mV/nm, about 12 mV/nm to about 80 mV/nm, about 13 mV/nm to about 70 mV/nm, about 14 mV/nm to about 60 mV/nm, about 15 mV/nm to about 50 mV/nm, about 16 mV/nm to about 45 mV/nm, about 17 mV/nm to about 40 mV/nm, or about 18 mV/nm to about 35 mV/nm.

In an embodiment, an absolute value of the GSP per thickness of the first emission layer (i.e., GSP₁ in Condition 1) may be less than 10 mV/nm. For example, the GSP₁ in Condition 1 may be in a range of about −9.5 mV/nm to about 9.5 mV/nm, about −9 mV/nm to about 9 mV/nm, about −8.5 mV/nm to about 8.5 mV/nm, about −8 mV/nm to about 8 mV/nm, about −7.5 mV/nm to about 7.5 mV/nm, about −7 mV/nm to about 7 mV/nm, about −6.5 mV/nm to about 6.5 mV/nm, about −6 mV/nm to about 6 mV/nm, about −5.5 mV/nm to about 5.5 mV/nm, about −5 mV/nm to about 5 mV/nm, about −4.5 mV/nm to about 4.5 mV/nm, about −4 mV/nm to about 4 mV/nm, about −3.5 mV/nm to about 3.5 mV/nm, about −3 mV/nm to about 3 mV/nm, about −2.5 mV/nm to about 2.5 mV/nm, about −2 mV/nm to about 2 mV/nm, about −1.5 mV/nm to about 1.5 mV/nm, or about −1 mV/nm to about 1 mV/nm.

The first emission layer may have a GSP of 0 or greater. For example, both the first emission layer and the second emission layer may satisfy Condition 1-1:

$$0 mV / nm \leq {GSP}_{1} < 10 mV / nm \leq {GSP}_{2} \qquad Condition 1 - 1$$

wherein, in Condition 1-1, GSP1 and GSP2 are each the same as those described in connection with Condition 1.

In an embodiment, the GSP₁ in Condition 1-1 may be in a range of about 0.5 mV/nm to about 9.5 mV/nm, about 0.5 mV/nm to about 9 mV/nm, about 0.5 mV/nm to about 8.5 mV/nm, about 0.5 mV/nm to about 8 mV/nm, about 0.5 mV/nm to about 7.5 mV/nm, about 0.5 mV/nm to about 7 mV/nm, about 0.5 mV/nm to about 6.5 mV/nm, about 0.5 mV/nm to about 6 mV/nm, about 0.5 mV/nm to about 5.5 mV/nm, about 0.5 mV/nm to about 5 mV/nm, about 0.5 mV/nm to about 4.5 mV/nm, about 0.5 mV/nm to about 4 mV/nm, about 0.5 mV/nm to about 3.5 mV/nm, about 0.5 mV/nm to about 3 mV/nm, about 0.5 mV/nm to about 2.5 mV/nm, about 0.5 mV/nm to about 2 mV/nm, about 0.5 mV/nm to about 1.5 mV/nm, about 0.5 mV/nm to about 1 mV/nm, about 1 mV/nm to about 9.5 mV/nm, about 1 mV/nm to about 9 mV/nm, about 1 mV/nm to about 8.5 mV/nm, about 1 mV/nm to about 8 mV/nm, about 1 mV/nm to about 7.5 mV/nm, about 1 mV/nm to about 7 mV/nm, about 1 mV/nm to about 6.5 mV/nm, about 1 mV/nm to about 6 mV/nm, about 1 mV/nm to about 5.5 mV/nm, about 1 mV/nm to about 5 mV/nm, about 1 mV/nm to about 4.5 mV/nm, about 1 mV/nm to about 4 mV/nm, about 1 mV/nm to about 3.5 mV/nm, about 1 mV/nm to about 3 mV/nm, about 1 mV/nm to about 2.5 mV/nm, about 1 mV/nm to about 2 mV/nm, or about 1 mV/nm to about 1.5 mV/nm.

In an embodiment, at least one of the first emission layer or the second emission layer may include at least one type of dopant containing boron. For example, each of the first emission layer and the second emission layer may include at least one type of dopants containing boron. The first emission layer may include a first dopant containing boron. The second emission layer may include a second dopant containing boron. The first dopant and the second dopant may be identical to or different from each other.

In an embodiment, the dopant containing boron may further include a heteroatom other than boron. For example, the dopant containing boron may further include O and/or N.

In an embodiment, at least one of the first emission layer or the second emission layer may include at least one type of dopants represented by Formula D1 or D2:

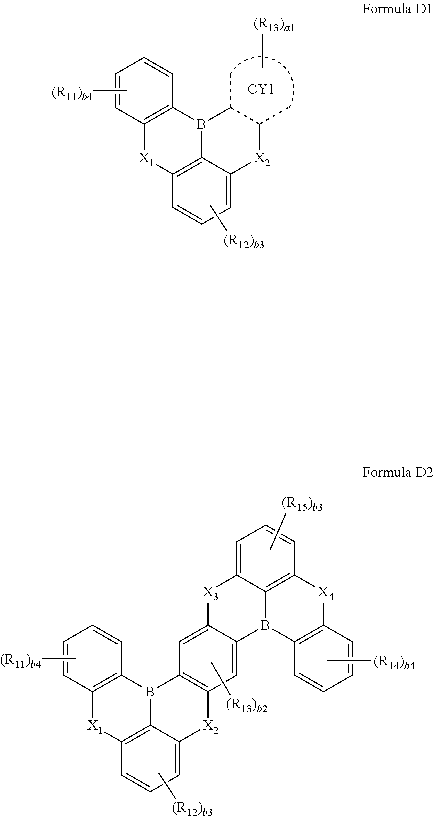

wherein, in Formulae D1 and D2,
X₁ may be O, S, Se, N(R₁), P(R₁), C(R₁)(R₂), or Si(R₁)(R₂),
X₂ may be O, S, Se, N(R₃), P(R₃), C(R₃)(R₄), or Si(R₃)(R₄),
X₃ may be O, S, Se, N(R₅), P(R₅), C(R₅)(R₆), or Si(R₅)(R₆),
X₄ may be O, S, Se, N(R₇), P(R₇), C(R₇)(R₈), or Si(R₇)(R₈),
CY₁ may be a C₃-C₃₀ carbocyclic group or a C₁-C₃₀ heterocyclic group,
a1 may be an integer from 0 to 20,
b2 may be 0, 1, or 2,
b3 may be 0, 1, 2, or 3,
b4 may be 0, 1, 2, 3, or 4,
R₁ to R₈ and R₁₁ to R₁₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

At least one of the first emission layer or the second emission layer may include one of Compounds BD1 to BD22 as the dopant:

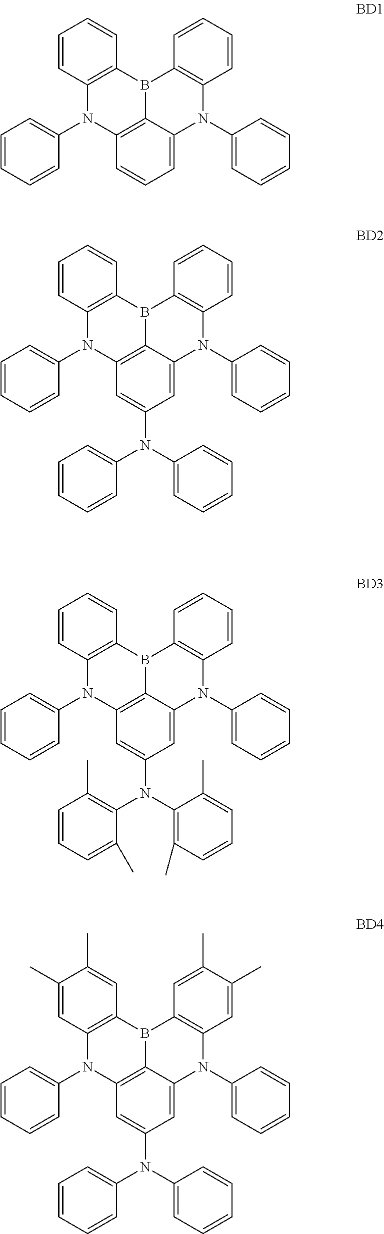 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

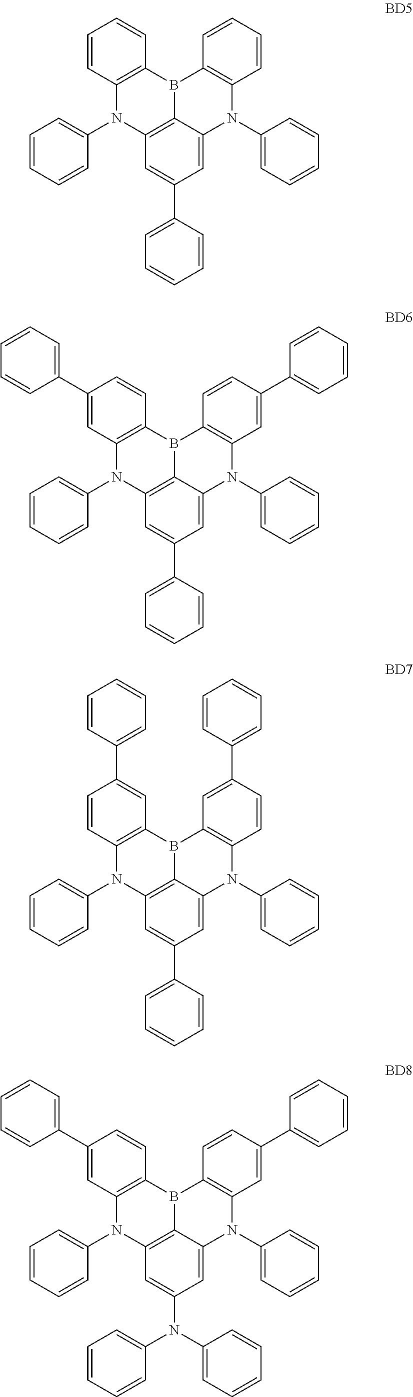 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1]

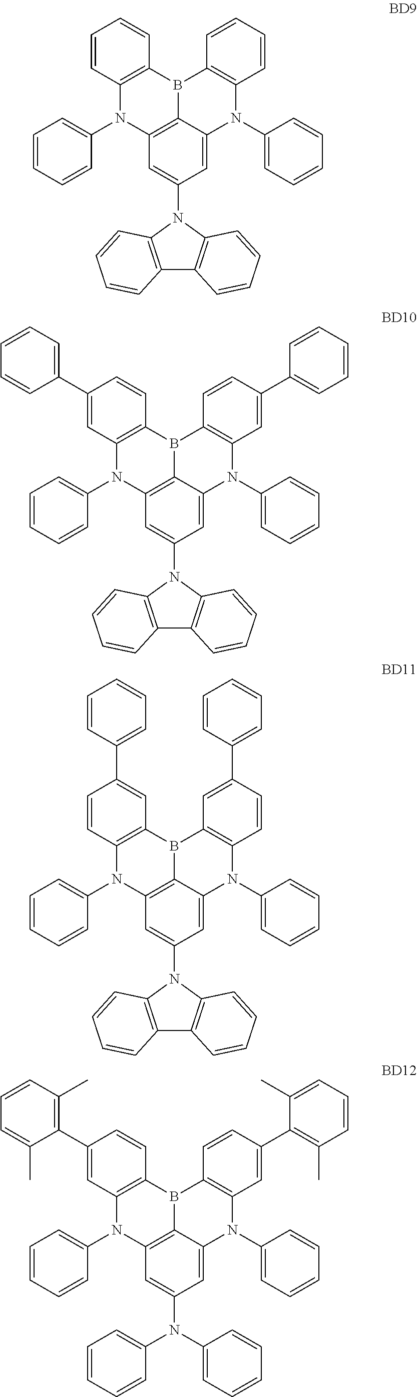

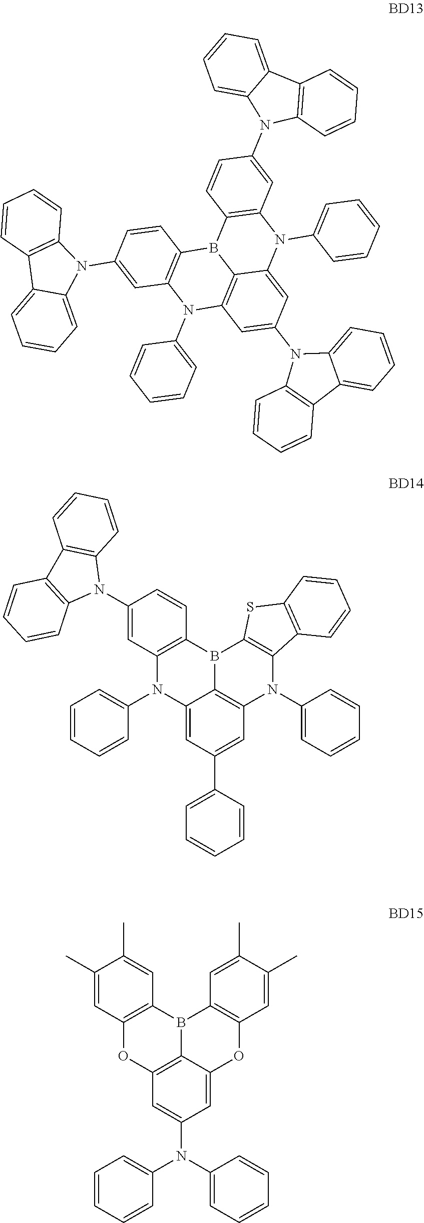

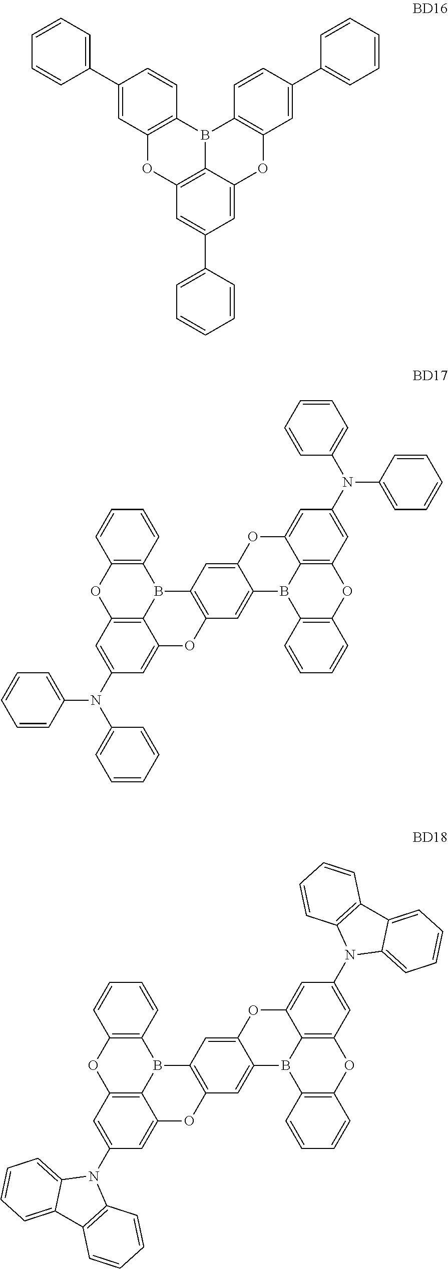 [SMILES: c1ccc(-c2ccc3c(c2)Oc2cc(-c4ccccc4)cc4c2B3c2ccc(-c3ccccc3)cc2O4)cc1 ; c1ccc(N(c2ccccc2)c2cc3c4c(c2)Oc2cc5c(cc2B4c2ccccc2O3)Oc2cc(N(c3ccccc3)c3ccccc3)cc3c2B5c2ccccc2O3)cc1 ; c1ccc2c(c1)Oc1cc(-n3c4ccccc4c4ccccc43)cc3c1B2c1cc2c(cc1O3)B1c3ccccc3Oc3cc(-n4c5ccccc5c5ccccc54)cc(c31)O2]

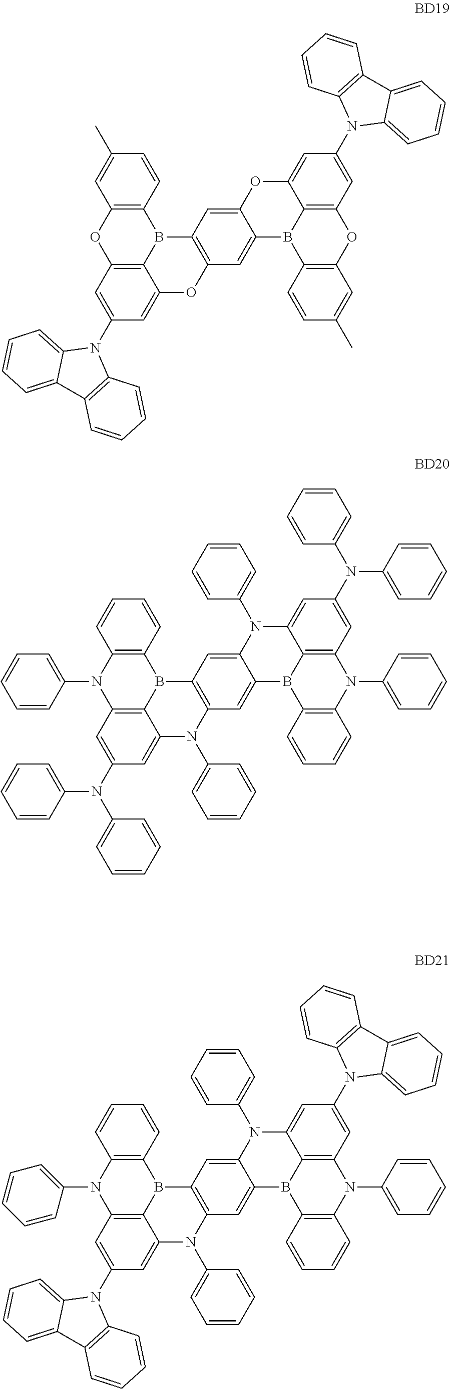 [SMILES: Cc1ccc2c(c1)Oc1cc(-n3c4ccccc4c4ccccc43)cc3c1B2c1cc2c(cc1O3)B1c3ccc(C)cc3Oc3cc(-n4c5ccccc5c5ccccc54)cc(c31)O2 ; c1ccc(N(c2ccccc2)c2cc3c4c(c2)N(c2ccccc2)c2cc5c(cc2B4c2ccccc2N3c2ccccc2)N(c2ccccc2)c2cc(N(c3ccccc3)c3ccccc3)cc3c2B5c2ccccc2N3c2ccccc2)cc1 ; c1ccc(N2c3ccccc3B3c4cc5c(cc4N(c4ccccc4)c4cc(-n6c7ccccc7c7ccccc76)cc2c43)B2c3ccccc3N(c3ccccc3)c3cc(-n4c6ccccc6c6ccccc64)cc(c32)N5c2ccccc2)cc1]

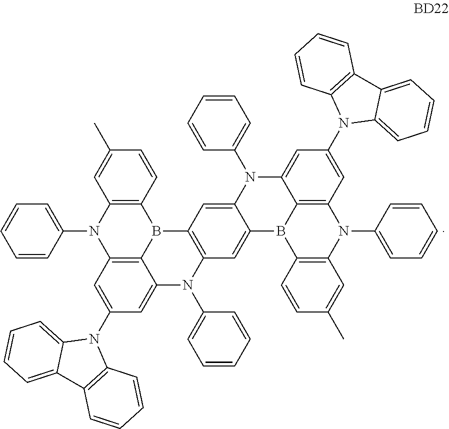 [SMILES: Cc1ccc2c(c1)N(c1ccccc1)c1cc(-n3c4ccccc4c4ccccc43)cc3c1B2c1cc2c(cc1N3c1ccccc1)B1c3ccc(C)cc3N(c3ccccc3)c3cc(-n4c5ccccc5c5ccccc54)cc(c31)N2c1ccccc1]

In an embodiment, at least one of the first emission layer or the second emission layer may include a host including a condensed group in which 3 to 5 benzene groups are condensed with each other. For example, each of the first emission layer and the second emission layer may include the host including a condensed group. The first emission layer may include a first host including a condensed group in which 3 to 5 benzene groups are condensed with each other. The second emission layer may include a second host including a condensed group in which 3 to 5 benzene groups are condensed with each other. The first host and the second host may be identical to or different from each other.

In an embodiment, the condensed group may be one selected from an anthracene group, a phenanthrene group, a phenalene group, a tetracene group, a tetraphene group, a benzoanthracene group, and a pyrene group.

In an embodiment, at least one of the first host or the second host may further include a carbazole group linked to the condensed group. The carbazole group may be a group represented by

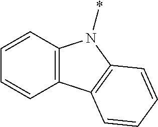 [SMILES: *n1c2ccccc2c2ccccc21]

(which may be unsubstituted or substituted with at least one R₁₀ₐ). For example, at least one of the first host or the second host may be a compound in which the carbazole group is linked to the condensed group via a nitrogen of the carbazole group. The term “linked” includes not only an embodiment in which nitrogen of the carbazole group is directly bonded to the condensed group, but also an embodiment in which a linker group is present between the carbazole group and the condensed group and nitrogen of the carbazole group is indirectly bonded to the condensed group via the linker group. For example, at least one of the first host or the second host may further include a linker group that links to the condensed group, in addition to the condensed group. Example, the linker group may be a C₃-C₆₀ carbocyclic group unsubstituted or substituted with at least one R₁₀ₐ, or a C₁-C₆₀ heterocyclic group unsubstituted or substituted with at least one R₁₀ₐ. The linker group may be a C₆-C₆₀ arylene group unsubstituted or substituted with at least one R₁₀ₐ, or a C₃-C₆₀ heteroarylene group unsubstituted or substituted with at least one R₁₀ₐ.

In an embodiment, the first host may not include a carbazole group unsubstituted or substituted with at least one R₁₀ₐ, and the second host may include a carbazole group unsubstituted or substituted with at least one R₁₀ₐ.

In an embodiment, at least one of the first host or the second host may further include a C₃-C₂₀ cycloalkyl group that is unsubstituted or substituted with at least one R₁₀ₐ and is linked to the condensed group. Each of the first host and the second host may include 1 to 10 C₃-C₂₀ cycloalkyl groups, each of which is unsubstituted or substituted with at least one R₁₀ₐ. For example, at least one of the first host or the second host may include a cyclopropyl group unsubstituted or substituted with at least one R₁₀ₐ, a cyclobutyl group unsubstituted or substituted with at least one R₁₀ₐ, a cyclopentyl group unsubstituted or substituted with at least one R₁₀ₐ, a cyclohexyl group unsubstituted or substituted with at least one R₁₀ₐ, a cycloheptyl group unsubstituted or substituted with at least one R₁₀ₐ, a cyclooctyl group unsubstituted or substituted with at least one R₁₀ₐ, or any combination thereof.

In an embodiment, the first host may not include a C₃-C₂₀ cycloalkyl group unsubstituted or substituted with at least one R₁₀ₐ, and the second host may include a C₃-C₂₀ cycloalkyl group unsubstituted or substituted with at least one R₁₀ₐ.

The C₃-C₂₀ cycloalkyl group may be linked to the carbazole group. For example, the C₃-C₂₀ cycloalkyl group may be directly bonded to the carbazole group. At least one of the first host or the second host may include a group represented by one of Formulae C1 to C14:

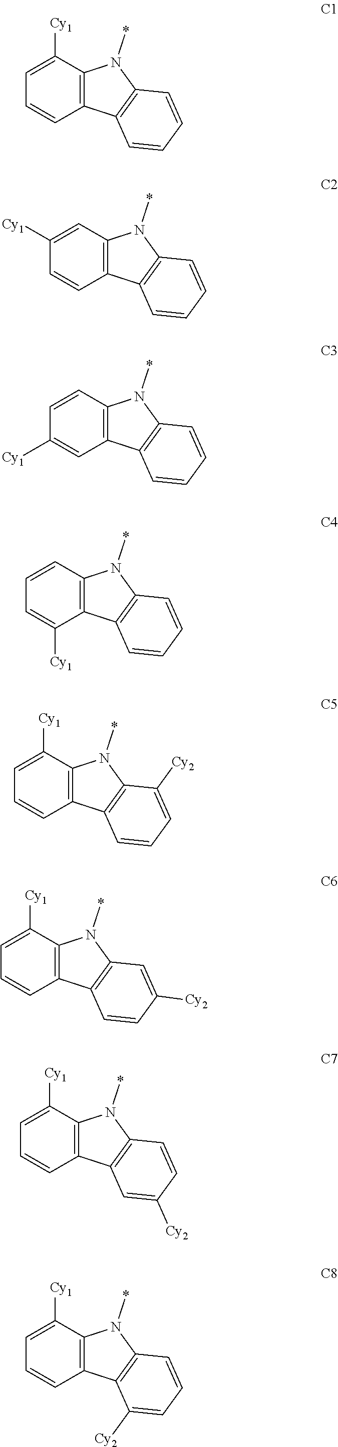

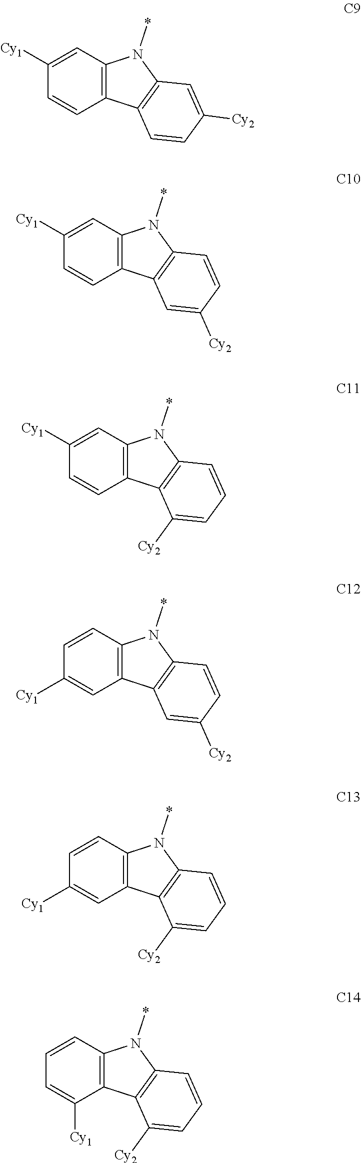

wherein, in Formulae C1 to C14,
each of Cy₁ and Cy₂ may be a C₃-C₂₀ cycloalkyl group unsubstituted or substituted with at least one R₁₀ₐ,
* indicates a binding site to the condensed group, and
at least one hydrogen may be substituted with any one of R₁₀ₐ described herein except a C₃-C₂₀ cycloalkyl group.

Each of the first host and the second host may be one of Compounds BH11 to BH14 and BH21 to BH32:

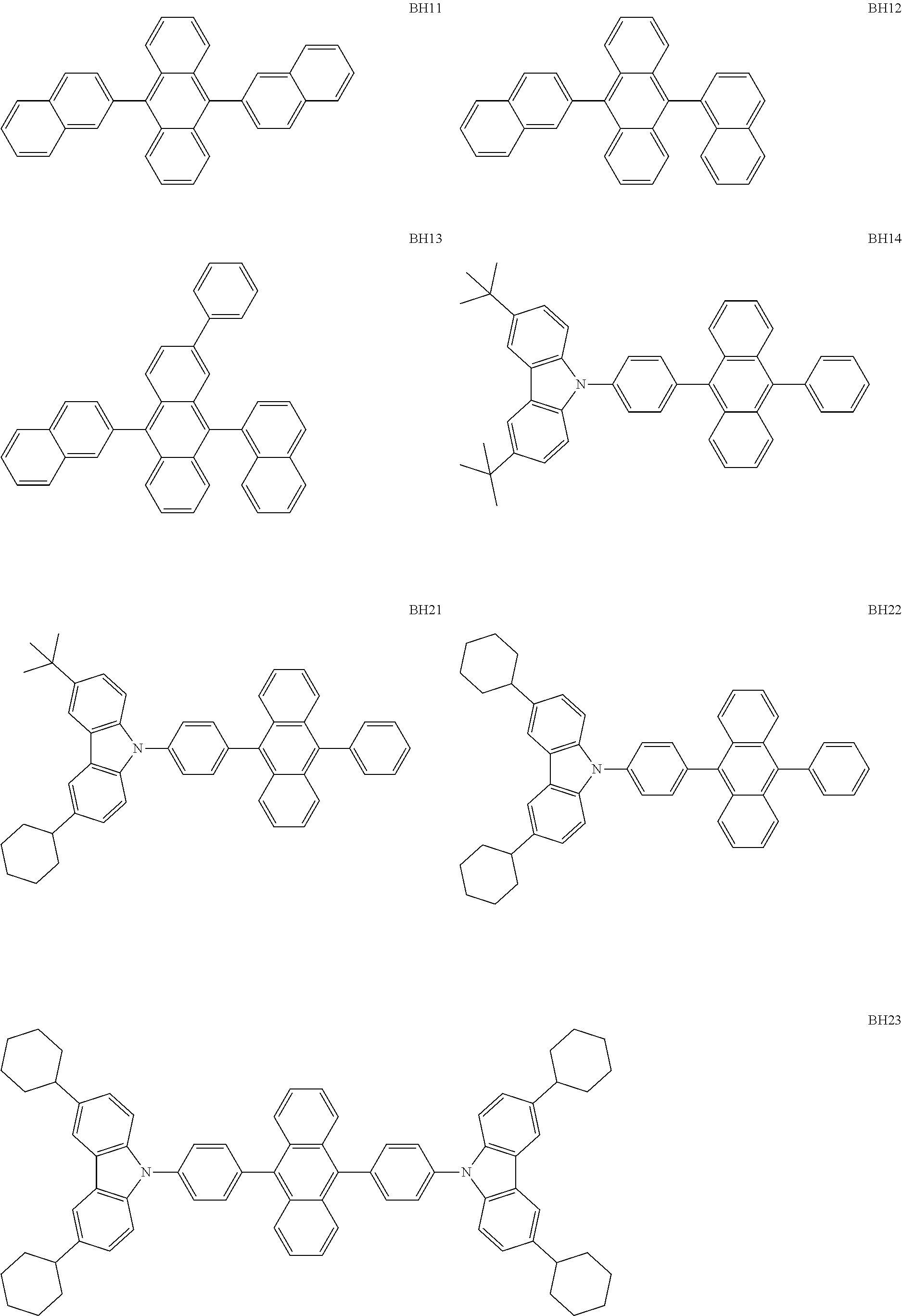

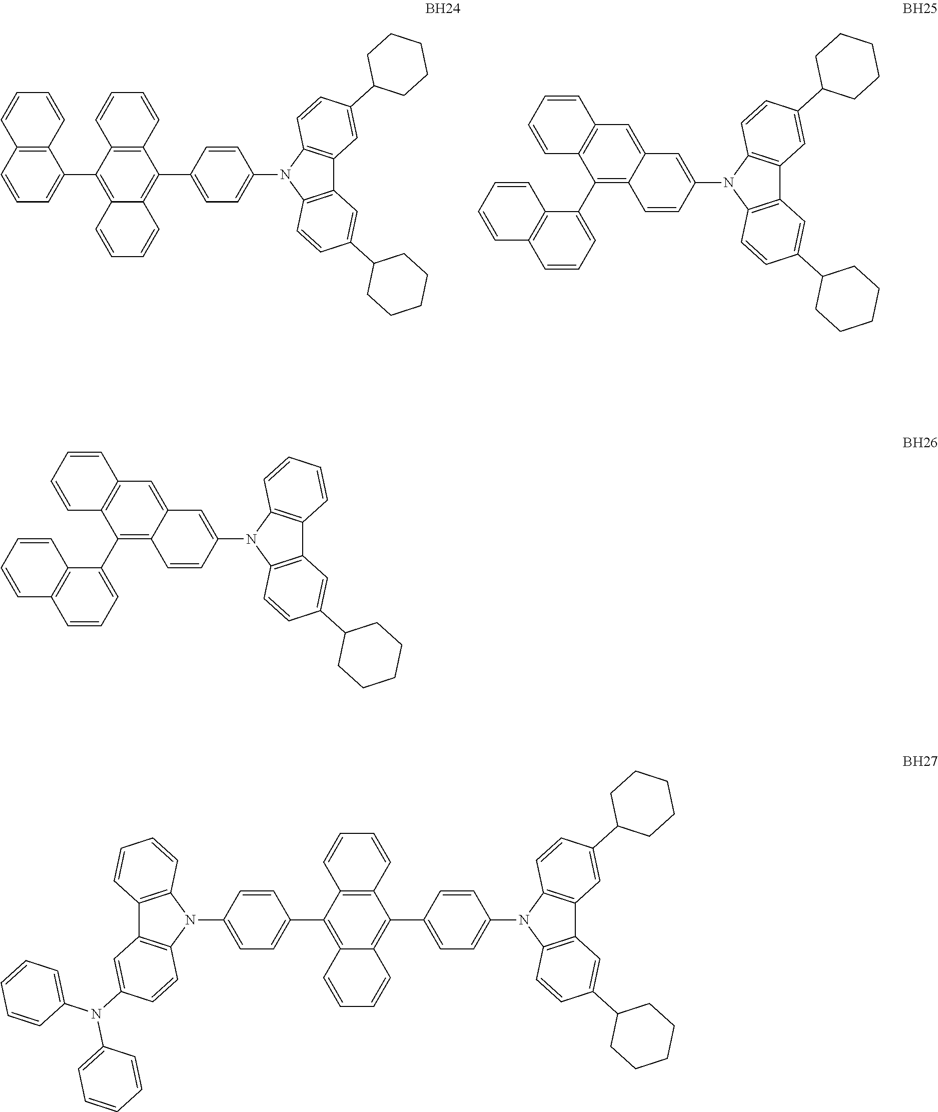 [SMILES: c1ccc2c(-c3c4ccccc4c(-c4ccc(-n5c6ccc(C7CCCCC7)cc6c6cc(C7CCCCC7)ccc65)cc4)c4ccccc34)cccc2c1 ; c1ccc2c(-c3c4ccccc4cc4cc(-n5c6ccc(C7CCCCC7)cc6c6cc(C7CCCCC7)ccc65)ccc34)cccc2c1 ; c1ccc2c(-c3c4ccccc4cc4cc(-n5c6ccccc6c6cc(C7CCCCC7)ccc65)ccc34)cccc2c1 ; c1ccc(N(c2ccccc2)c2ccc3c(c2)c2ccccc2n3-c2ccc(-c3c4ccccc4c(-c4ccc(-n5c6ccc(C7CCCCC7)cc6c6cc(C7CCCCC7)ccc65)cc4)c4ccccc34)cc2)cc1]

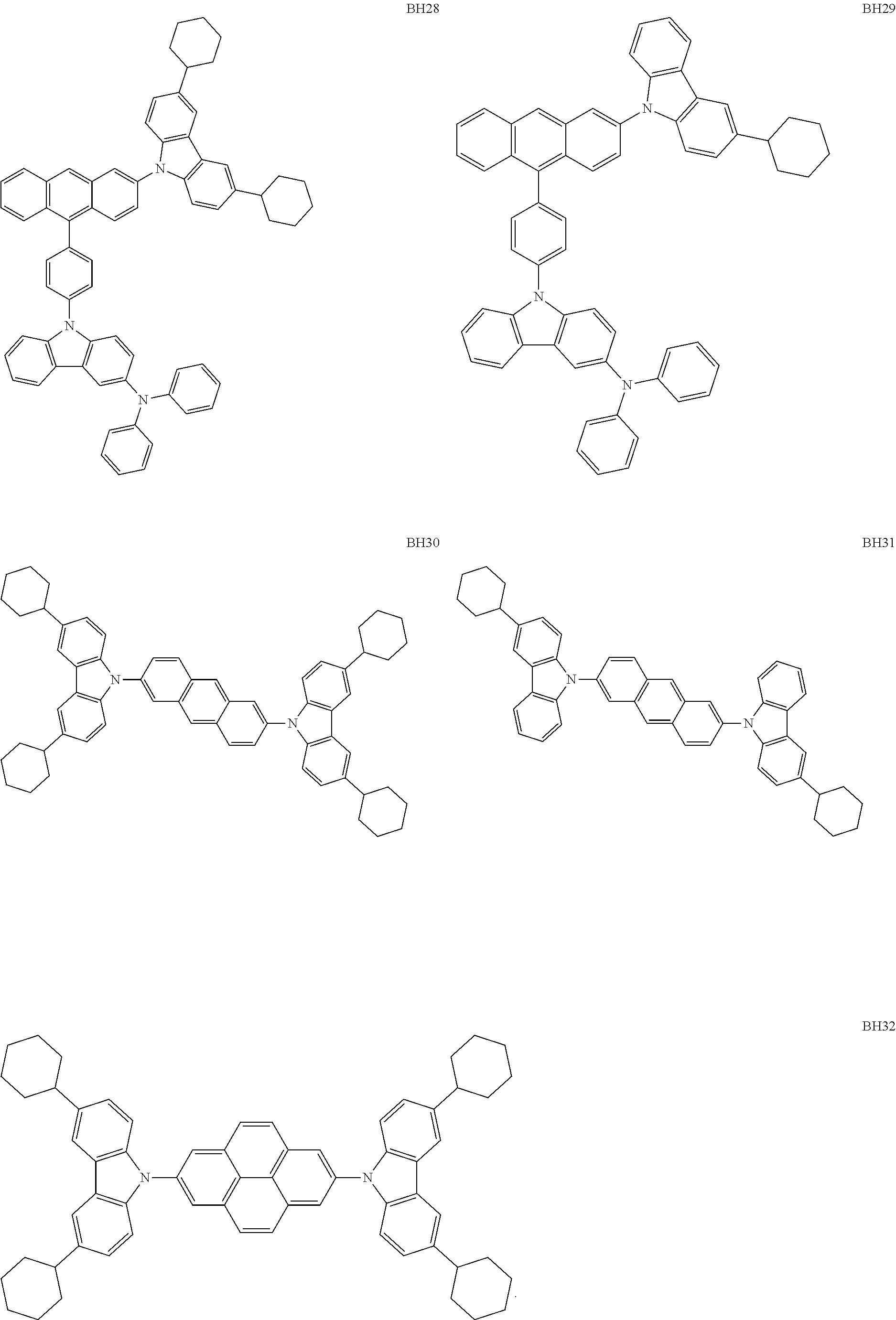

The first host included in the first emission layer may be selected from Compounds BH11 to BH14, and the second host included in the second emission layer may be selected from Compounds BH21 to BH32.

Another aspect provides a display apparatus including: the light-emitting device including a first electrode, a second electrode facing the first electrode, and an interlayer between the first electrode and the second electrode and including a first emission layer and a second emission layer that are sequentially stacked; and a thin-film transistor electrically linked to the first electrode. In the display apparatus, the first emission layer and the second emission layer may satisfy Condition 1:

$${GSP}_{1} < 10 mV / nm \leq {GSP}_{2} \qquad Condition 1$$

wherein, in Condition 1,
GSP₁ is a giant surface potential of the first emission layer, and
GSP₂ is a giant surface potential of the second emission layer.

That is, the light-emitting device included in the display apparatus may be the same as the light-emitting device including the first emission layer and the second emission layer that satisfy Condition 1.

In an embodiment, the display apparatus may further include a color filter, a color conversion layer, a touch screen layer, a polarizing layer, or a combination thereof.

Another aspect provides an electronic apparatus including: the display apparatus; and a processor which transmits a signal to the display apparatus. That is, the display apparatus included in the electronic apparatus may include the light-emitting device including the first emission layer and the second emission layer that satisfy Condition 1.

In an embodiment, the electronic apparatus may be one of a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle gauge, a center information display (CID) in a vehicle, a head-up display for a vehicle, a room mirror display, a video wall including multiple displays tiled together, a theater or stadium screen, a phototherapy device, and a signboard.

Hereinafter, the structure of a light-emitting device 11 illustrated in FIG. 6 will be described in detail as follows. The light-emitting device 11 may include a first electrode 110, a hole transport region 120, an emission layer 130, an electron transport region 140, and a second electrode 150, wherein the emission layer 130 may include a first emission layer 131 and a second emission layer 132. The hole transport region 120, the emission layer 130, and the electron transport region 140 may be collectively referred to as a stack ST, and the stack ST may correspond to a first stack ST1, a second stack ST2, or both a first stack ST1 and a second stack ST2 illustrated in FIG. 7.

### [First Electrode 110]

In FIG. 6, a substrate may be additionally arranged under the first electrode 110 or on the second electrode 150. For use as the substrate, a glass substrate or a plastic substrate may be used. The substrate may be a flexible substrate. For example, the substrate may include plastics with excellent heat resistance and durability, such as, for example, polyimide, polyethylene terephthalate (PET), polycarbonate, polyethylene naphthalate, polyarylate (PAR), polyetherimide, or any combination thereof.

The first electrode 110 may be formed by providing a material for forming the first electrode 110 on the substrate by using a deposition method or a sputtering method. In an example in which the first electrode 110 is an anode, a material for forming the first electrode 110 may be a high-work function material that facilitates injection of holes.

The first electrode 110 may be a reflective electrode, a semi-transmissive electrode, or a transmissive electrode. In an embodiment, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure consisting of a single layer or a multi-layer structure including multiple layers. For example, the first electrode 110 may have a three-layer structure of ITO/Ag/ITO.

### [Hole Transport Region 120]

The hole transport region 120 may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The hole transport region 120 may include a hole injection layer, a hole transport layer, an emission auxiliary layer, an electron blocking layer, or any combination thereof.

For example, the hole transport region 120 may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110.

The hole transport region 120 may include a compound represented by Formula 201, a compound represented by Formula 202, or any combination thereof:

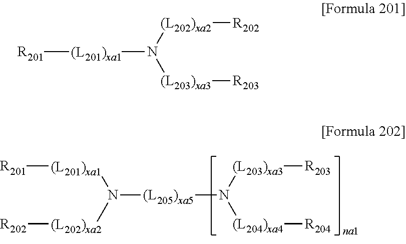

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, or the like) unsubstituted or substituted with at least one R₁₀ₐ (e.g., Compound HT16, or the like).

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

For example, each of Formulae 201 and 202 may include at least one of groups represented by Formulae CY201 to CY217:

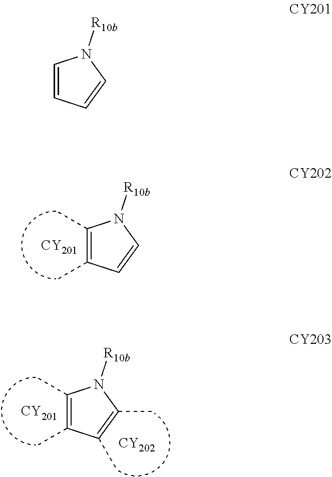

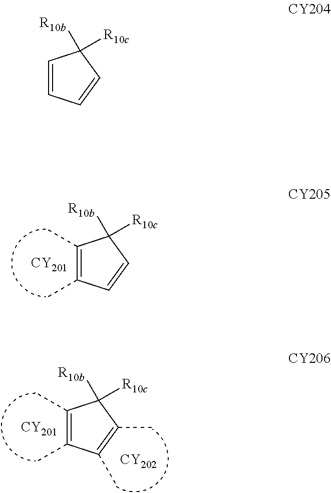

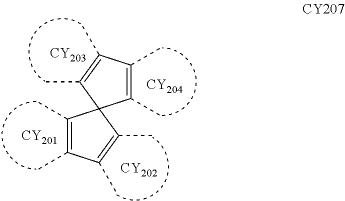

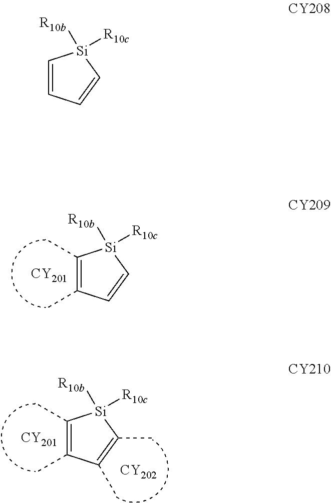

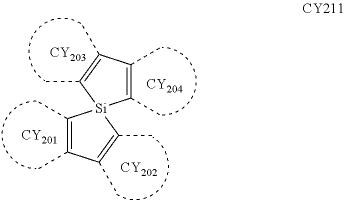

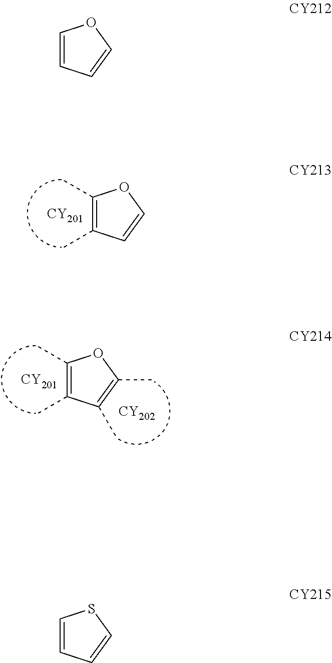

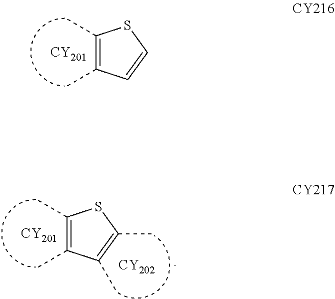

wherein, in Formulae CY201 to CY217, R_{10b} and R_{10c} may each be as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of the groups represented by Formulae CY201 to CY203 and at least one of groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include groups represented by Formulae CY201 to CY203.

In one or more embodiments, each of Formulae 201 and 202 may not include groups represented by Formulae CY201 to CY203, and may include at least one of groups represented by Formulae CY204 to CY217.

In one or more embodiments, each of Formulae 201 and 202 may not include groups represented by Formulae CY201 to CY217.

For example, the hole transport region 120 may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

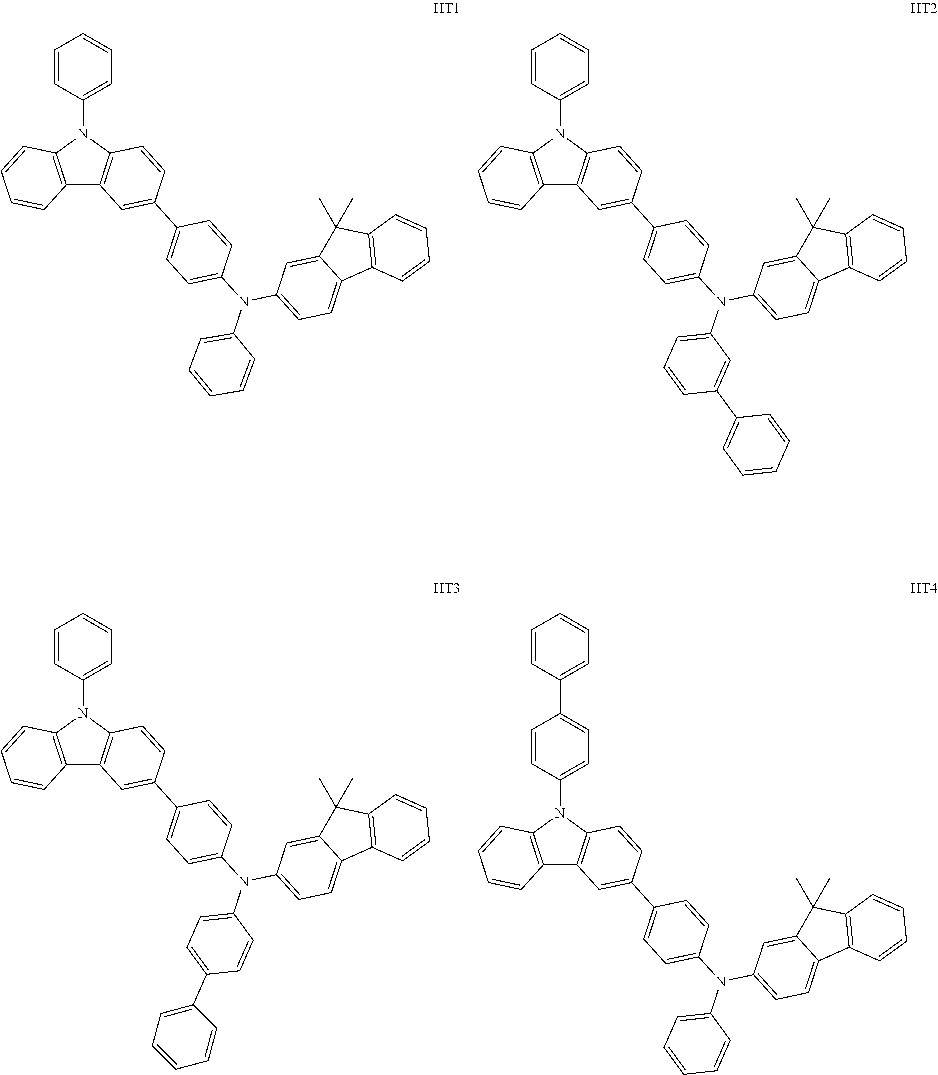 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

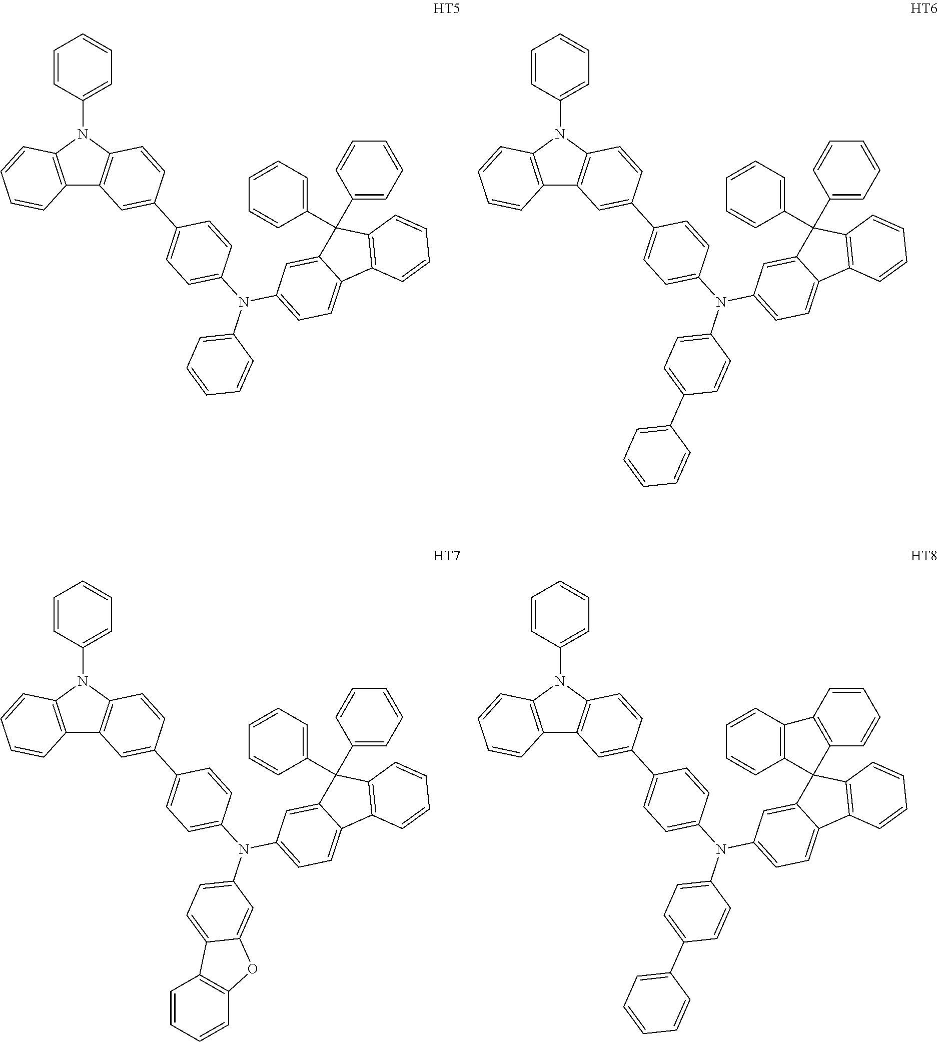 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

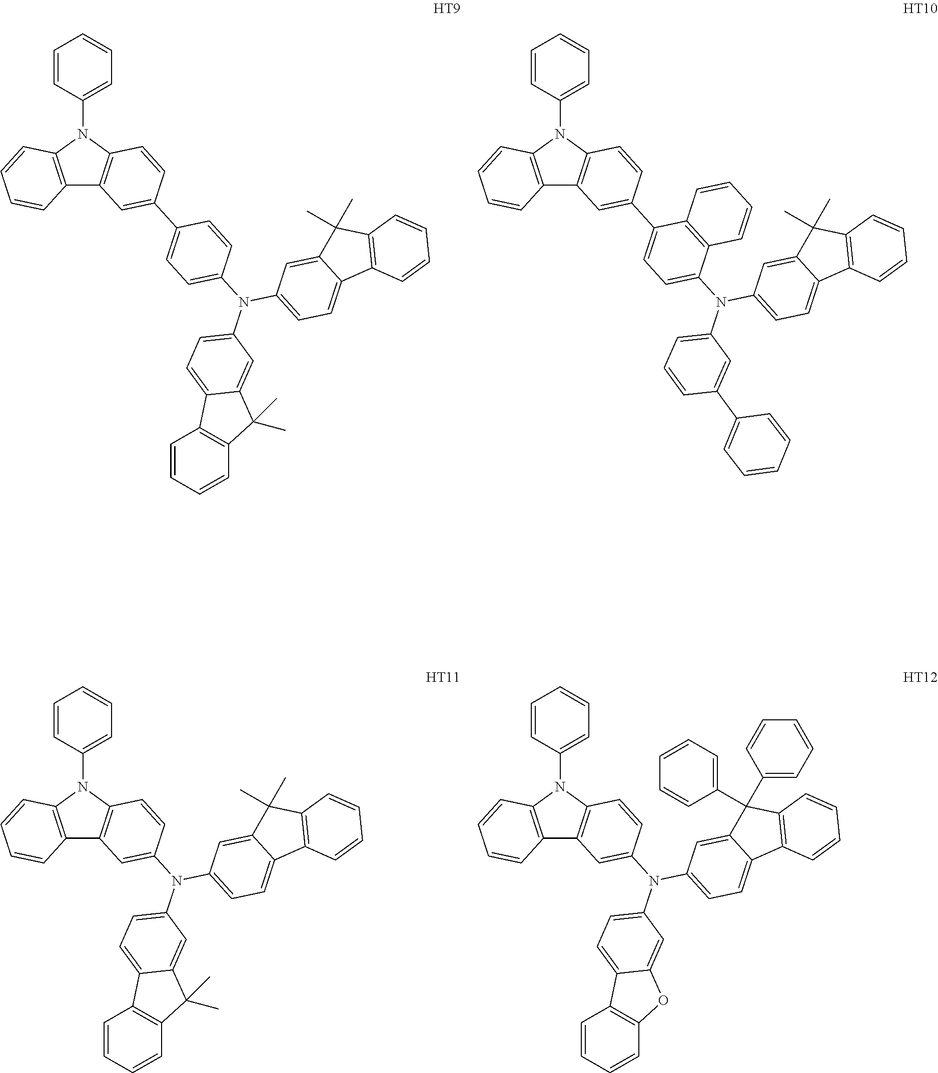 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

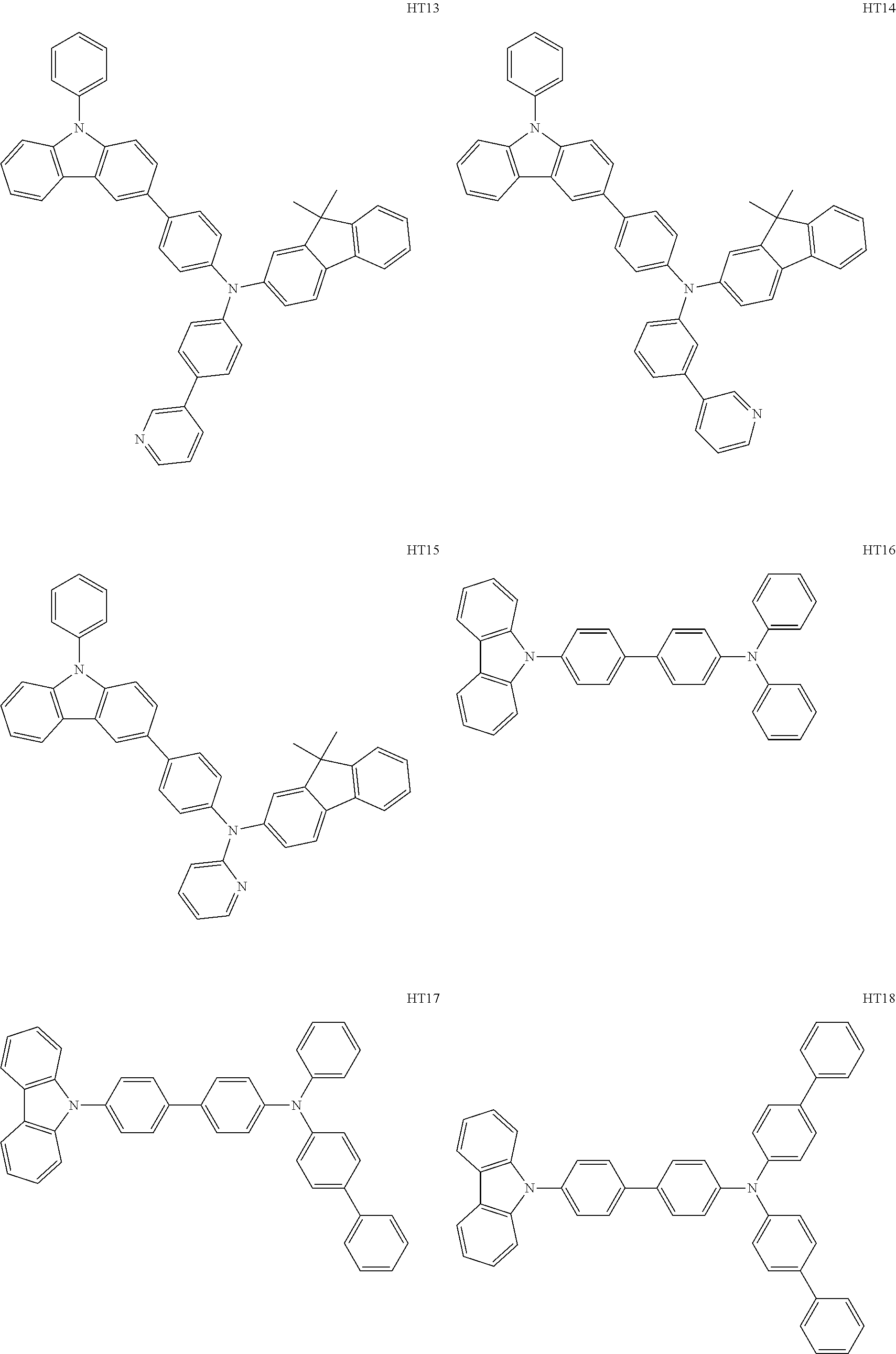 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

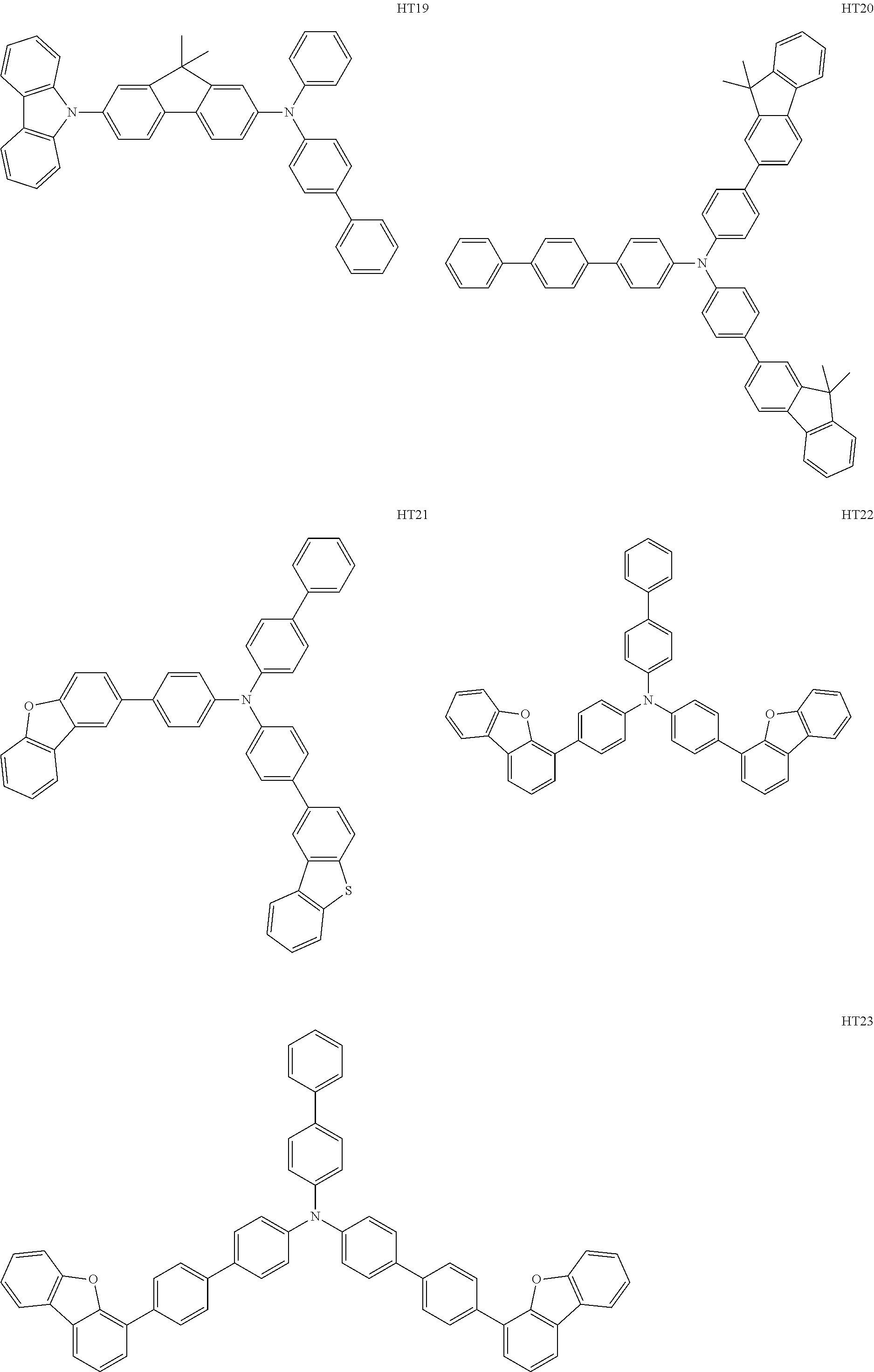 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

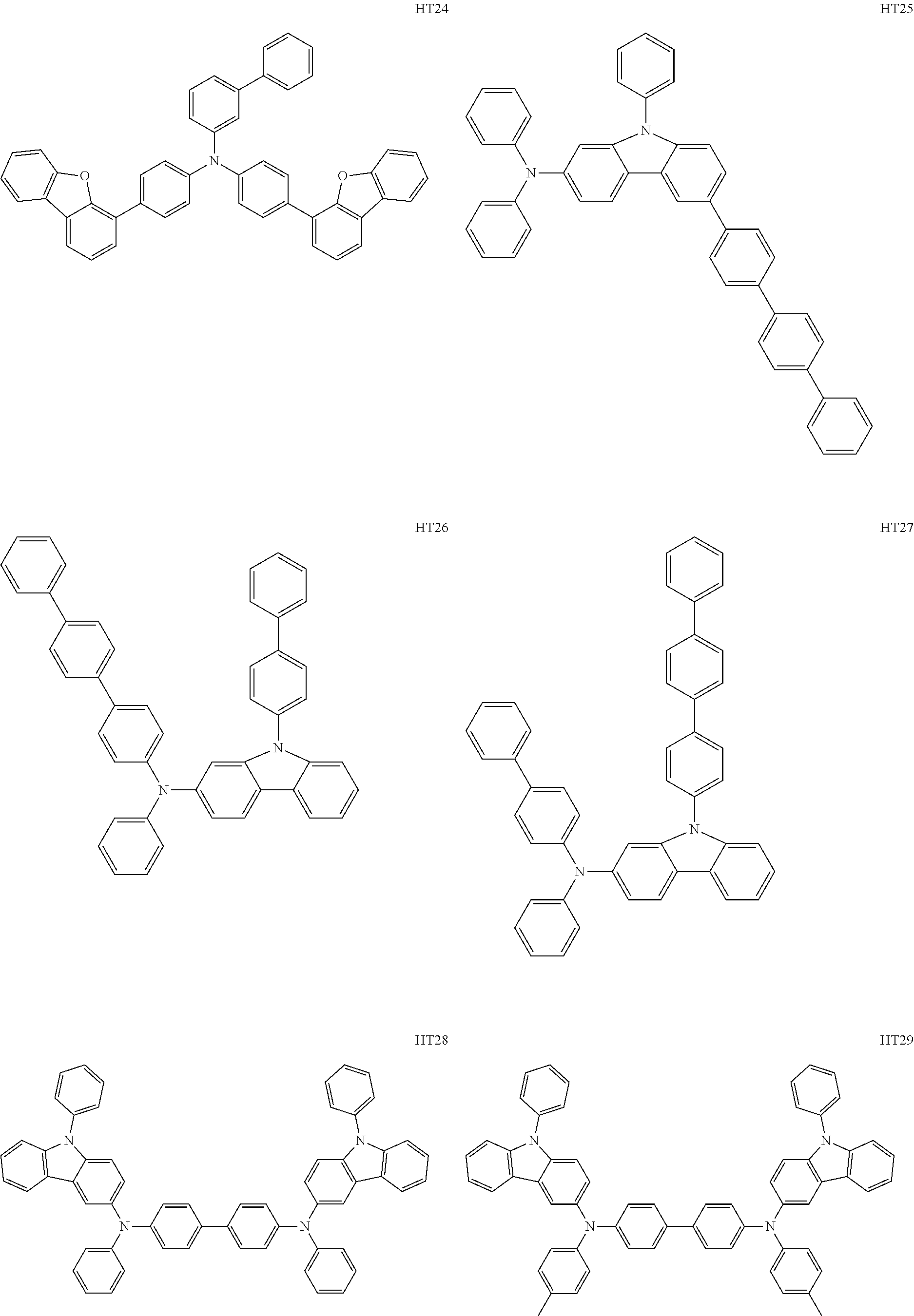

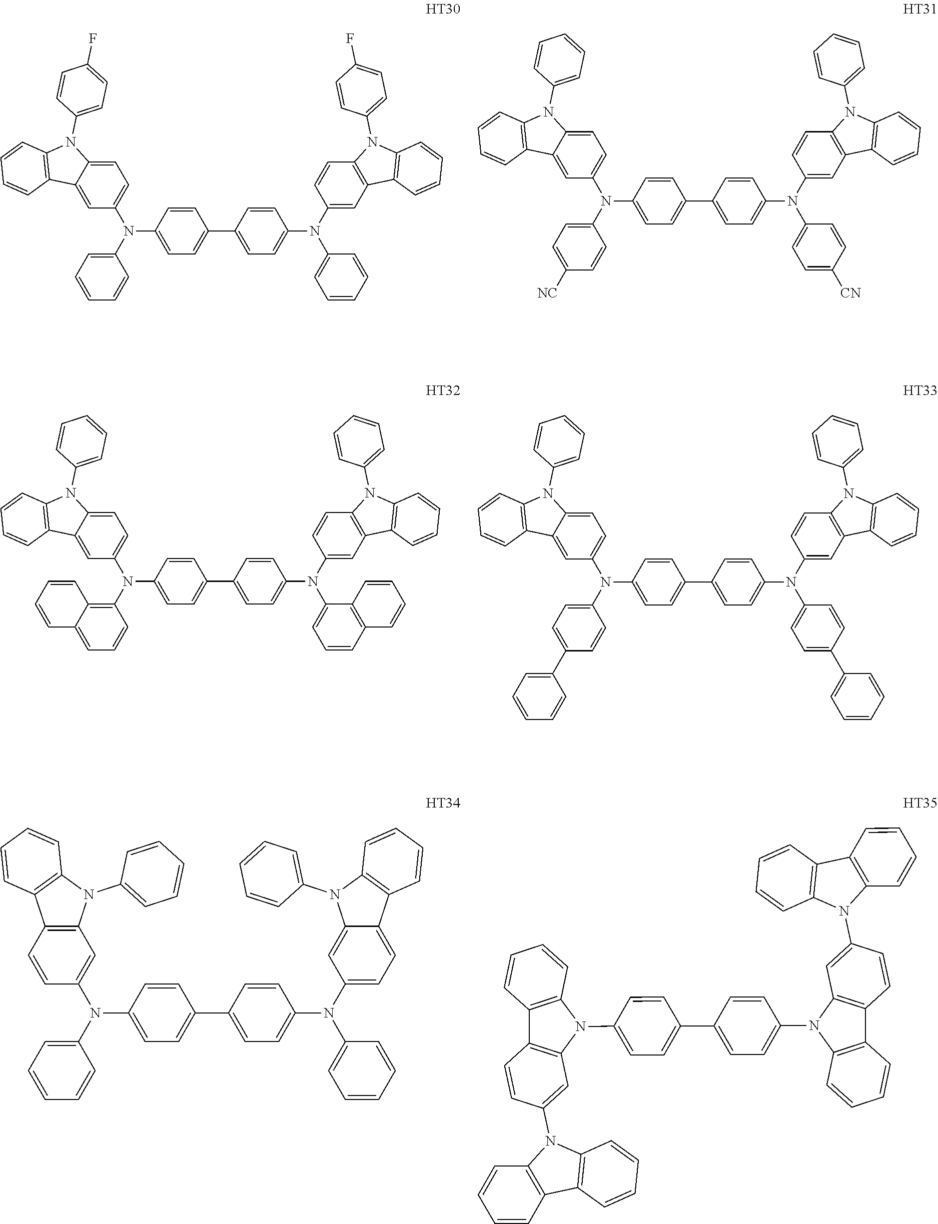

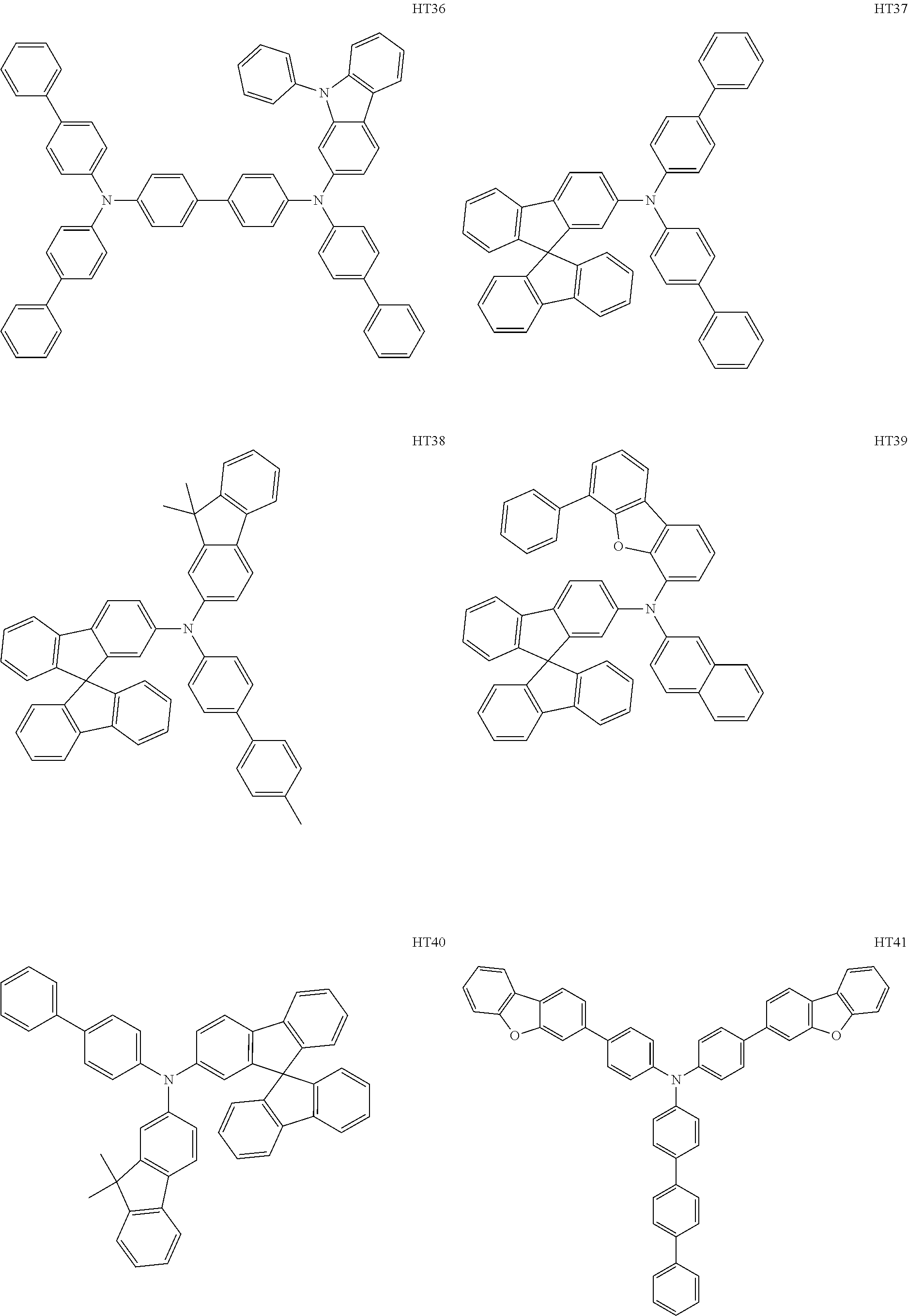

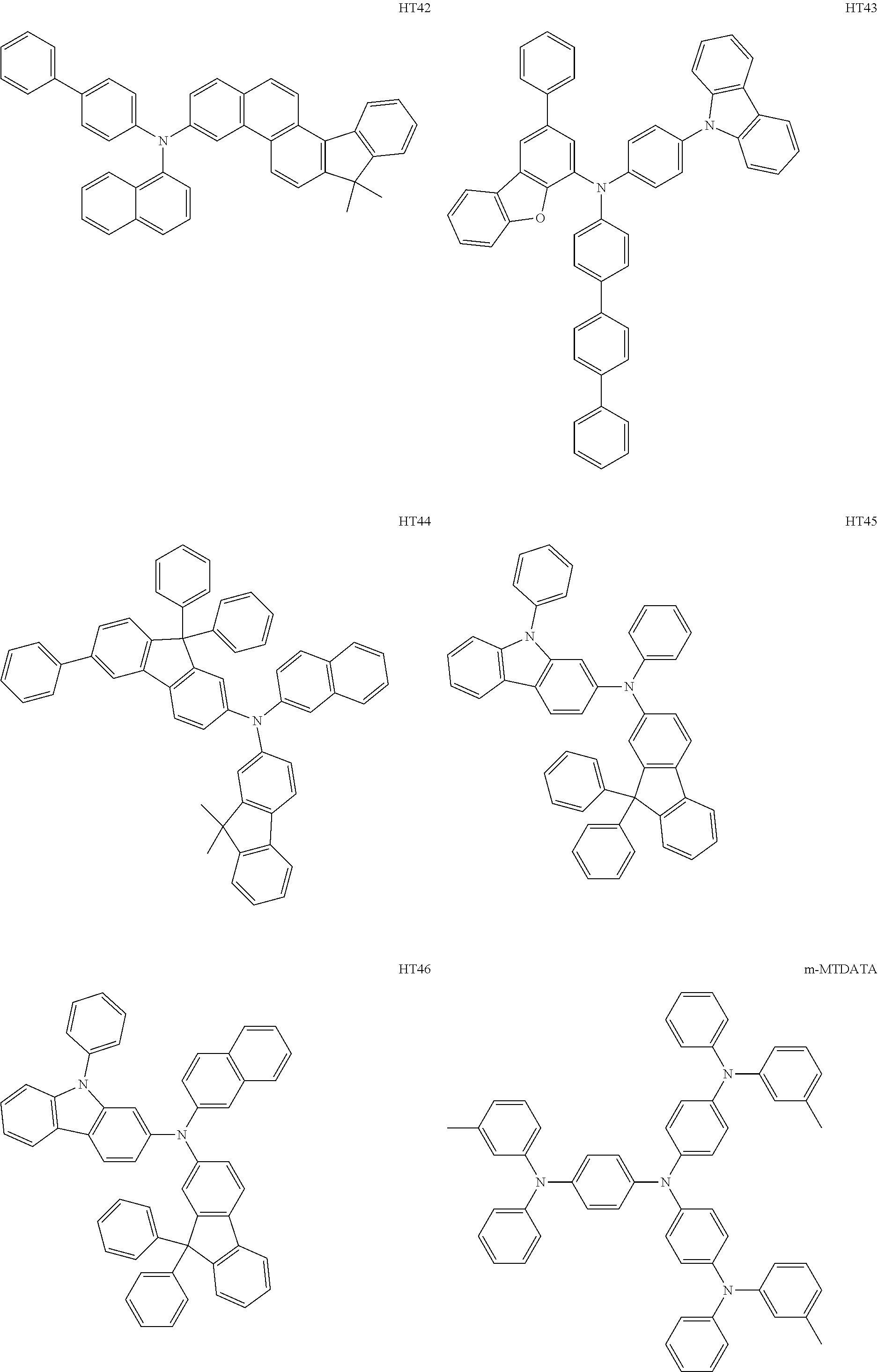

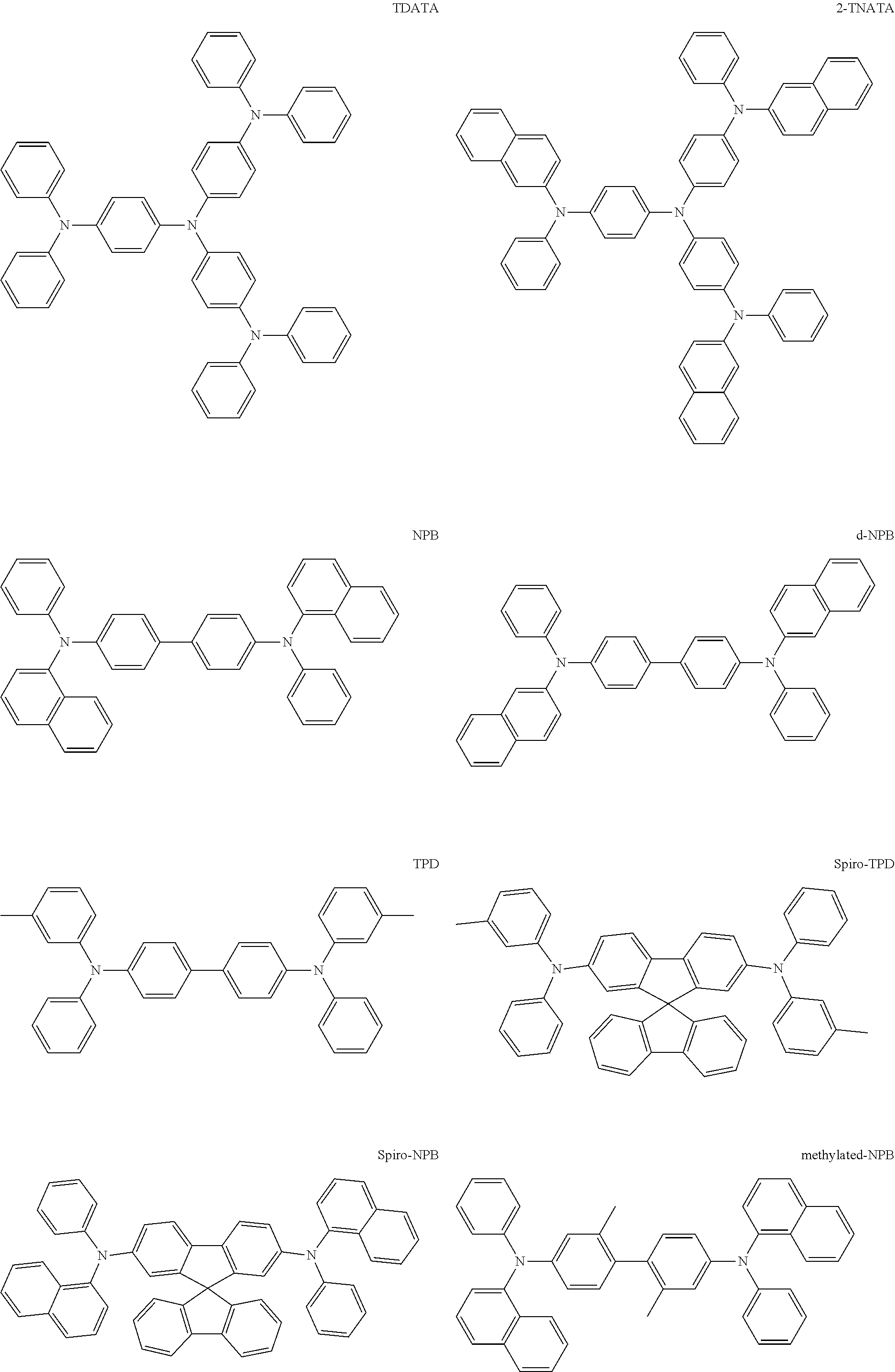

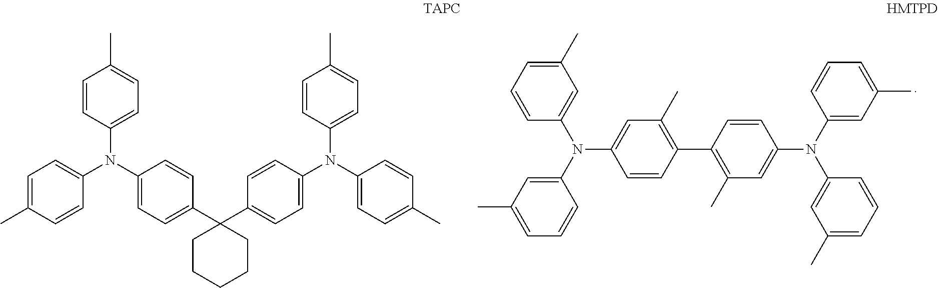

A thickness of the hole transport region 120 may be in a range of about 50 Å to about 10,000 Å, for example, about 100 Å to about 4,000 Å. In an example in which the hole transport region 120 includes a hole injection layer, a hole transport layer, or any combination thereof, a thickness of the hole injection layer may be in a range of about 100 Å to about 9,000 Å, for example, about 100 Å to about 1,000 Å, and a thickness of each of the hole transport layer and the electron blocking layer may be in a range of about 50 Å to about 2,000 Å, for example, about 100 Å to about 1,500 Å. In an example in which the thicknesses of the hole transport region, the hole injection layer, and the hole transport layer are within these ranges, satisfactory hole transporting characteristics may be obtained without a substantial increase in driving voltage.

The emission auxiliary layer is a layer that increases light emission efficiency by compensating for an optical resonance distance according to a wavelength of light emitted from the emission layer 130. The electron blocking layer may be a layer that prevents electron leakage from the emission layer 130 to the hole transport region 120. Materials that may be included in the hole transport region 120 may be included in the emission auxiliary layer and the electron blocking layer.

[p-Dopant]

The hole transport region 120 may further include, in addition to the aforementioned materials, a charge generation material for the improvement of conductive properties. The charge-generating material may be substantially homogeneously or non-homogeneously dispersed (for example, as a single layer consisting of charge generating material) in the hole transport region 120.

The charge generation material may be, for example, a p-dopant.

For example, the p-dopant may have a lowest unoccupied molecular orbital (LUMO) energy level of about −3.5 eV or less.

In an embodiment, the p-dopant may include a quinone derivative, a cyano group-containing compound, a compound including element EL1 and element EL2, or any combination thereof.

Examples of the quinone derivative may include TCNQ, F4-TCNQ, and the like.

Examples of the cyano group-containing compound may include HAT-CN and a compound represented by Formula 221:

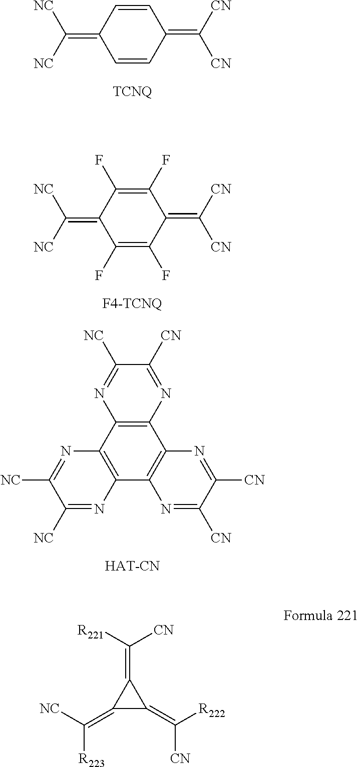

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including the element EL1 and the element EL2, the element EL1 may be a metal, a metalloid, or a combination thereof, and the element EL2 may be a non-metal, a metalloid, or a combination thereof.

Examples of the metal may include: alkali metal (e.g., lithium (Li), sodium (Na), potassium (K), rubidium (Rb), cesium (Cs), or the like); alkaline earth metal (e.g., beryllium (Be), magnesium (Mg), calcium (Ca), strontium (Sr), barium (Ba), or the like); transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), or the like); post-transition metal (e.g., zinc (Zn), indium (In), tin (Sn), or the like); lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), or the like); and the like.

Examples of the metalloid may include silicon (Si), antimony (Sb), tellurium (Te), and the like.

Examples of the non-metal may include oxygen (O), a halogen (e.g., F, Cl, Br, I, or the like), and the like.

For example, the compound including element EL1 and element EL2 may include metal oxide, metal halide (e.g., metal fluoride, metal chloride, metal bromide, metal iodide, or the like), metalloid halide (e.g., metalloid fluoride, metalloid chloride, metalloid bromide, metalloid iodide, or the like), metal telluride, or any combination thereof.

Examples of the metal oxide may include a tungsten oxide (for example, WO, W₂O₃, WO₂, WO₃, W₂O₅, or the like), a vanadium oxide (for example, VO, V₂O₃, VO₂, V₂O₅, or the like), a molybdenum oxide (for example, MoO, Mo₂O₃, MoO₂, MoO₃, Mo₂O₅, or the like), a rhenium oxide (for example, ReO₃, or the like), and the like.

Examples of the metal halide may include alkali metal halide, alkaline earth metal halide, transition metal halide, post-transition metal halide, lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide may include a titanium halide (e.g., TiF₄, TiCl₄, TiBr₄, TiI₄, or the like), a zirconium halide (e.g., ZrF₄, ZrCl₄, ZrBr₄, ZrI₄, or the like), a hafnium halide (e.g., HfF₄, HfCl₄, HfBr₄, HfI₄, or the like), a vanadium halide (e.g., VF₃, VCl₃, VBr₃, VI₃, or the like), a niobium halide (e.g., NbF₃, NbCl₃, NbBr₃, NbI₃, or the like), a tantalum halide (e.g., TaF₃, TaCl₃, TaBr₃, TaI₃, or the like), a chromium halide (e.g., CrF₃, CrCl₃, CrBr₃, CrI₃, or the like), a molybdenum halide (e.g., MoF₃, MoCl₃, MoBr₃, MoI₃, or the like), a tungsten halide (e.g., WF₃, WCl₃, WBr₃, WI₃, or the like), a manganese halide (e.g., MnF₂, MnCl₂, MnBr₂, MnI₂, or the like), a technetium halide (e.g., TcF₂, TcCl₂, TcBr₂, TcI₂, or the like), a rhenium halide (e.g., ReF₂, ReCl₂, ReBr₂, ReI₂, or the like), an iron halide (e.g., FeF₂, FeCl₂, FeBr₂, FeI₂, or the like), a ruthenium halide (e.g., RuF₂, RuCl₂, RuBr₂, RuI₂, or the like), an osmium halide (e.g., OsF₂, OsCl₂, OsBr₂, OsI₂, or the like), a cobalt halide (e.g., CoF₂, CoCl₂, CoBr₂, CoI₂, or the like), a rhodium halide (e.g., RhF₂, RhCl₂, RhBr₂, RhI₂, or the like), an iridium halide (e.g., IrF₂, IrCl₂, IrBr₂, IrI₂, or the like), a nickel halide (e.g., NiF₂, NiCl₂, NiBr₂, NiI₂, or the like), a palladium halide (e.g., PdF₂, PdCl₂, PdBr₂, PdI₂, or the like), a platinum halide (e.g., PtF₂, PtCl₂, PtBr₂, PtI₂, or the like), a copper halide (e.g., CuF, CuCl, CuBr, CuI, or the like), a silver halide (e.g., AgF, AgCl, AgBr, AgI, or the like), a gold halide (e.g., AuF, AuCl, AuBr, Aul, or the like), and the like.

Examples of the post-transition metal halide may include a zinc halide (for example, ZnF₂, ZnCl₂, ZnBr₂, ZnI₂, or the like), an indium halide (for example, InI₃, or the like), a tin halide (for example, SnI₂, or the like), and the like.

Examples of the lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of the metalloid halide may include an antimony halide (e.g., SbCI₅, or the like) and the like.

Examples of the metal telluride may include an alkali metal telluride (for example, Li₂Te, Na₂Te, K₂Te, Rb₂Te, Cs₂Te, or the like), an alkaline earth metal telluride (for example, BeTe, MgTe, CaTe, SrTe, BaTe, or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, or the like), a post-transition metal telluride (for example, ZnTe, or the like), a lanthanide metal telluride (for example, LaTe, CeTe, PrTe, NdTe, PmTe, EuTe, GdTe, TbTe, DyTe, HoTe, ErTe, TmTe, YbTe, LuTe, or the like), and the like.

### [Emission Layer 130]

When the light-emitting device 11 is a full-color light-emitting device, the emission layer 130 may be patterned into a red emission layer, a green emission layer, and/or a blue emission layer, according to a sub-pixel. In an embodiment, the emission layer 130 may have a stacked structure in which two or more layers among a red emission layer, a green emission layer, and a blue emission layer contact each other or are separated from each other to emit white light. In one or more embodiments, the emission layer may have a structure in which two or more materials among a red light-emitting material, a green light-emitting material, and a blue light-emitting material are mixed with each other in a single layer to emit white light.

The emission layer 130 may include a host and a dopant. The dopant may include a phosphorescent dopant, a fluorescent dopant, or any combination thereof.

An amount of the dopant in the emission layer 130 may be in a range of about 0.01 parts by weight to about 15 parts by weight, based on 100 parts by weight of the host.

The emission layer 130 may include quantum dots.

The emission layer 130 may include a delayed fluorescence material. The delayed fluorescence material may serve as a host or a dopant in the emission layer.

A thickness of the emission layer 130 may be in a range of about 100 Å to about 1,000 Å, for example, about 200 Å to about 600 Å. In an example in which the thickness of the emission layer 130 is within these ranges, excellent luminescence characteristics may be obtained without a substantial increase in driving voltage.

### [Host]

In an embodiment, the host may include a compound represented by Formula 301:

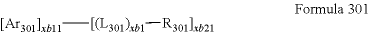

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each be as described in connection with Q₁.

In an example in which xe11 in Formula 301 is 2 or more, two or more of Ar₆₀₁ may be linked to each other via a single bond.

In an embodiment, the host may further include a compound represented by Formula 301-1, a compound represented by Formula 301-2, or any combination thereof:

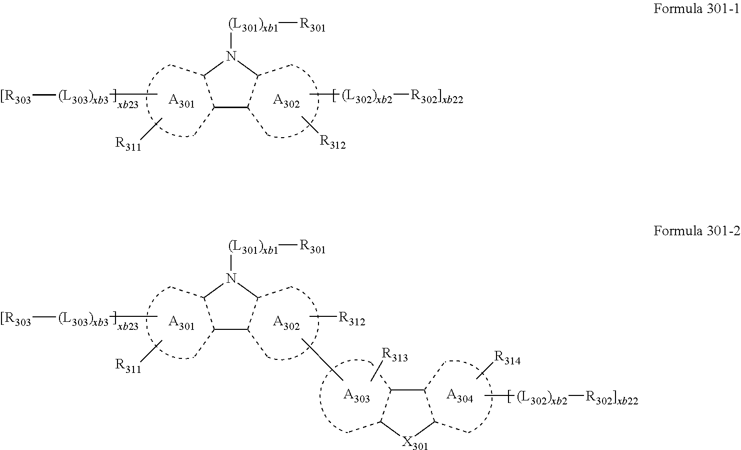

wherein, in Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,

L₃₀₁, xb1, and R₃₀₁ may each be as described elsewhere herein,
L₃₀₂ to L₃₀₄ may each independently be as described in connection with L₃₀₁,
xb2 to xb4 may each independently be as described in connection with xb1, and
R₃₀₂ to R₃₀₅ and R₃₁₁ to R₃₁₄ may each be as described in connection with R₃₀₁.

In one or more embodiments, the host may include an alkali earth metal complex, a post-transition metal complex, or any combination thereof. In one or more embodiments, the host may include a Be complex (e.g., Compound H55), an Mg complex, a Zn complex, or any combination thereof.

In one or more embodiments, the host may include: one of Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di(carbazol-9-yl)benzene (mCP); 1,3,5-tri(carbazol-9-yl)benzene (TCP); or any combination thereof:

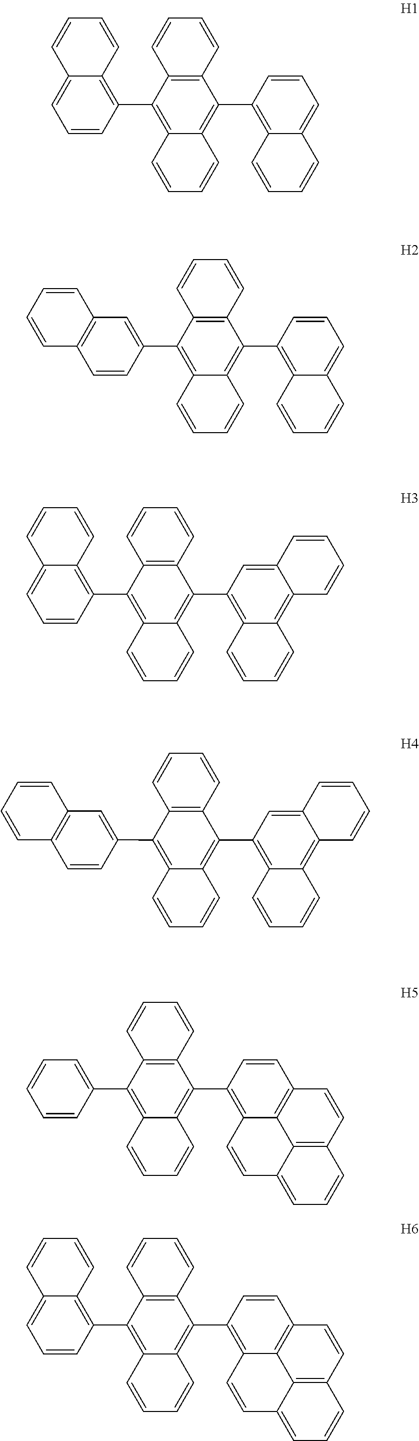

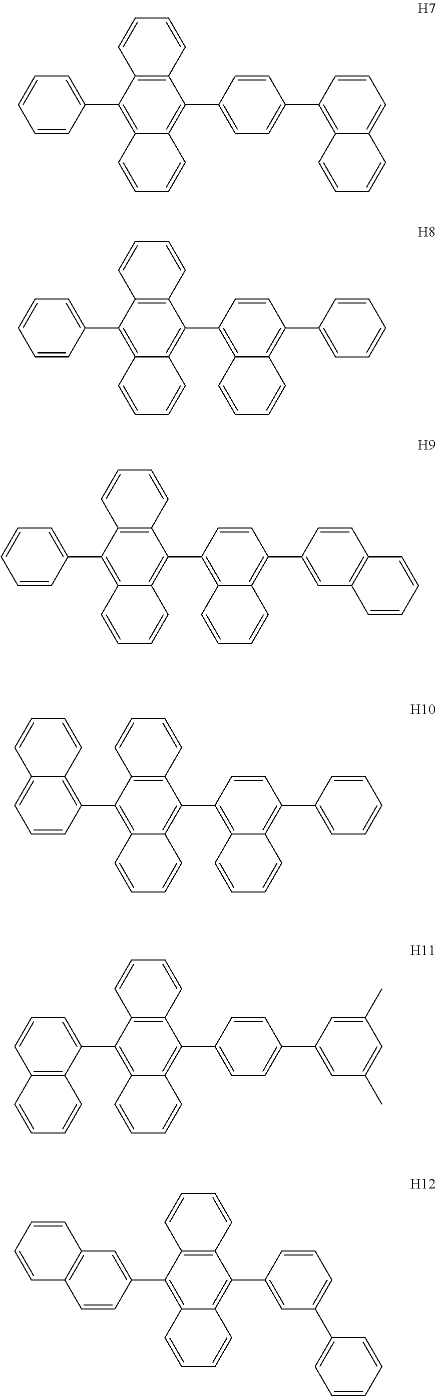

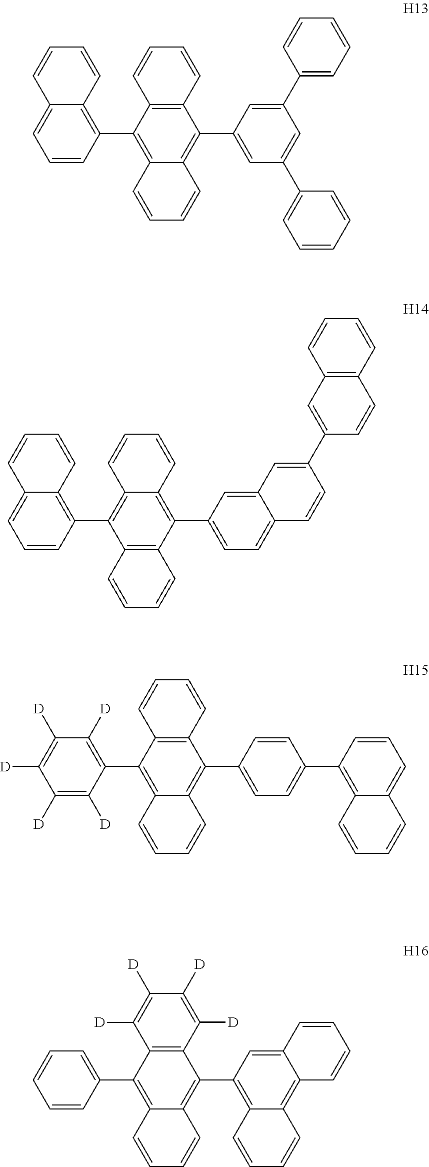

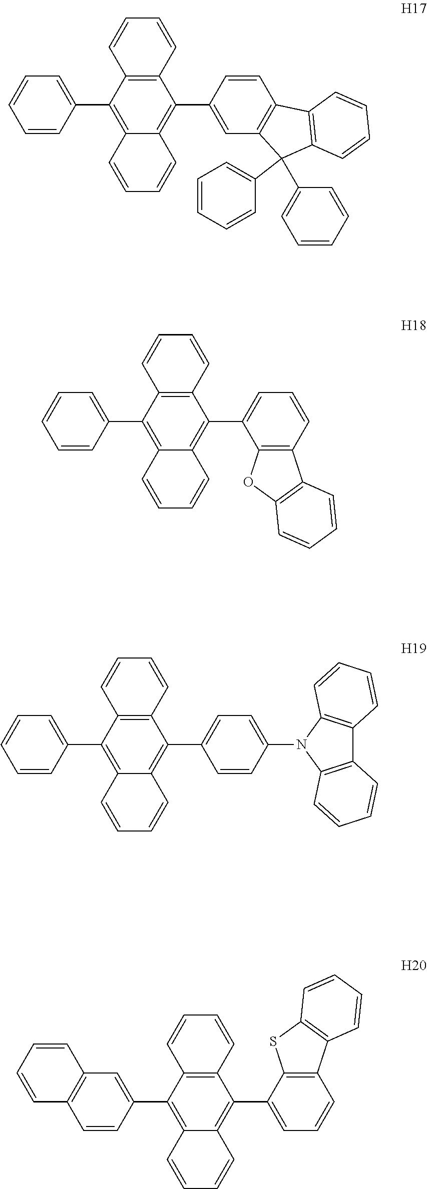

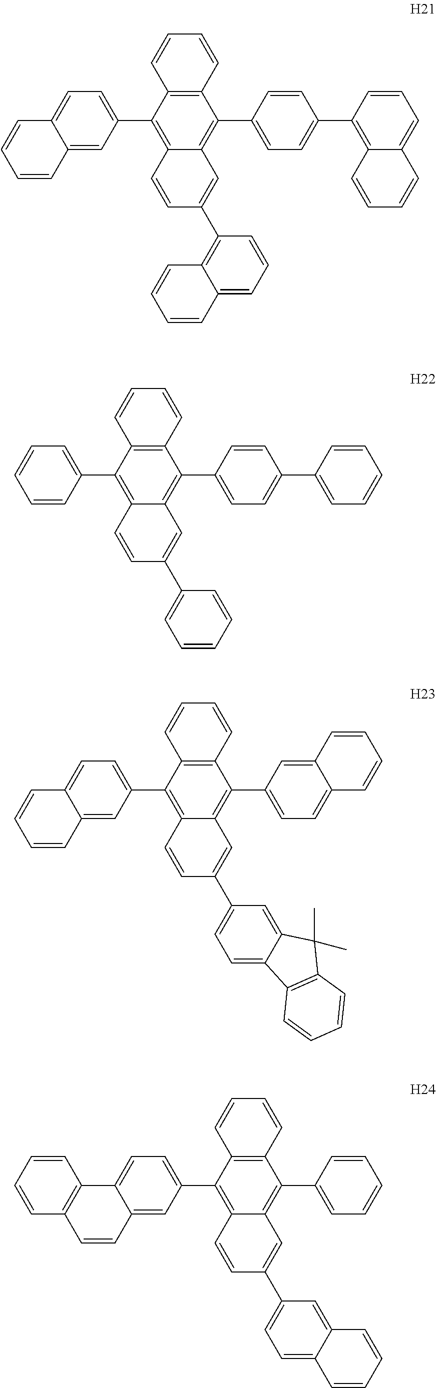

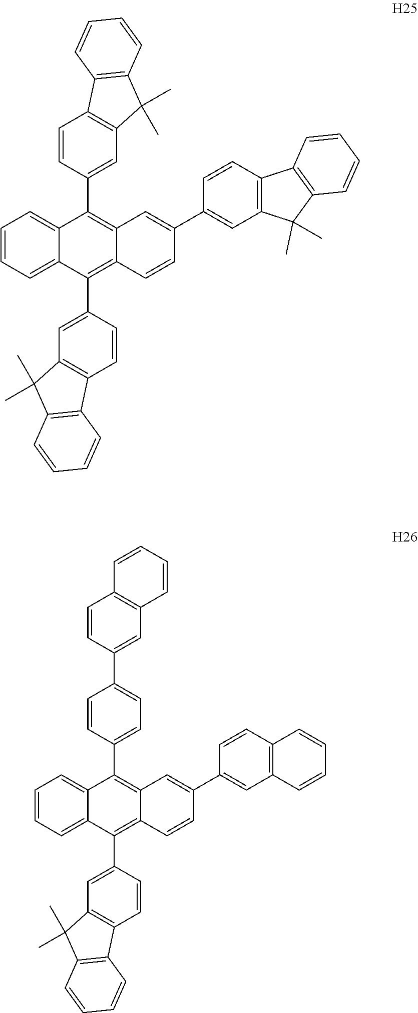

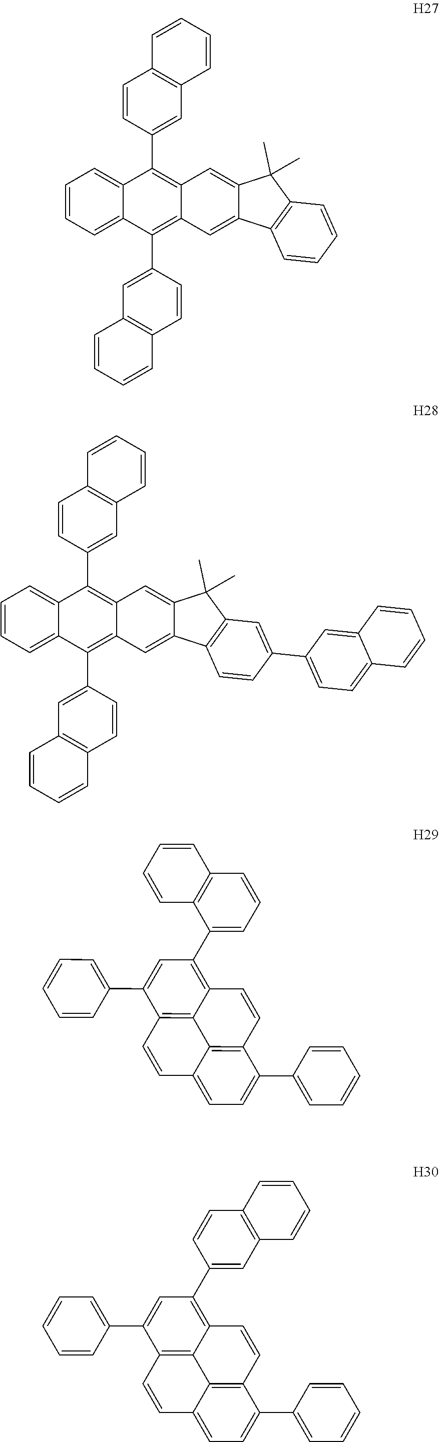

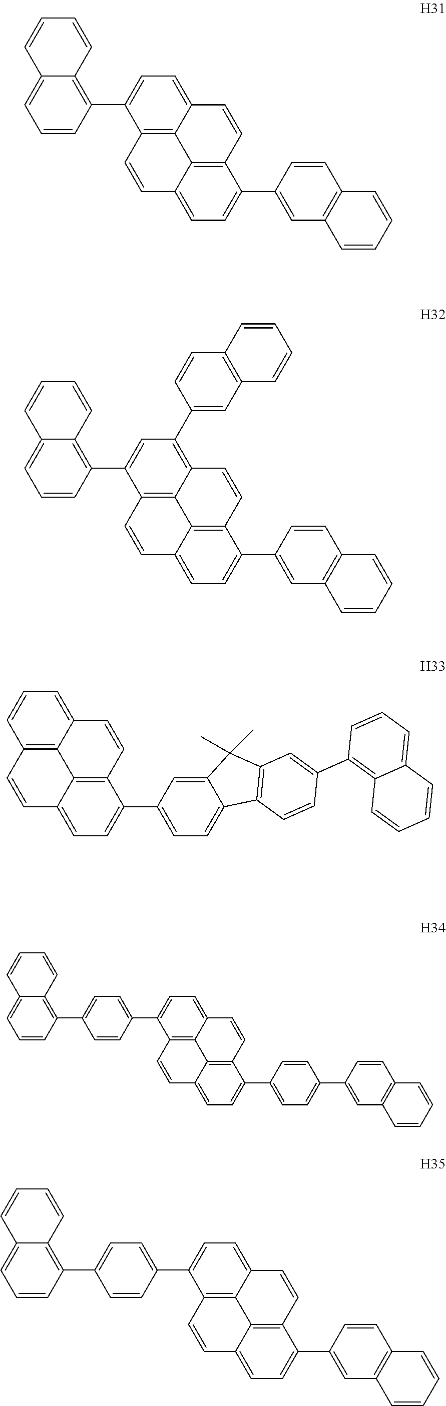

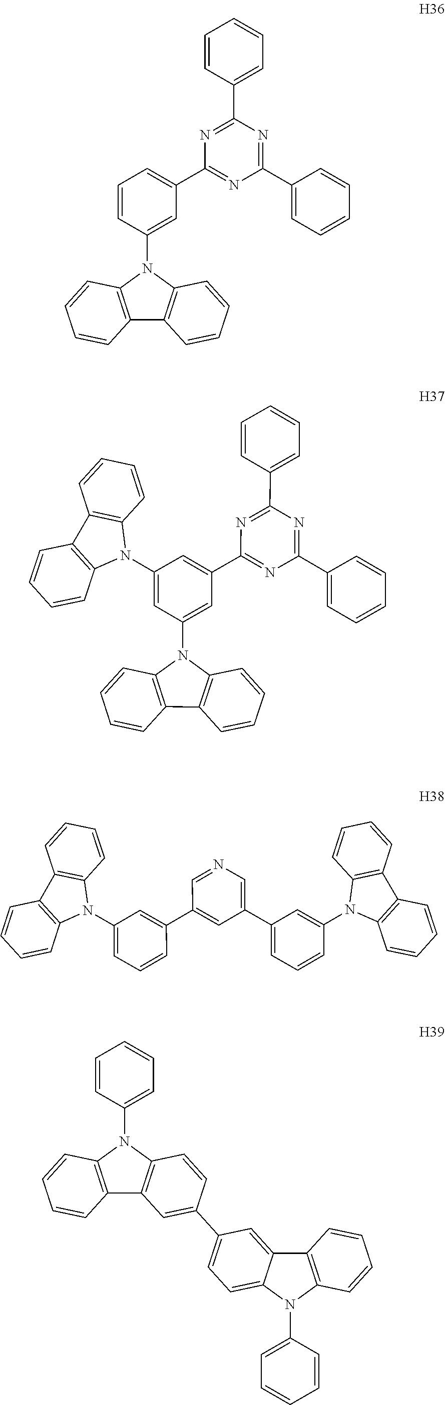 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

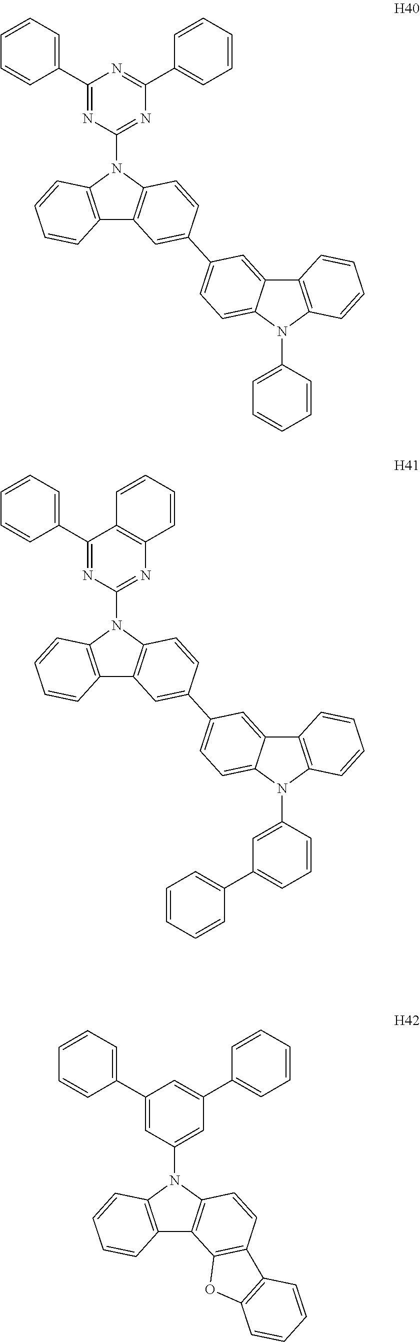 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

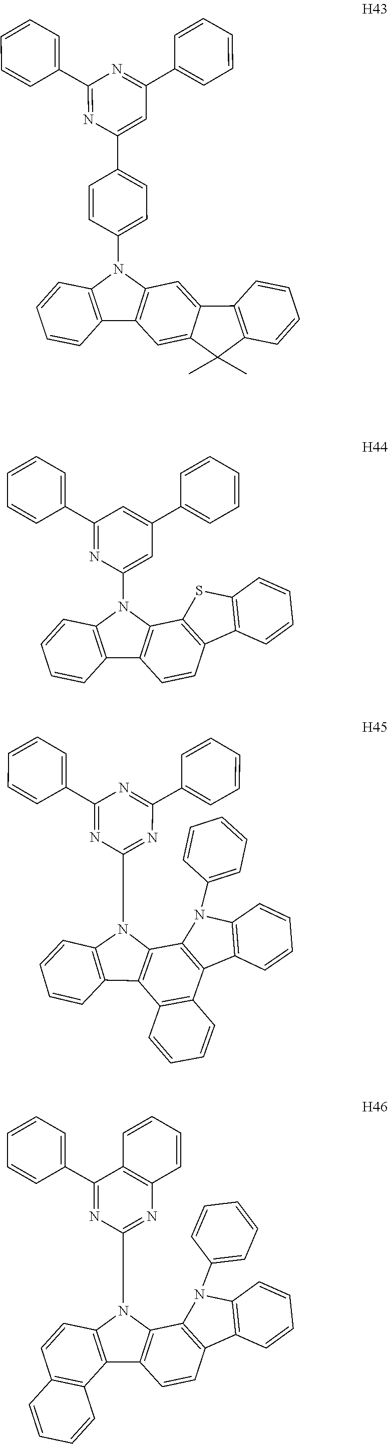 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

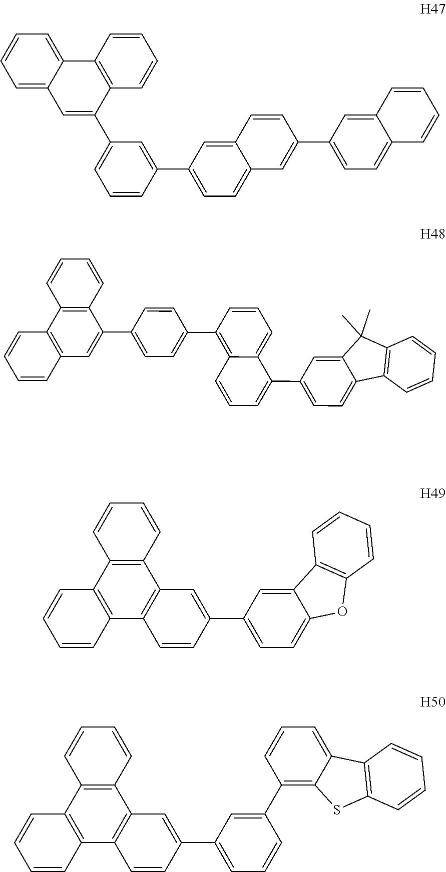

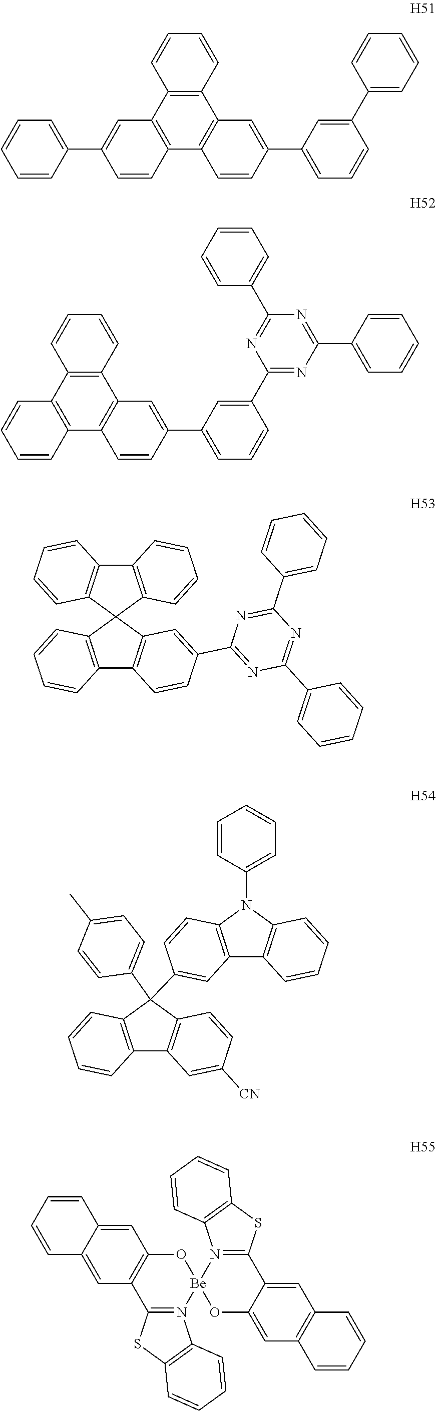

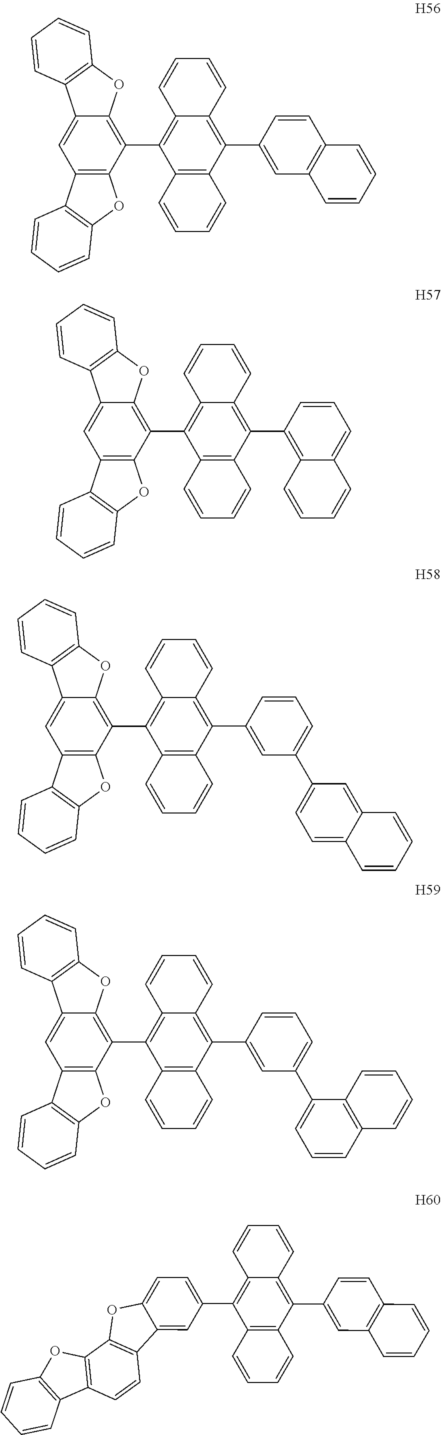

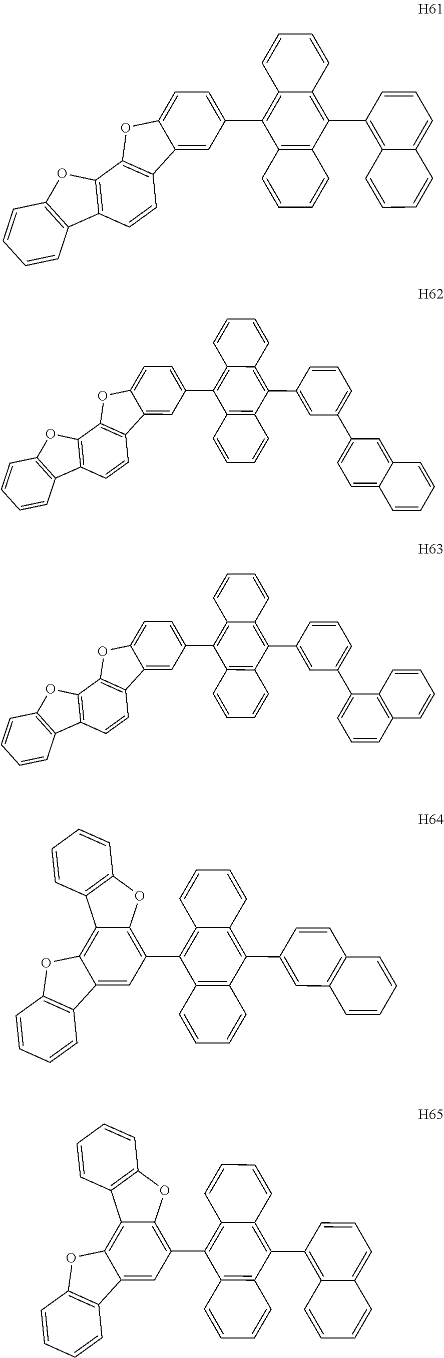 [SMILES: c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1]

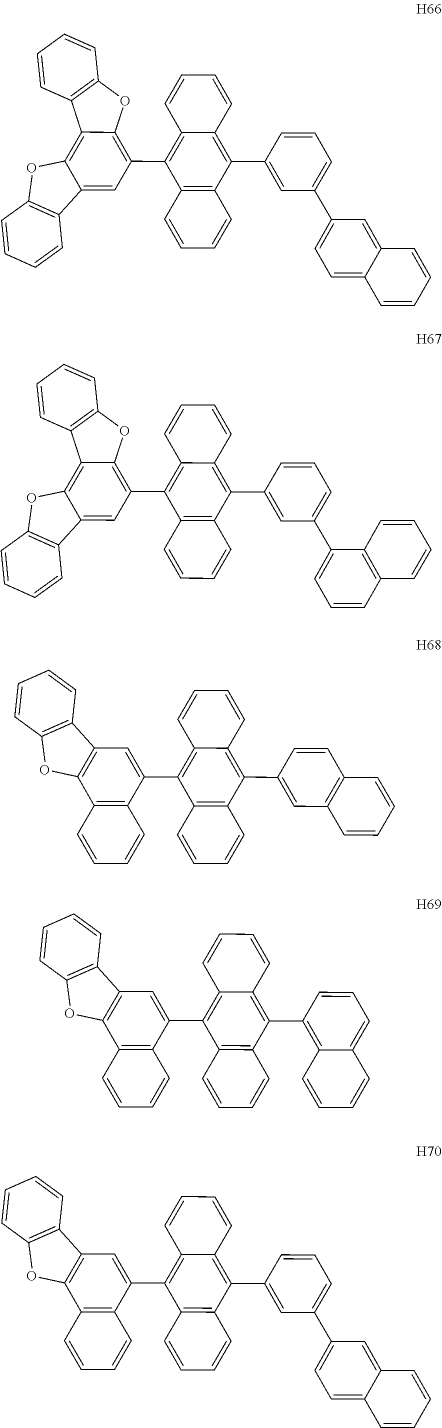 [SMILES: c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1]

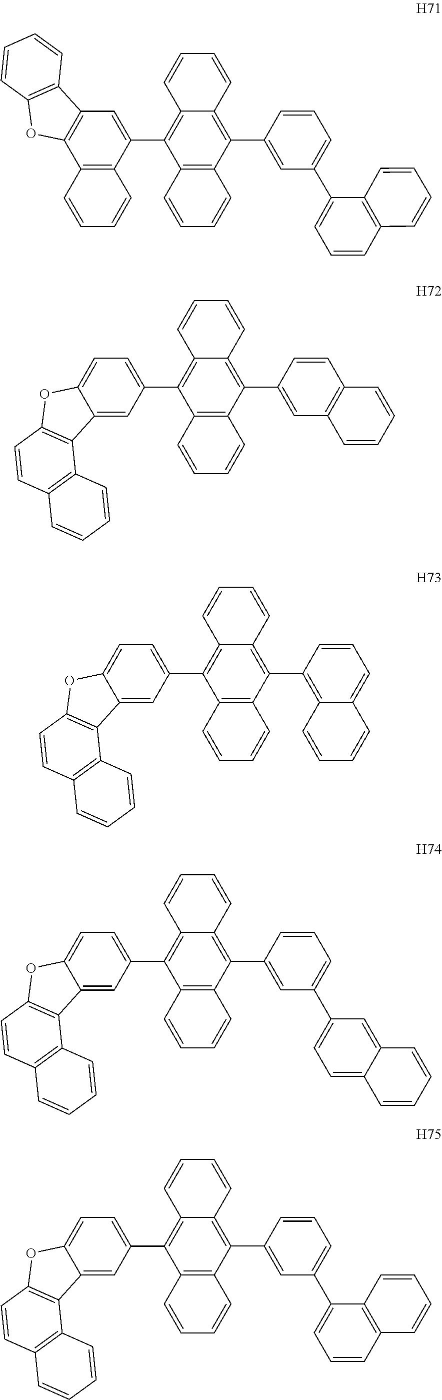 [SMILES: c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1]

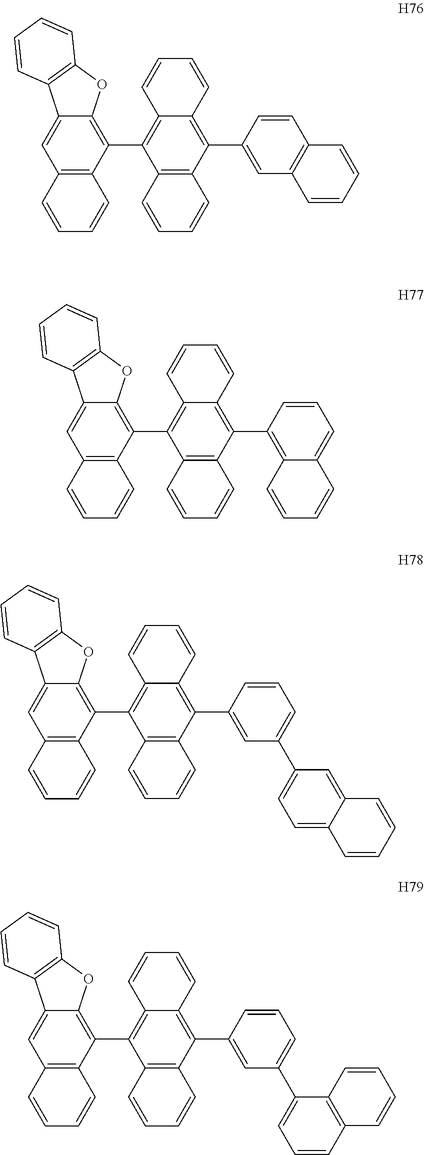 [SMILES: c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

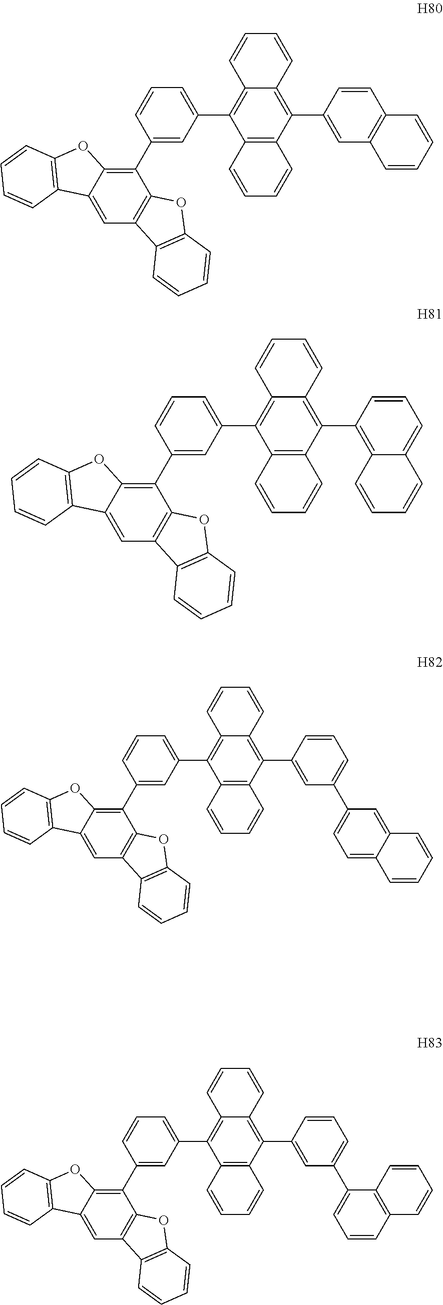 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

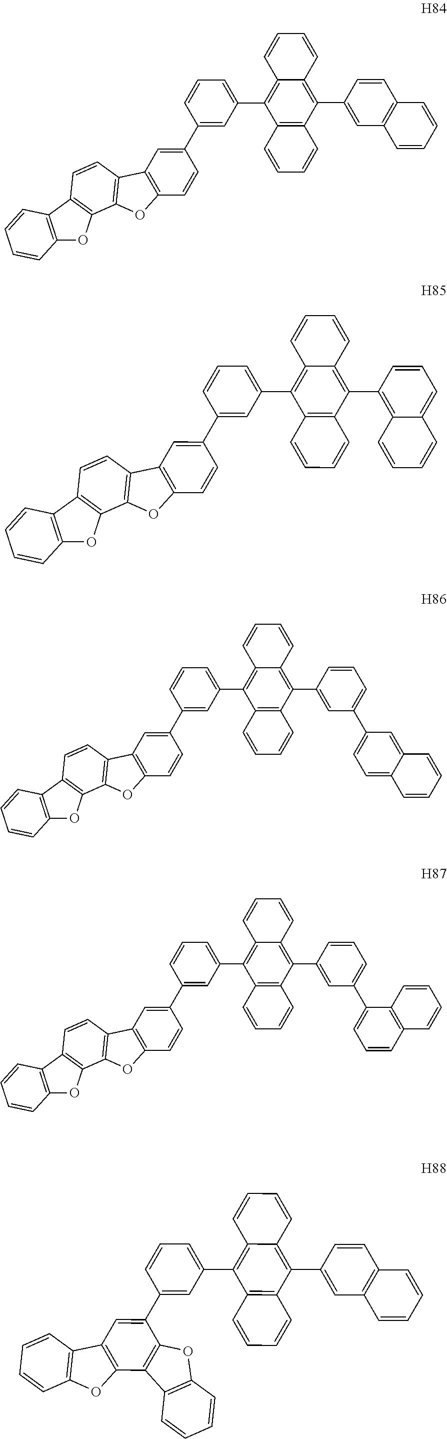 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

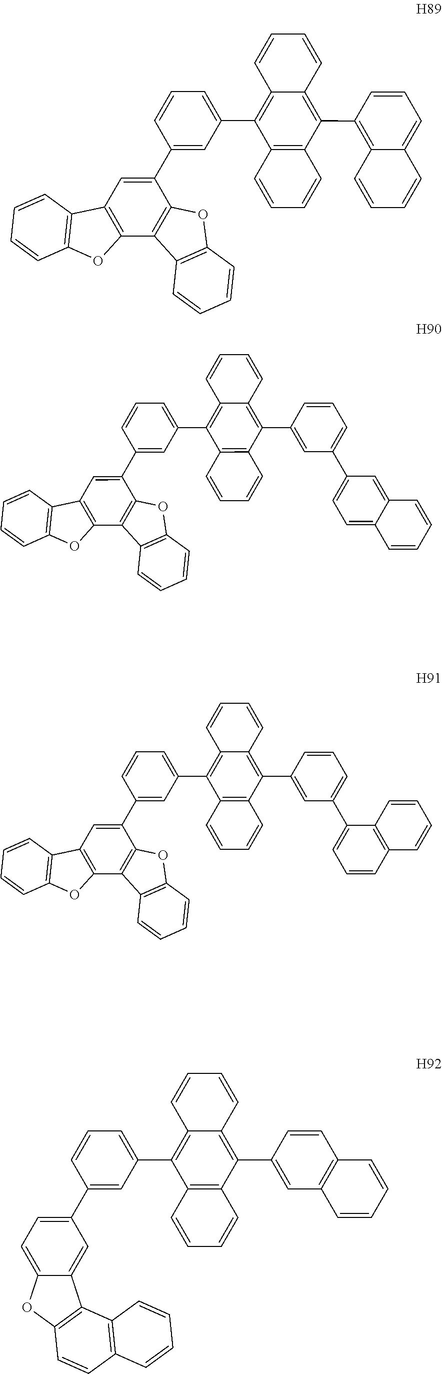 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

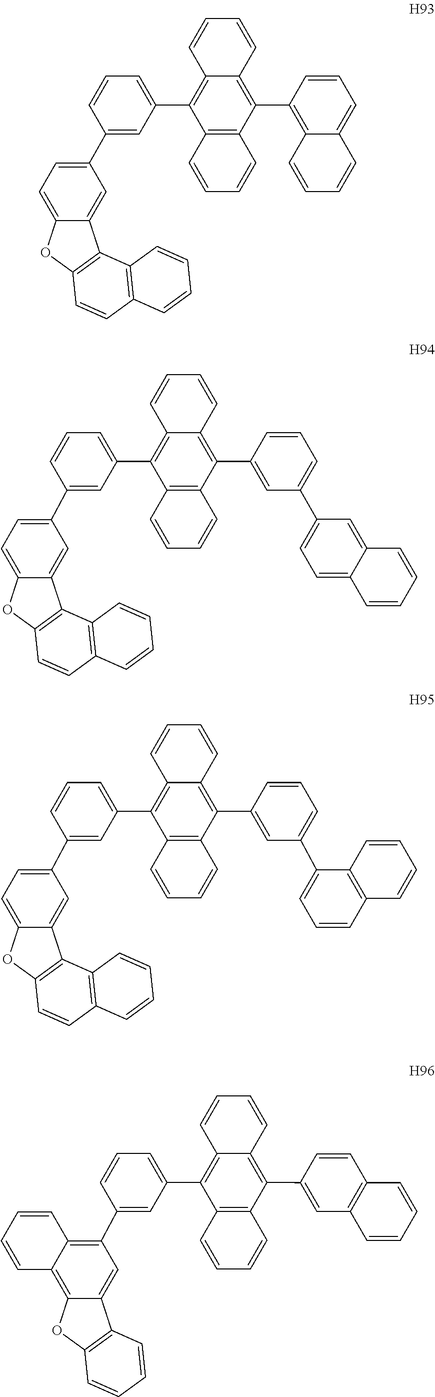 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

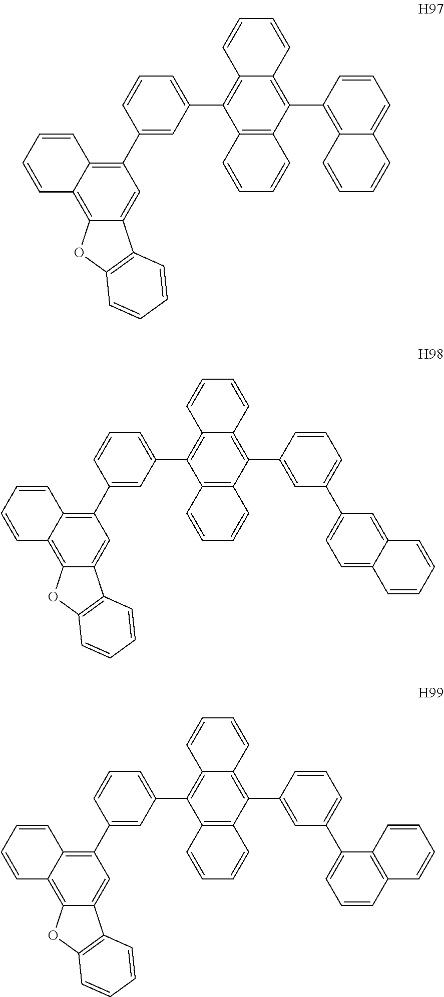 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

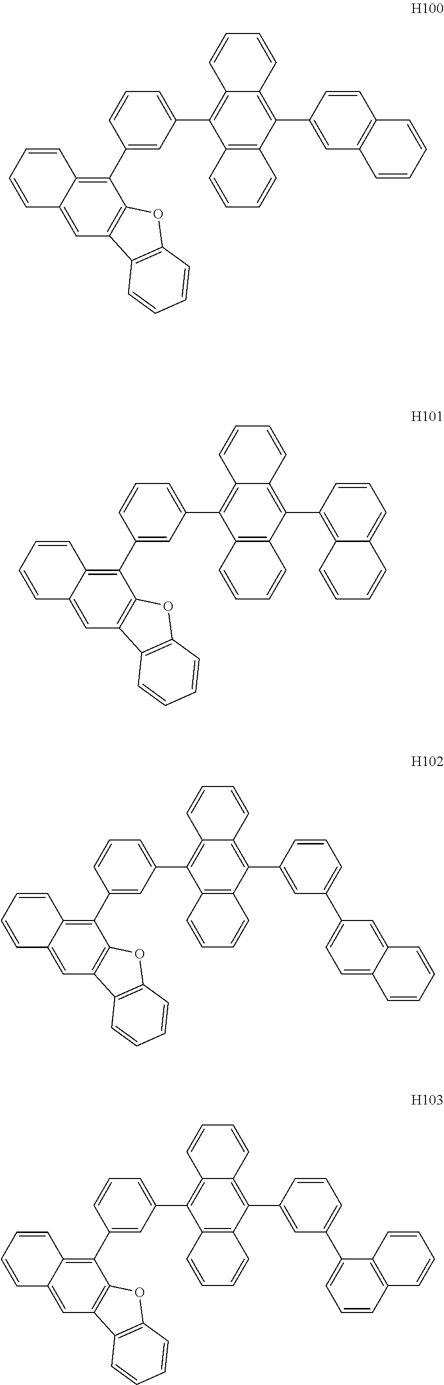 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

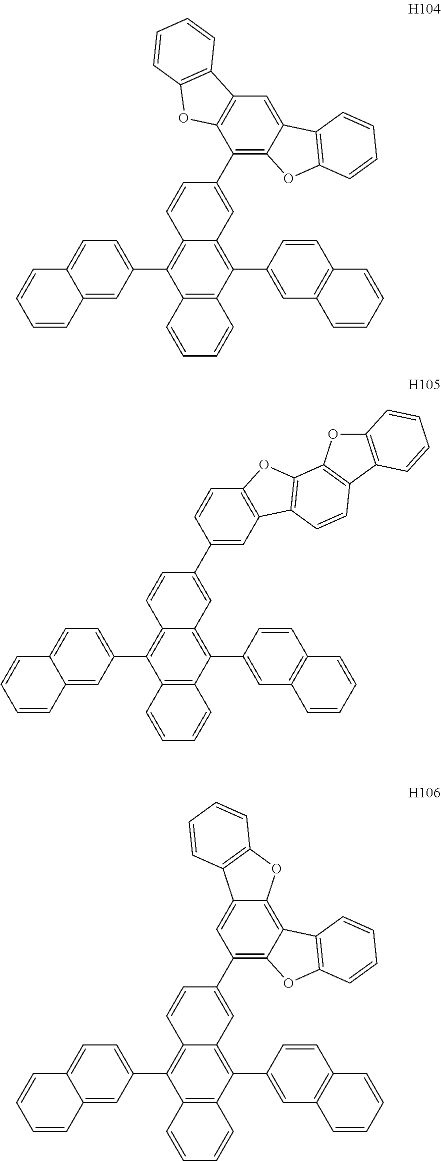 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

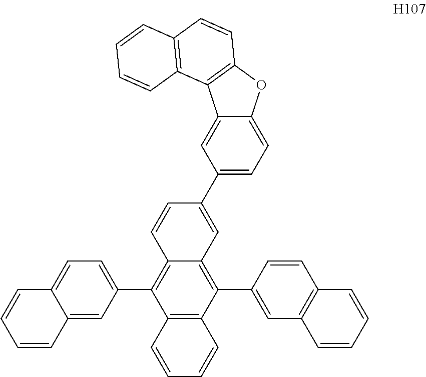 [SMILES: c1ccc2cc(-c3c4ccccc4c(-c4ccc5ccccc5c4)c4cc(-c5ccc6oc7ccc8ccccc8c7c6c5)ccc34)ccc2c1]

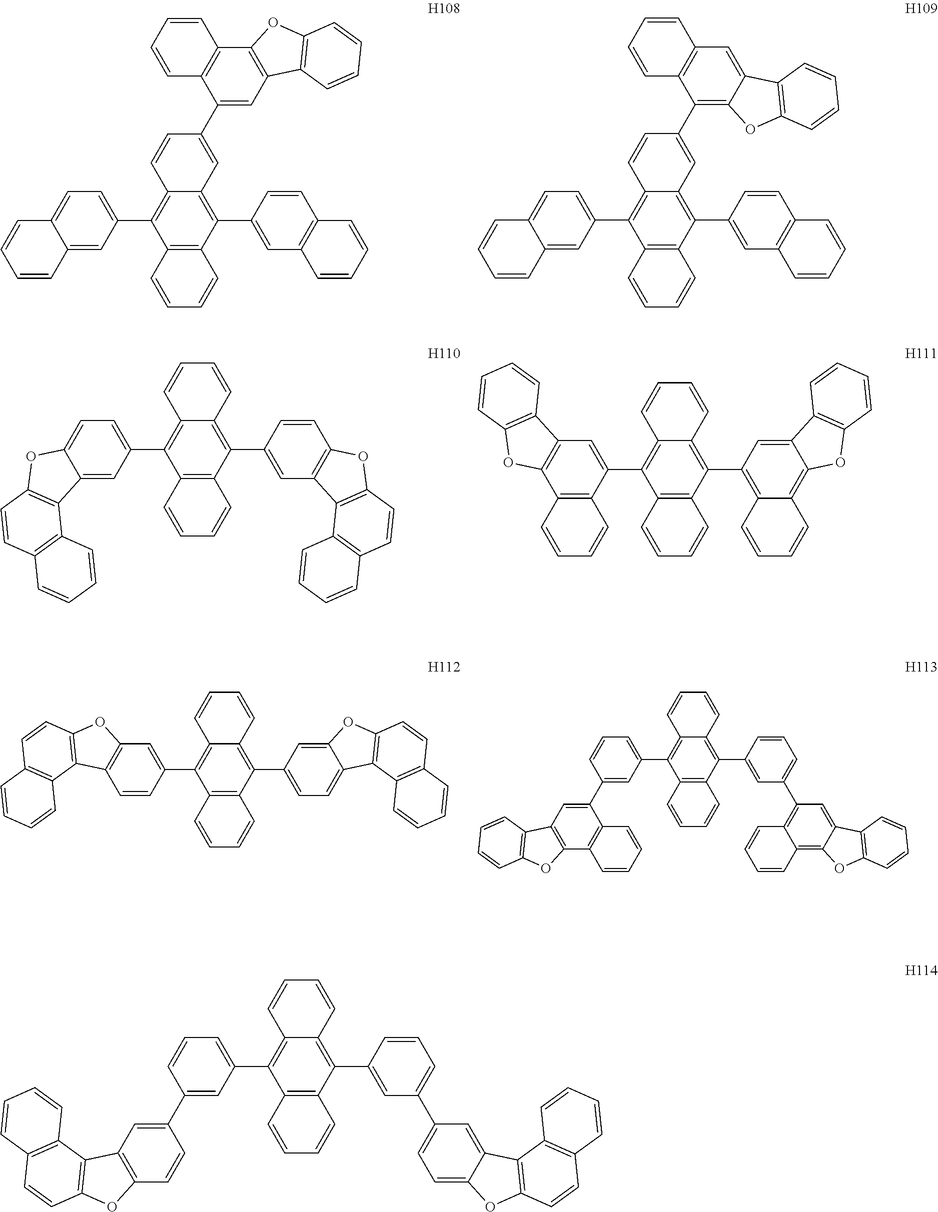

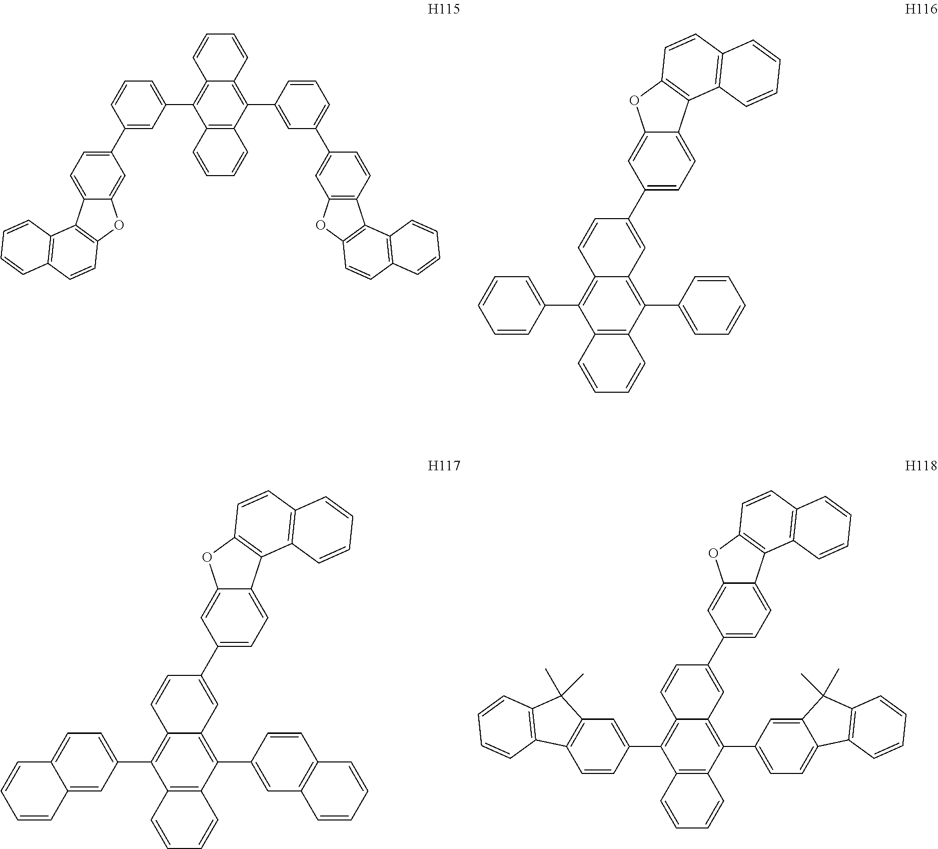 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

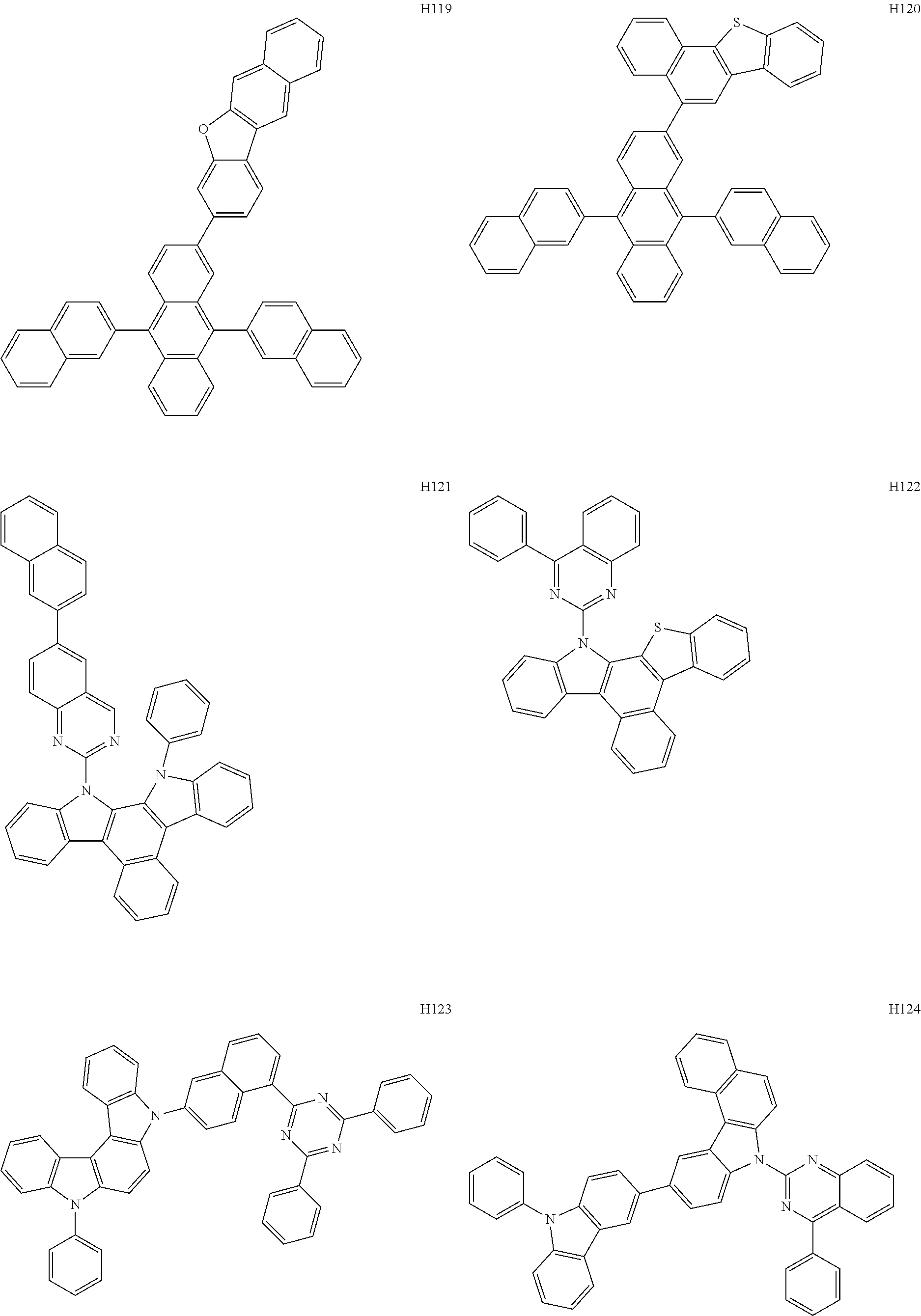

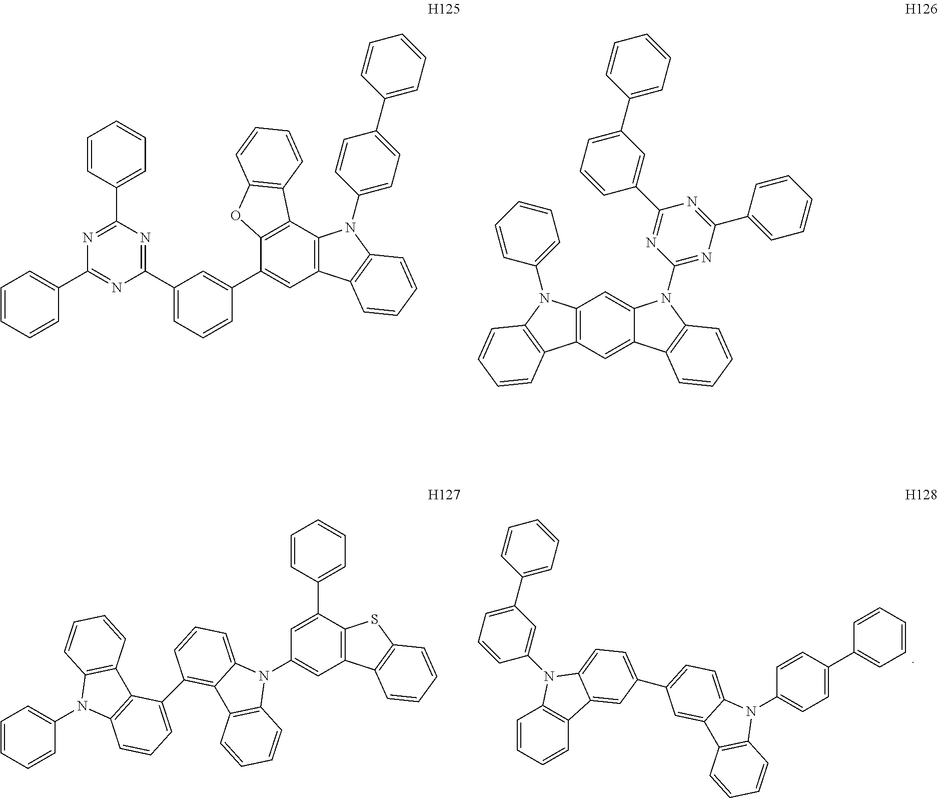 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

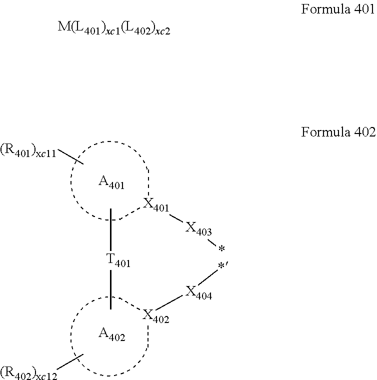

wherein, in Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more L₄₀₁(s) may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)*′, *—C(Q₄₁₁)(Q₄₁₂)-*′, *—C(Q₄₁₁)═C(Q₄₁₂)*′, *13 C(Q₄₁₁)=*′, or *=C═*′,
X₄₀₃ and X₄₀₄ may each independently be a chemical bond (e.g., a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be as described in connection with Q₁, R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be as described in connection with Q₁,
xc11 and xc12 may each independently be an integer from 0 to 10, and
* and *′ in Formula 402 each indicate a binding site to M in Formula 401.

For example, in Formula 402, i) X₄₀₁ may be nitrogen and X₄₀₂ may be carbon, or ii) each of X₄₀₁ and X₄₀₂ may be nitrogen.

In an embodiment, when xc1 in Formula 401 is 2 or more, two ring A₄₀₁(s) among two or more of L₄₀₁ may optionally be linked to each other via T₄₀₂, which is a linking group, and two ring A₄₀₂(s) among two or more of L₄₀₁ may optionally be linked to each other via T₄₀₃, which is a linking group (see Compounds PD1 to PD4 and PD7). T₄₀₂ and T₄₀₃ may each be as described in connection with T₄₀₁.

In Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, a —CN group, a phosphorus group (e.g., a phosphine group, a phosphite group, or the like), or any combination thereof.

The phosphorescent dopant may include, for example, one of Compounds PD1 to PD39, or any combination thereof:

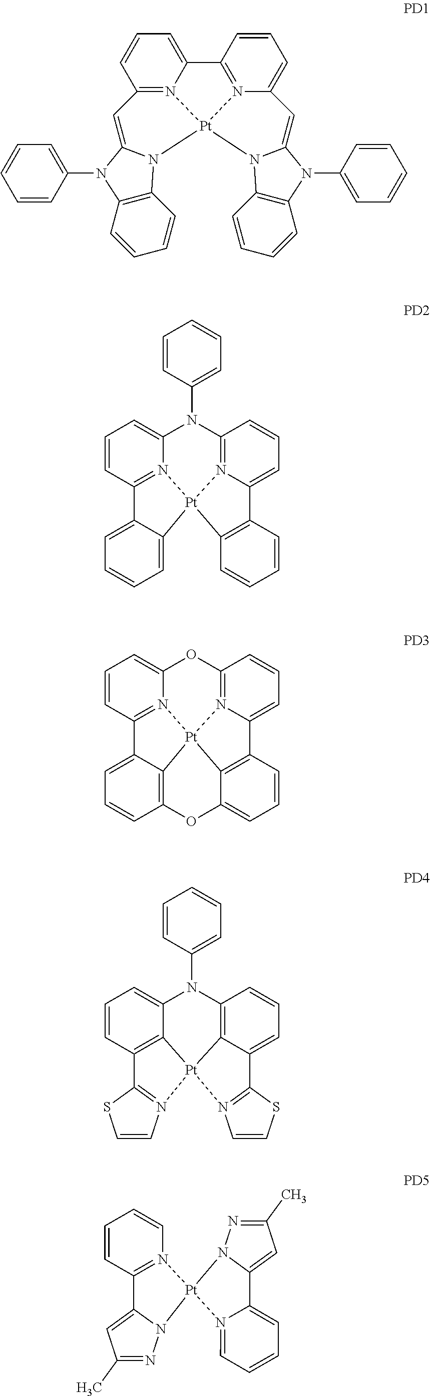

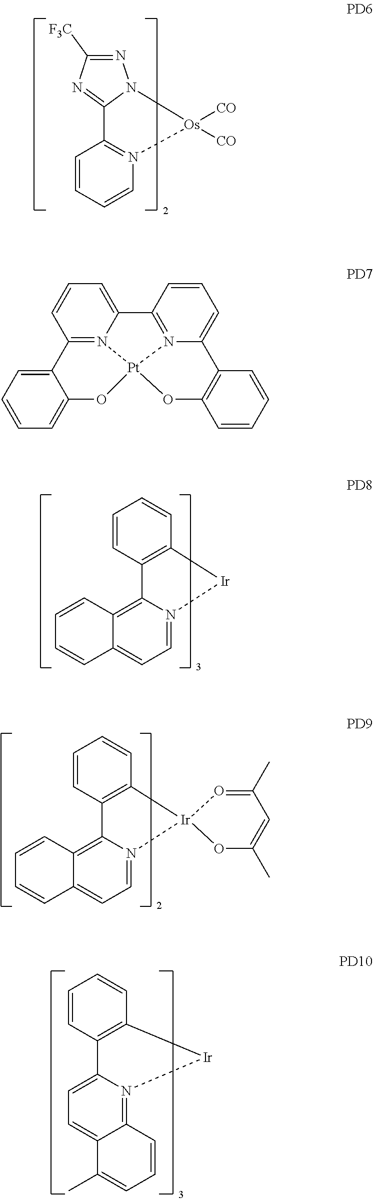

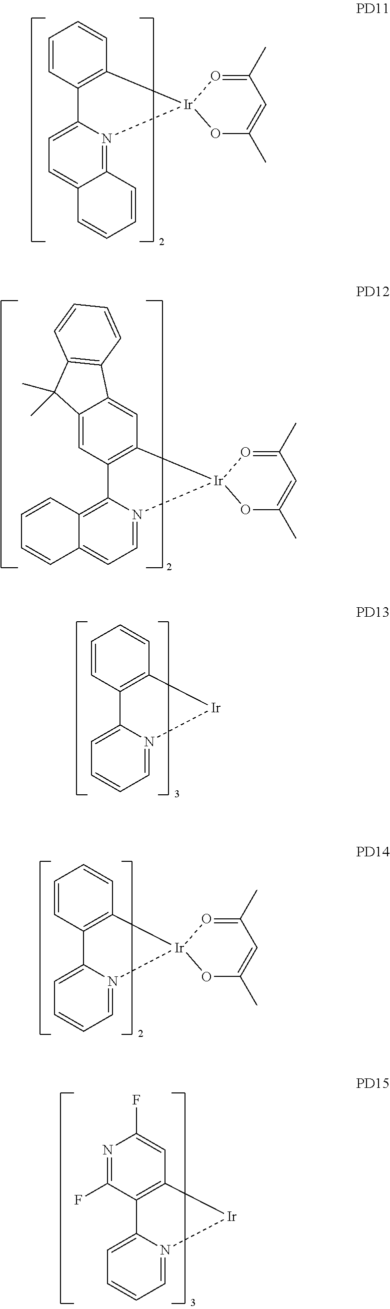

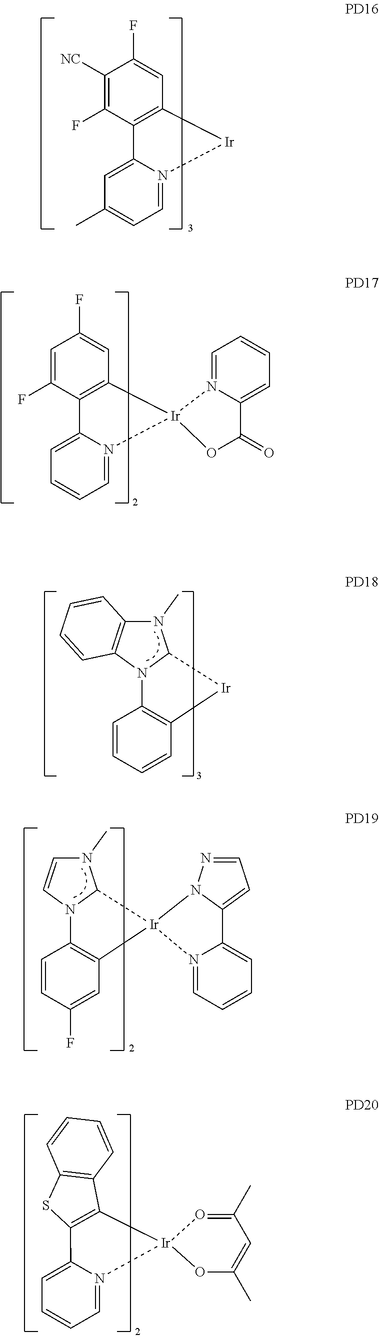

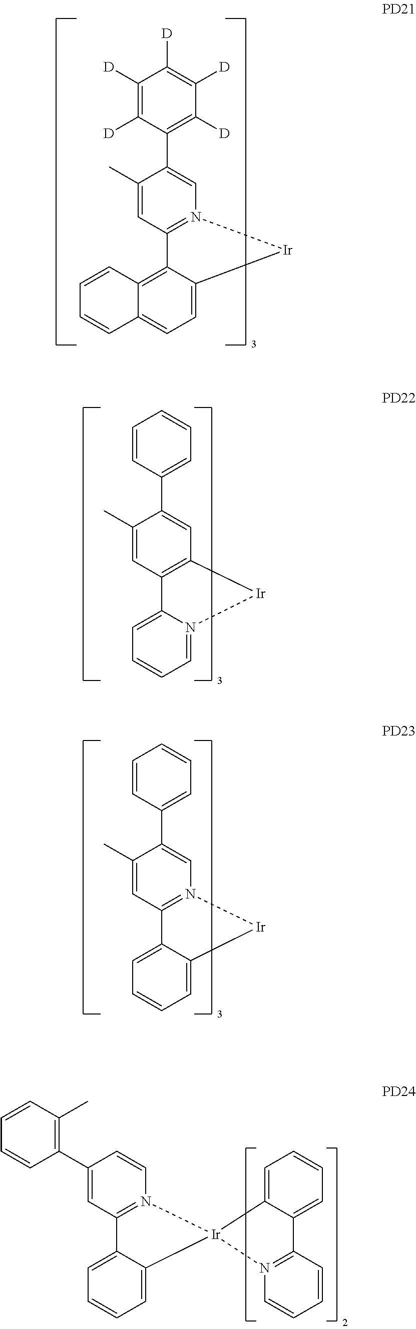

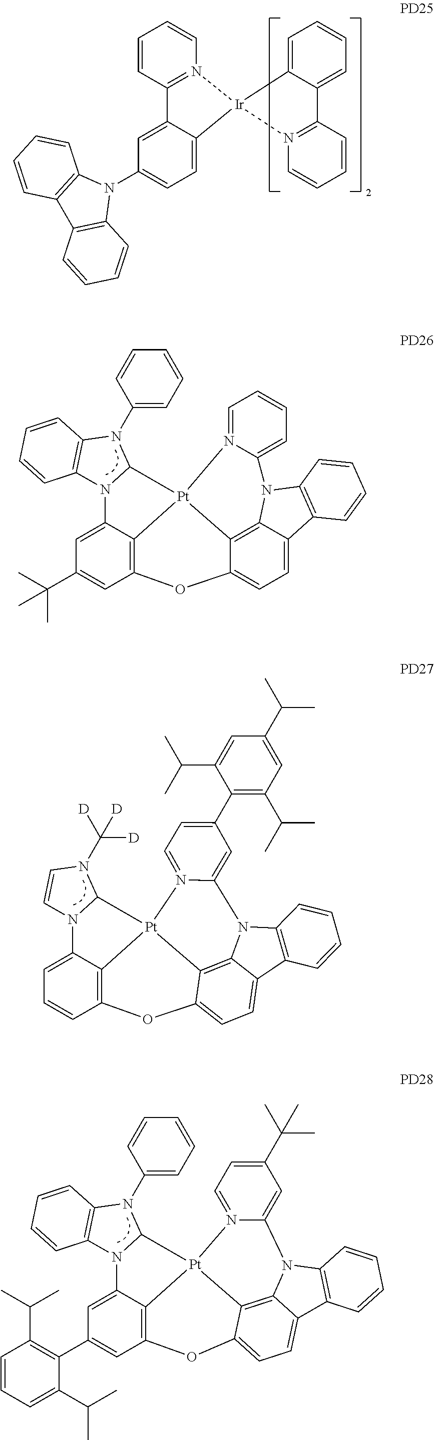

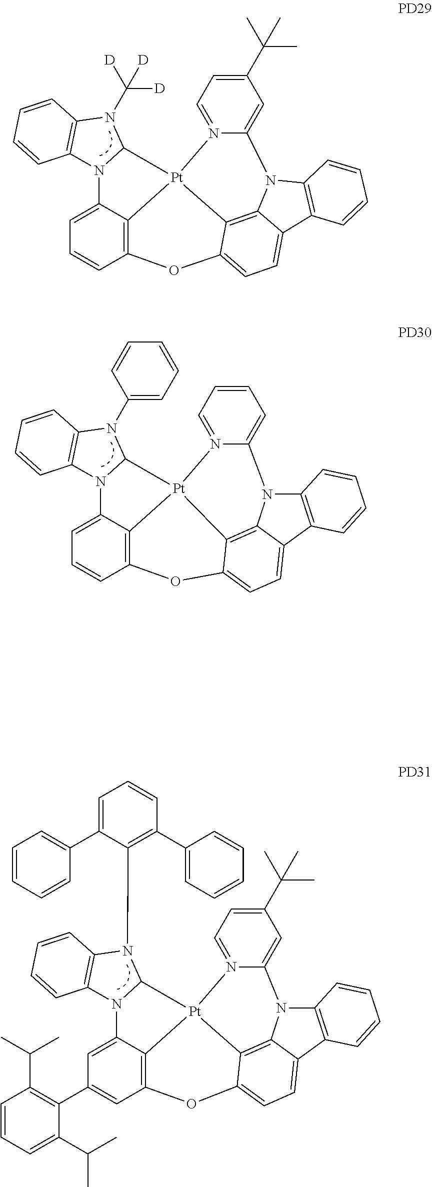

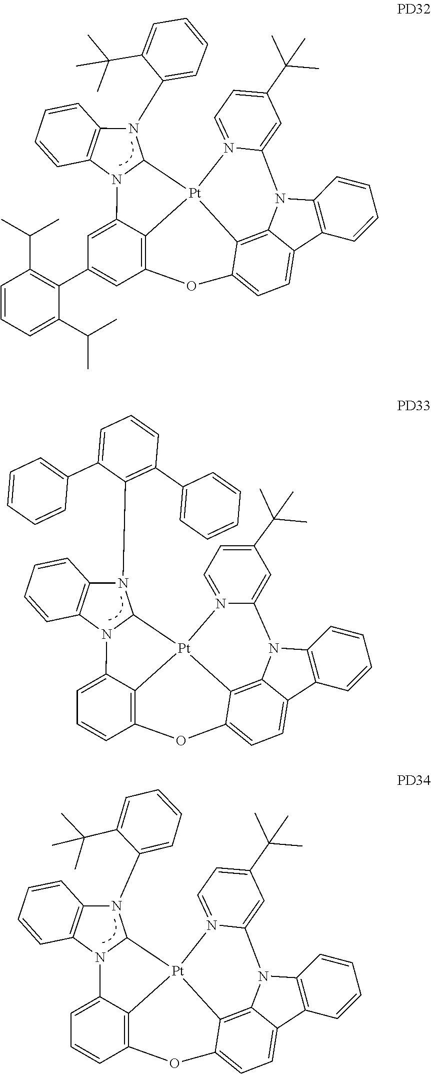

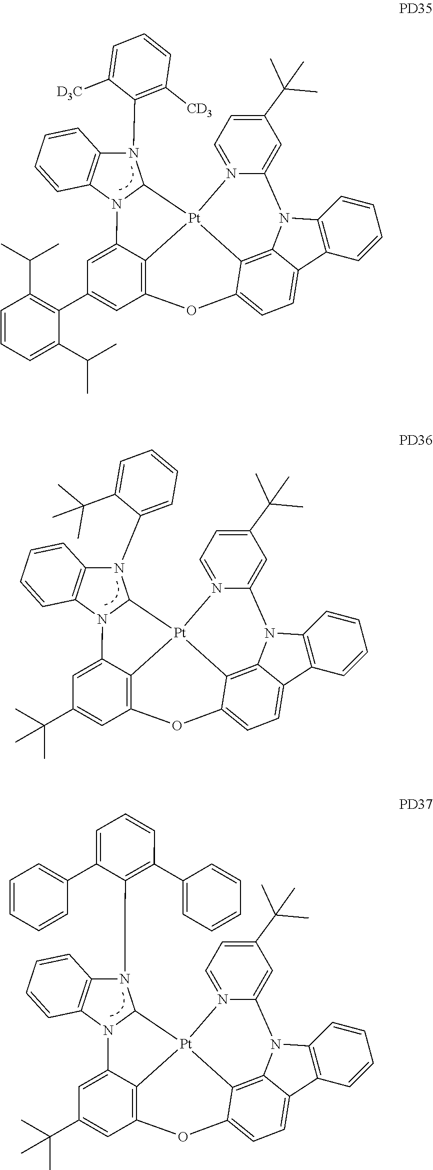

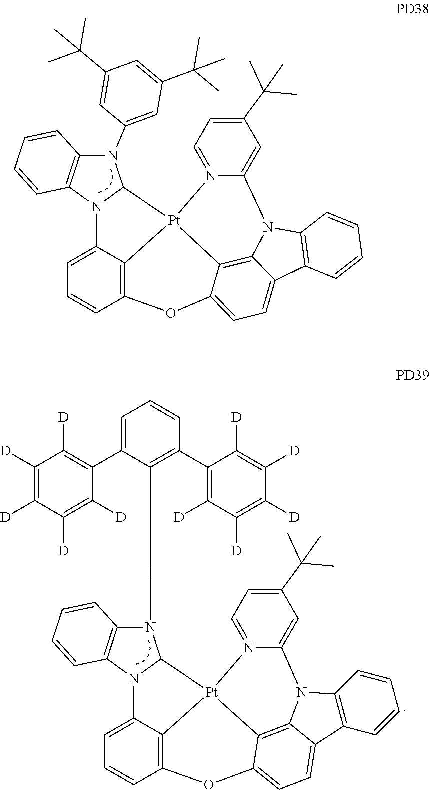

### [Fluorescent Dopant]

The fluorescent dopant may include an amine group-containing compound, a styryl group-containing compound, or any combination thereof.

For example, the fluorescent dopant may include a compound represented by Formula 501:

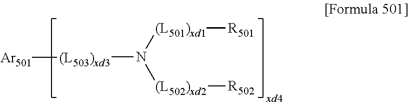

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, Ar₅₀₁ in Formula 501 may be a condensed cyclic group (e.g., an anthracene group, a chrysene group, a pyrene group, or the like) in which three or more monocyclic groups are condensed with each other.

For example, xd4 in Formula 501 may be 2.

For example, the fluorescent dopant may include: one of Compounds FD1 to FD37; DPVBi; DPAVBi; or any combination thereof:

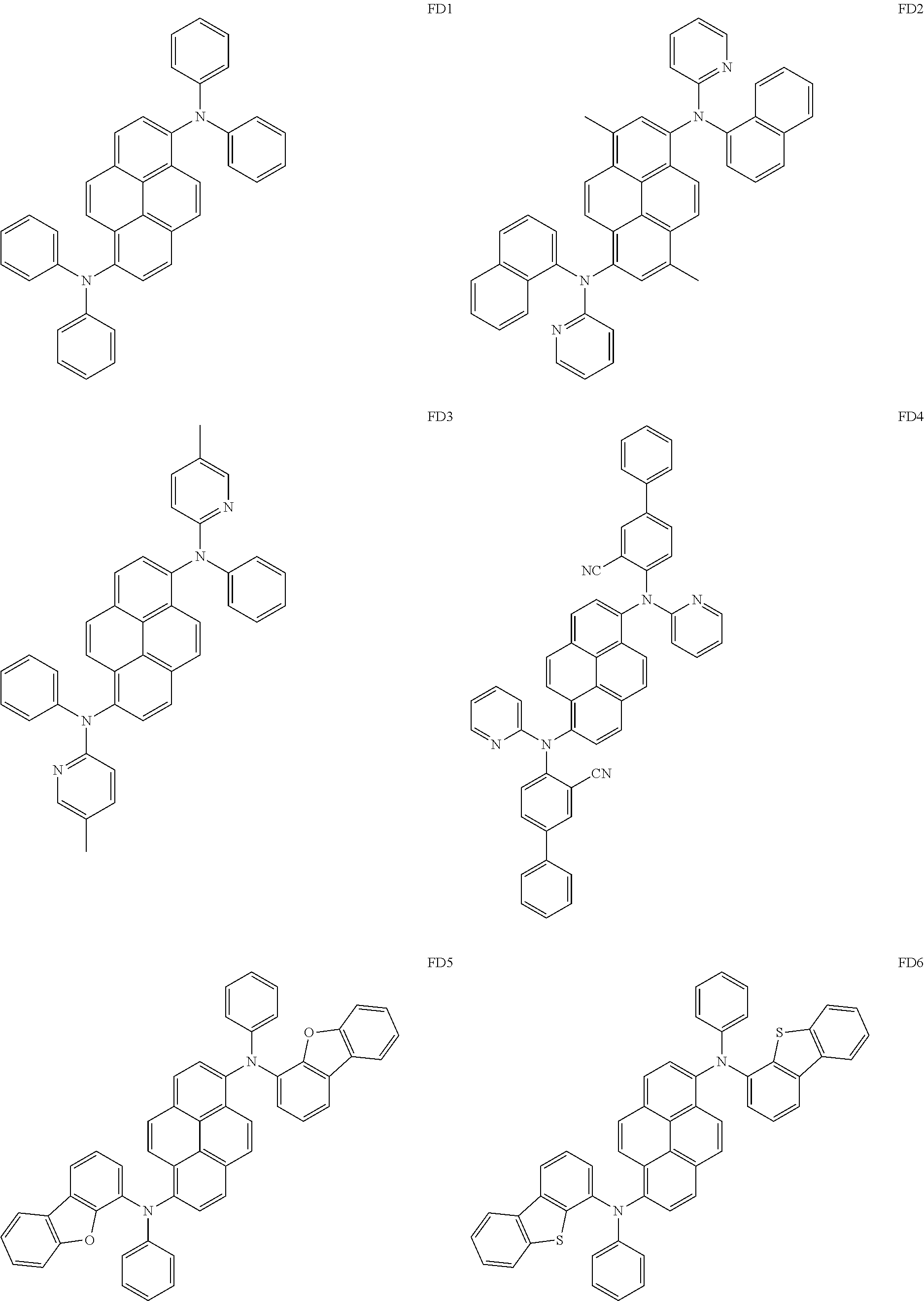

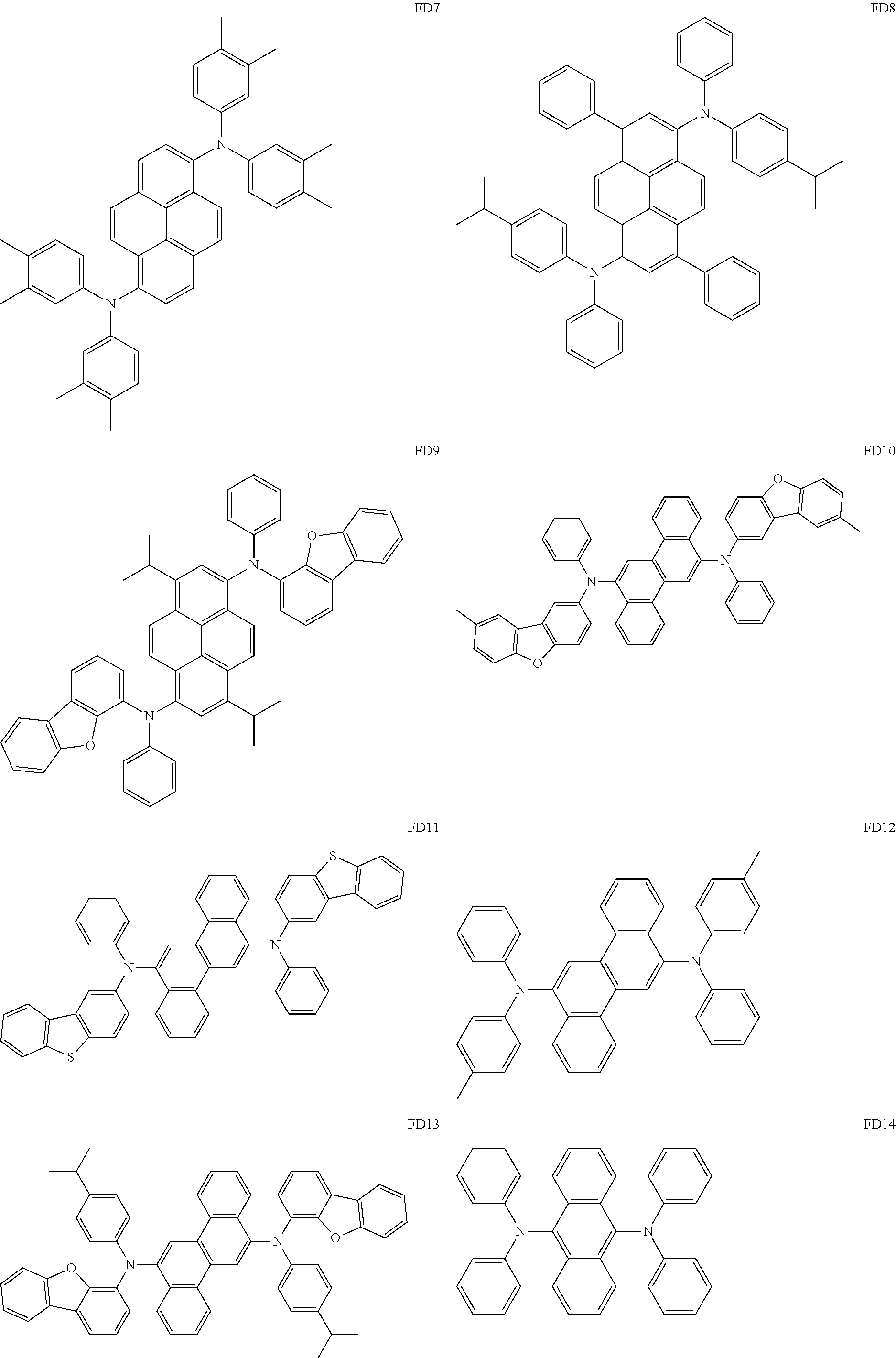

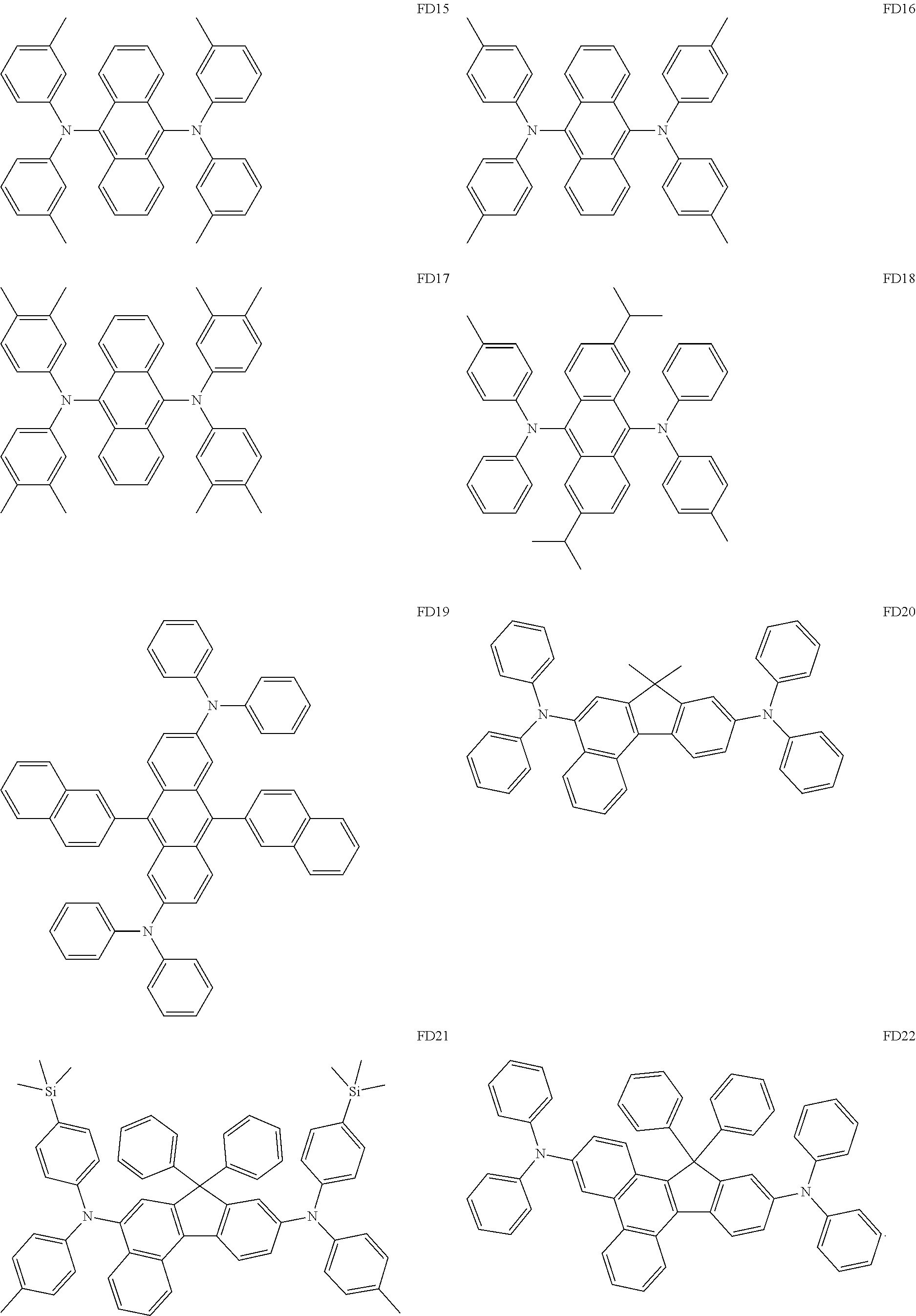

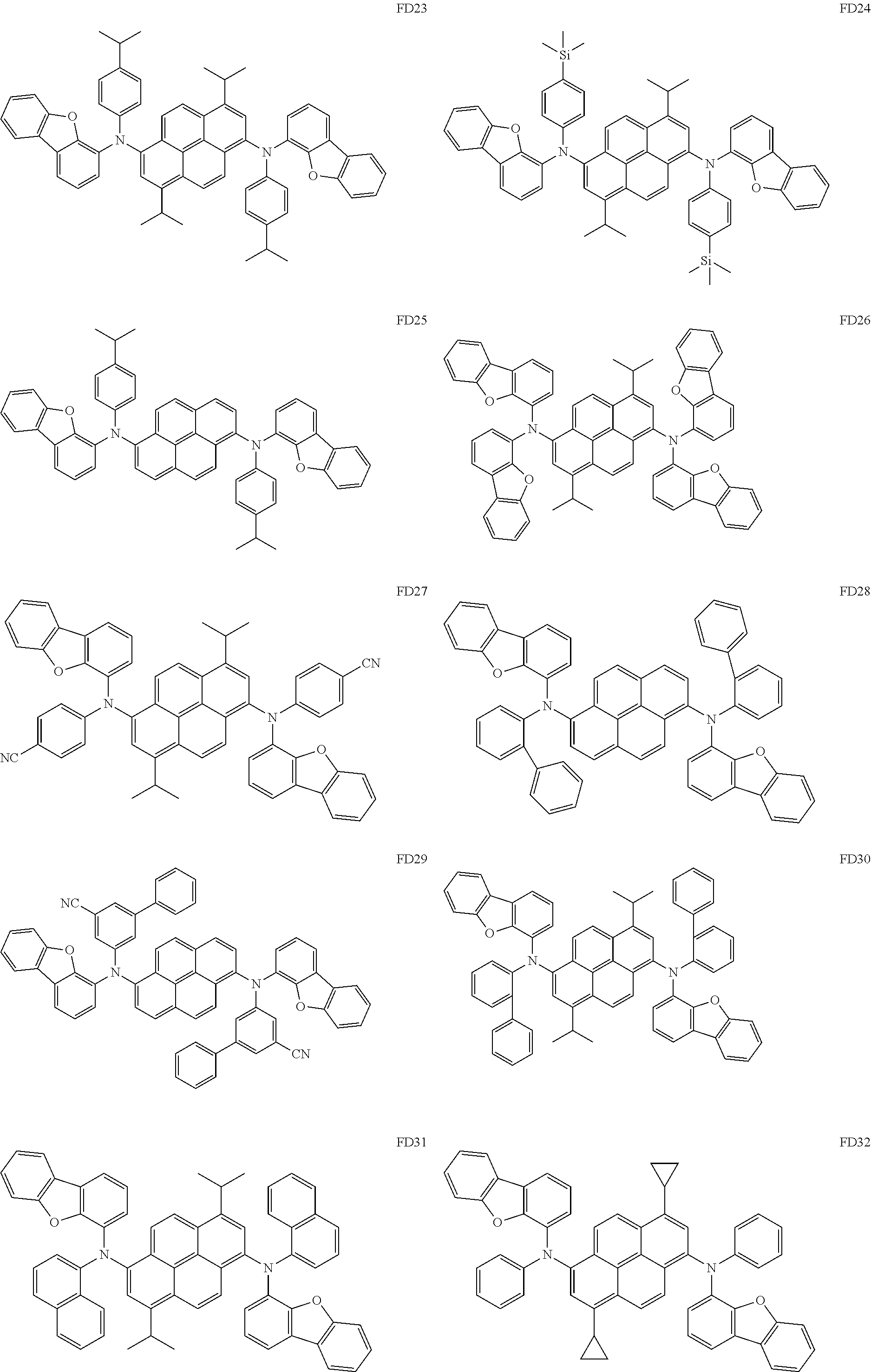

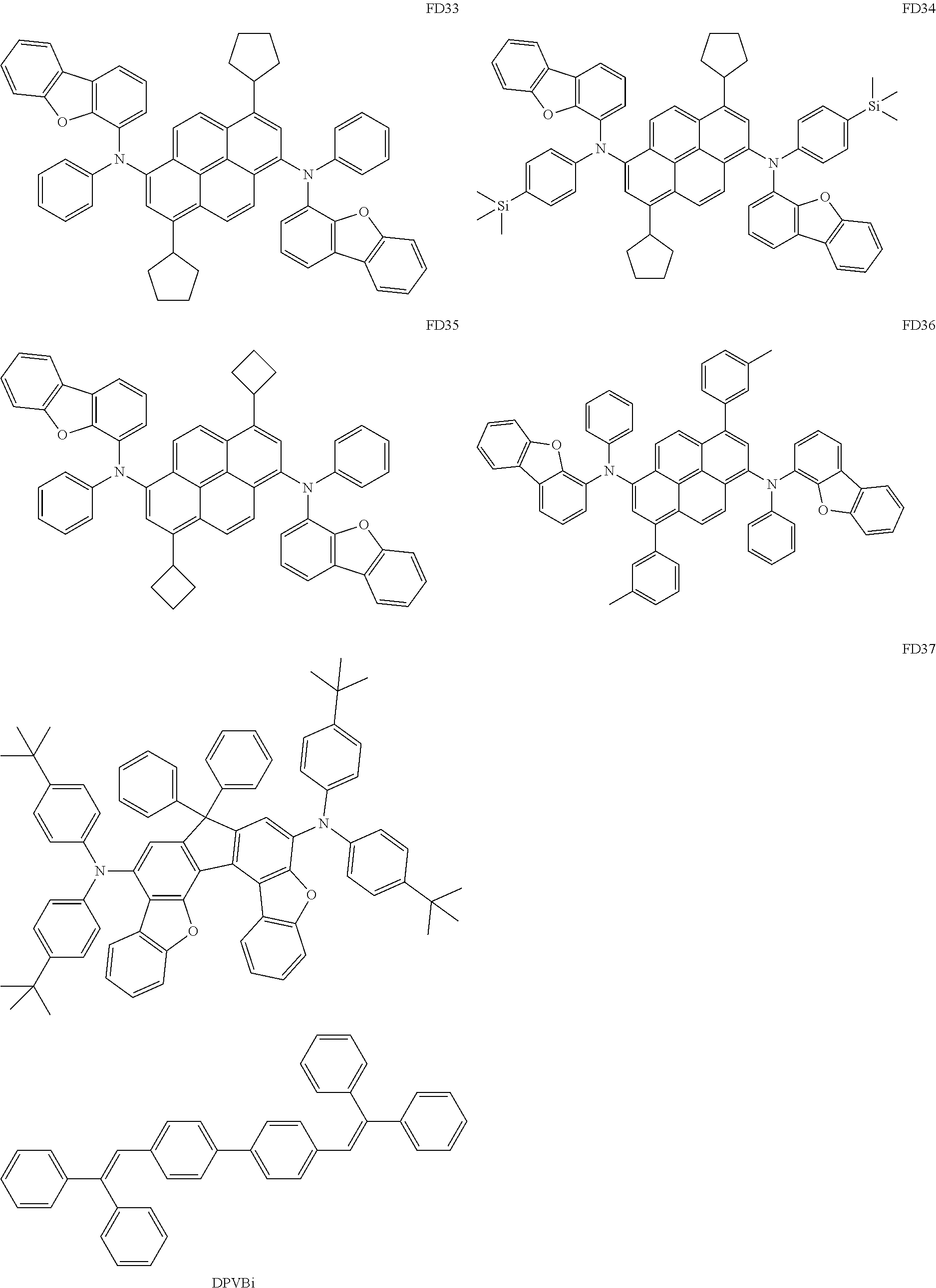

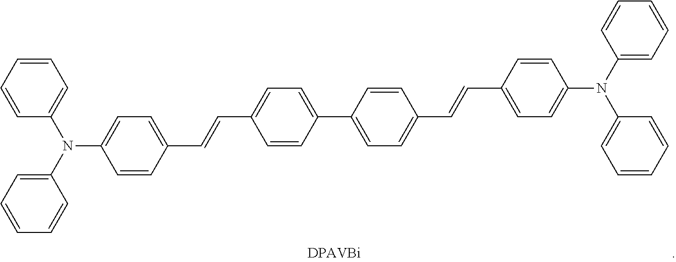 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

[Delayed fluorescence material]

The emission layer 130 may include a delayed fluorescence material.

The delayed fluorescence material described herein may be selected from compounds capable of emitting delayed fluorescence based on a delayed fluorescence emission mechanism.

The delayed fluorescence material included in the emission layer 130 may act as a host or a dopant, depending on the type of other materials included in the emission layer 130.

In an embodiment, a difference between a triplet energy level (eV) of the delayed fluorescence material and a singlet energy level (eV) of the delayed fluorescence material may be in a range of about 0 eV to about 0.5 eV. In an example in which the difference between the triplet energy level (eV) of the delayed fluorescence material and the singlet energy level (eV) of the delayed fluorescence material is satisfied within the described range, up-conversion from the triplet state to the singlet state of the delayed fluorescence materials may effectively occur, and thus, the light-emitting device 11 may have improved luminescence efficiency.

For example, the delayed fluorescence material may include i) a material including at least one electron donor (e.g., a π electron-rich C₃-C₆₀ cyclic group, such as, for example, a carbazole group, or the like) and at least one electron acceptor (e.g., a sulfoxide group, a cyano group, a π electron-deficient nitrogen-containing C₁-C₆₀ cyclic group, or the like), and ii) a material including a C₈-C₆₀ polycyclic group in which two or more cyclic groups are condensed with each other while sharing B.

Examples of the delayed fluorescence material may include at least one of Compounds DF1 to DF14:

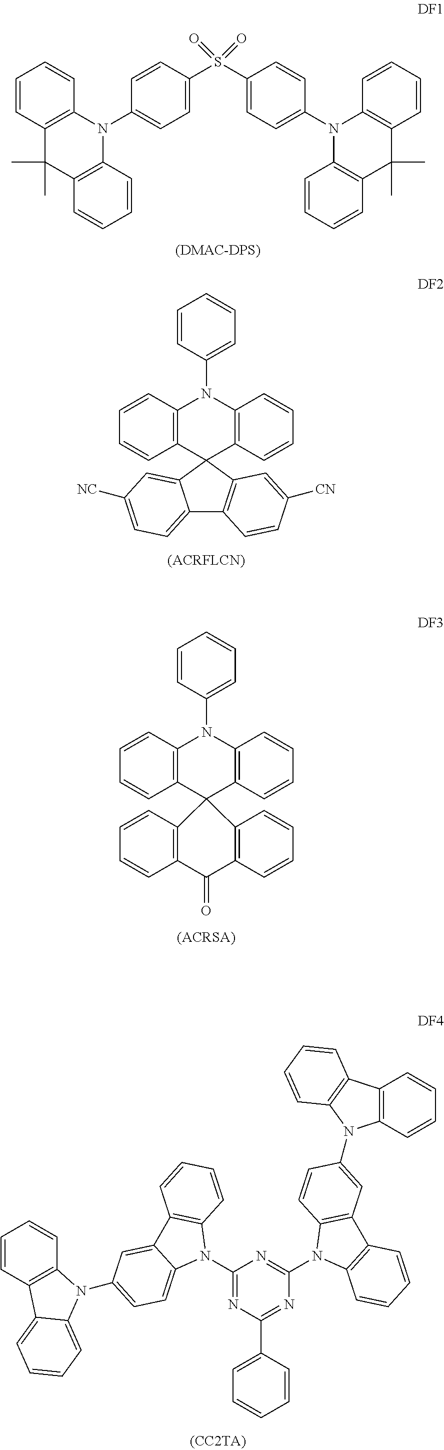

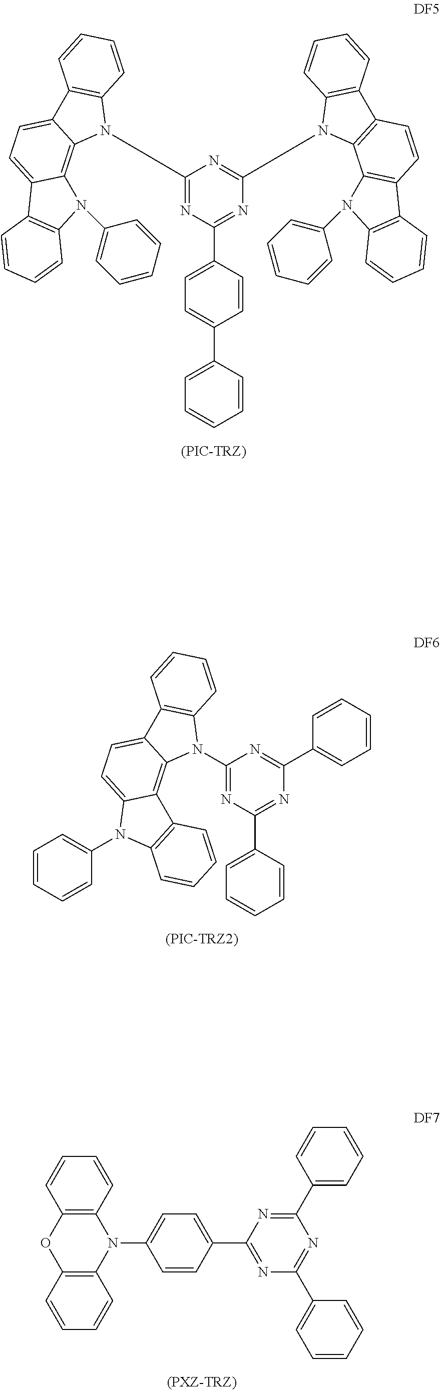 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

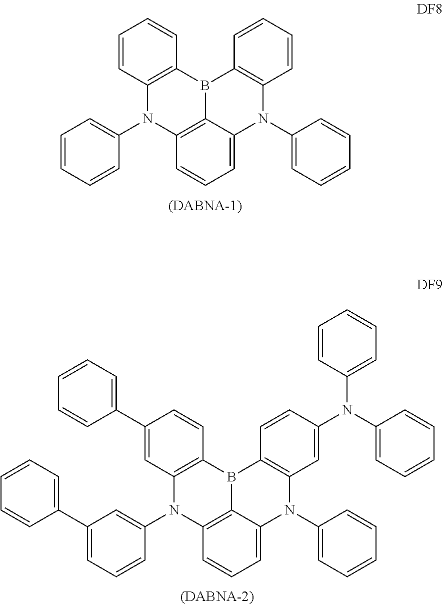

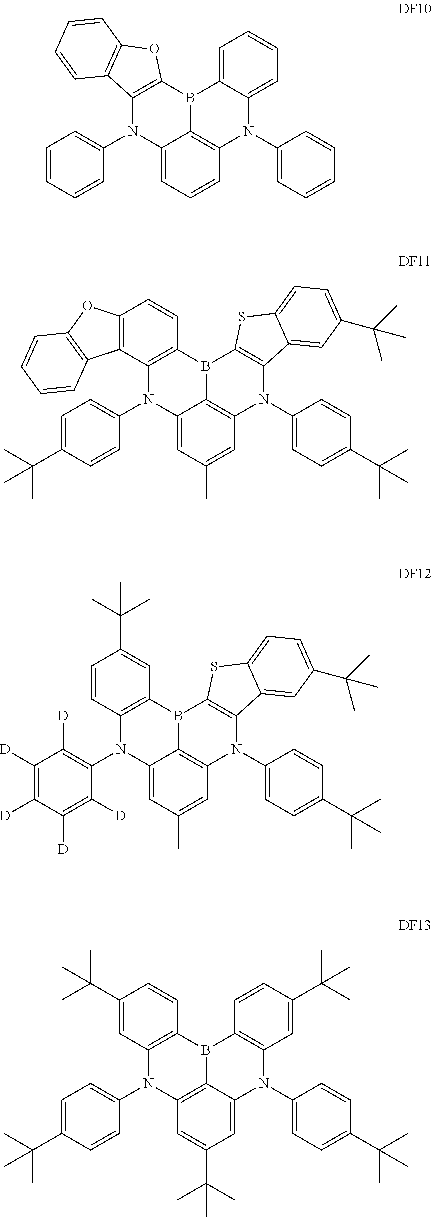

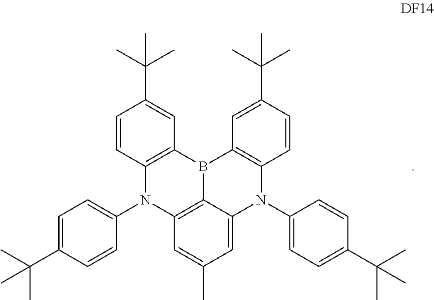 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### [Quantum Dots]

The emission layer 130 may include quantum dots.

In the specification, quantum dots refer to crystals of a semiconductor compound. Quantum dots may emit light of various emission wavelengths depending on the size of crystals. Quantum dots may emit light of various emission wavelengths by adjusting a ratio of elements constituting the quantum dots.

A diameter of the quantum dot may be, for example, in a range of about 1 nm to about 10 nm.

The quantum dots may be synthesized by a wet chemical process, a metal organic chemical vapor deposition process, a molecular beam epitaxy process, or any process similar thereto.

The wet chemical process is a method including mixing a precursor material with an organic solvent and then growing quantum dot particle crystals. In an example in which the crystals grow, the organic solvent naturally acts as a dispersant coordinated on the surface of the quantum dot crystals and controls the growth of the crystals such that the growth of quantum dot particles may be controlled through a process which costs lower and is easier than vapor deposition methods, such as, for example, metal organic chemical vapor deposition (MOCVD) or molecular beam epitaxy (MBE).

The quantum dots may include: a Group II-VI semiconductor compound; a Group III-V semiconductor compound; a Group III-VI semiconductor compound; a Group I—III-VI semiconductor compound; a Group IV-VI semiconductor compound; a Group IV element or compound; or any combination thereof.

Examples of the Group II-VI semiconductor compound may include: a binary compound, such as, for example, CdS, CdSe, CdTe, ZnS, ZnSe, ZnTe, ZnO, HgS, HgSe, HgTe, MgSe, MgS, and the like; a ternary compound, such as, for example, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as, for example, CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of the Group III-V semiconductor compound may include: a binary compound, such as, for example, GaN, GaP, GaAs, GaSb, AlN, AlP, AlAs, AlSb, InN, InP, InAs, InSb, or the like; a ternary compound, such as, for example, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or the like; a quaternary compound, such as, for example, GaAlNP, GaAlNAs, GaAlNSb, GaAlPAs, GaAlPSb, GaInNP, GaInNAs, GaInNSb, GaInPAs, GalnPSb, InAlNP, InAlNAs, InAlNSb, InAlPAs, InAlPSb, or the like; or any combination thereof. In some embodiments, the Group III-V semiconductor compound may further include a Group II element. Examples of the Group III-V semiconductor compound further including a Group II element may include InZnP, InGaZnP, InAlZnP, and the like.

Examples of the Group III-VI semiconductor compound are: a binary compound, such as, for example, GaS, Ga₂Se₃, GaTe, InS, InSe, In₂S₃, In₂Se₃, InTe, or the like; a ternary compound, such as, for example, InGaS₃, InGaSe₃, or the like; or any combination thereof.

Examples of the Group I-III-VI semiconductor compound may include: a ternary compound, such as, for example, AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, or the like; a quaternary compound, such as, for example, CuInGaS, CuInGaS₂, AgInGaS, AgInGaS₂, AgInGaSe, AgInGaSe₂, or the like; or any combination thereof.

Examples of the Group IV-VI semiconductor compound may include: a binary compound, such as, for example, SnS, SnSe, SnTe, PbS, PbSe, or PbTe; a ternary compound, such as, for example, SnSeS, SnSeTe, SnSTe, PbSeS, PbSeTe, PbSTe, SnPbS, SnPbSe, SnPbTe, or the like; a quaternary compound, such as, for example, SnPbSSe, SnPbSeTe, SnPbSTe, or the like; or any combination thereof.

The Group IV element or compound may include: a single element, such as, for example, Si, Ge, or the like; a binary compound, such as, for example, SiC, SiGe, or the like; or any combination thereof.

Each element included in a multi-element compound, such as, for example, the binary compound, the ternary compound, and the quaternary compound, may be present at a uniform concentration or non-uniform concentration in a particle. That is, the formulae above refer to types of elements included in the compound, and the element ratios within the compound may vary. For example, AgInGaS₂ may refer to AgInₓGa₁₋ₓS₂ (where x is a real number between 0 and 1).

In one or more embodiments, the quantum dots may have a single structure in which the concentration of each element in the quantum dots is uniform, or a core-shell dual structure. For example, materials included in the core and materials included in the shell may be different from each other.

The shell of the quantum dots may act as a protective layer that prevents chemical degeneration of the core to maintain semiconductor characteristics, and/or as a charging layer that imparts electrophoretic characteristics to the quantum dots. The shell may be single-layered or multi-layered. The interface between the core and the shell may have a concentration gradient in which the concentration of an element existing in the shell decreases toward the center of the core.

Examples of the shell of the quantum dots may include: an oxide of metal or non-metal; a semiconductor compound: or any combination thereof. Examples of the oxide of metal or non-metal may include: a binary compound, such as, for example, SiO₂, Al₂O₃, TiO₂, ZnO, MnO, Mn₂O₃, Mn₃O₄, CuO, FeO, Fe₂O₃, Fe₃O₄, CoO, C₀₃₀₄, NiO, or the like; a ternary compound, such as, for example, MgAl₂O₄, CoFe₂O₄, NiFe₂O₄, CoMn₂O₄, or the like; or any combination thereof. Examples of the semiconductor compound are: as described herein, Group III-VI semiconductor compounds; Group II-VI semiconductor compounds; Group III-V semiconductor compounds; Group I-III-VI semiconductor compounds; Group IV-VI semiconductor compounds; or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

A full width of half maximum (FWHM) of an emission wavelength spectrum of the quantum dots may be about 45 nm or less, for example, about 40 nm or less, and for example, about 30 nm or less, and within these ranges, the color purity or color reproducibility of the quantum dots may be improved. In some aspects, since light emitted through the quantum dots is emitted in all directions, the wide viewing angle may be improved.

In some aspects, the quantum dots may be nanoparticles, nanotubes, nanowires, nanofibers, nanoplates, and the like, specifically in the form of spherical particles, pyramidal particles, multi-arm particles, or cubic particles.

Since the energy band gap may be controlled by adjusting the size of the quantum dots or the ratio of elements in the quantum dot compound, light of various wavelengths may be obtained from the quantum dot-containing emission layer. Therefore, by using the aforementioned quantum dots (using quantum dots of different sizes or having different element ratios in the quantum dot compound), a light-emitting device emitting light of various wavelengths may be implemented. In detail, the control of the size of the quantum dots or the ratio of elements in the quantum dot compound may be selected to emit red light, green light, and/or blue light. In some aspects, the size of the quantum dots may be configured to emit white light by combination of light of various colors.

### [Electron Transport Region 140]

The electron transport region 140 may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The electron transport region 140 may include a buffer layer, a hole blocking layer, an electron control layer, an electron transport layer, an electron injection layer, or any combination thereof.

For example, the electron transport region 140 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein layers in each structure may be sequentially stacked from the emission layer 130.

In an embodiment, the electron transport region 140 (e.g., the buffer layer, the hole blocking layer, the electron control layer, or the electron transport layer in the electron transport region) may include a metal-free compound including at least one π electron-deficient nitrogen-containing C₁-C₆₀ cyclic group.

For example, the electron transport region 140 may include a compound represented by Formula 601:

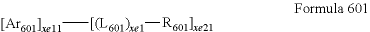

wherein, in Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be as described in connection with Q₁,
xe21 may be 1, 2, 3, 4, or 5, and
at least one of Ar₆₀₁, L₆₀₁, and R₆₀₁ may each independently be a rr electron-deficient nitrogen-containing C₁-C₆₀ cyclic group unsubstituted or substituted with at least one R₁₀ₐ.

In an example in which xe11 in Formula 601 is 2 or more, two or more of Ar₆₀₁ may be linked to each other via a single bond.

In an embodiment, Ar₆₀₁ in Formula 601 may be an anthracene group that is unsubstituted or substituted with at least one R₁₀ₐ.

In one or more embodiments, the electron transport region 140 may include a compound represented by Formula 601-1:

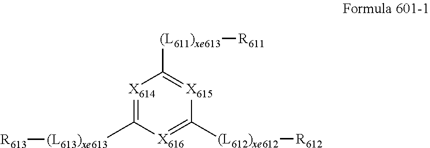

wherein, in Formula 601-1,
X₆₁₄ may be N or C(R₆₁₄), X₆₁₅ may be N or C(R₆₁₅), and X₆₁₆ may be N or C(R₆₁₆), wherein at least one of X₆₁₄ to X₆₁₆ may be N,
L₆₁₁ to L₆₁₃ may each be as described in connection with L₆₀₁,
xe611 to xe613 may each be as described in connection with xe1,
R₆₁₁ to R₆₁₃ may each be as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, xe1 and xe611 to xe613 in Formulae 601 and 601-1 may each independently be 0, 1, or 2.

The electron transport region 140 may include: one of Compounds ET1 to ET45; 2,9-dimethyl-4,7-diphenyl-1,10-phenanthroline (BCP); 4,7-diphenyl-1,10-phenanthroline (Bphen); Alq₃; BAlq; TAZ; NTAZ; or any combination thereof:

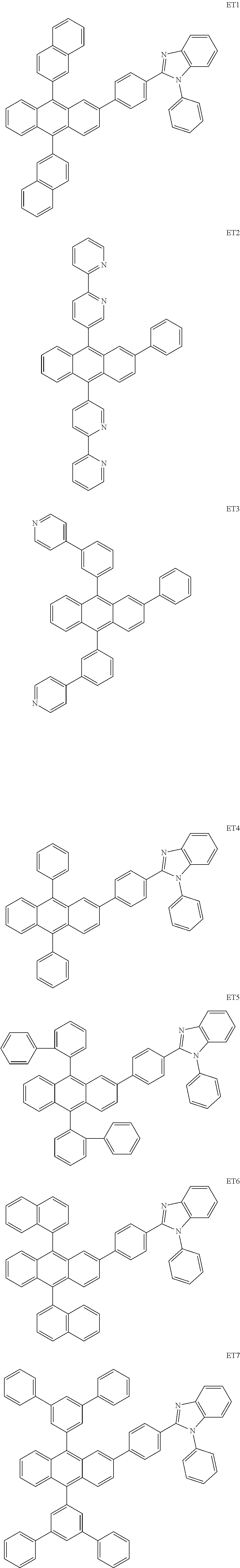

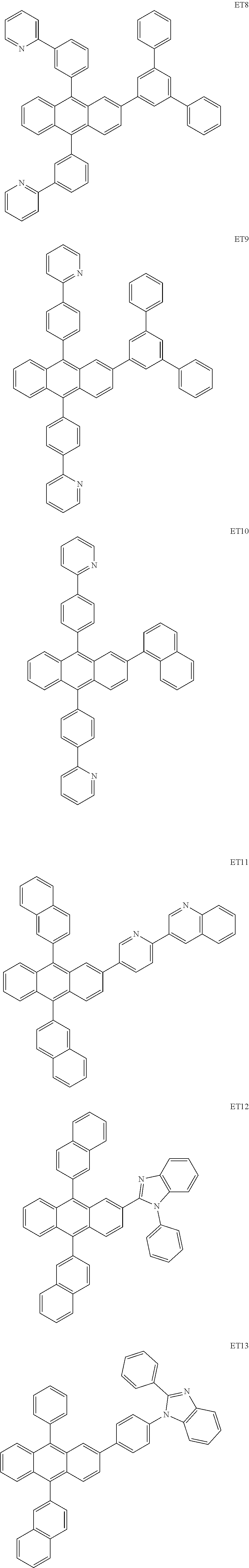

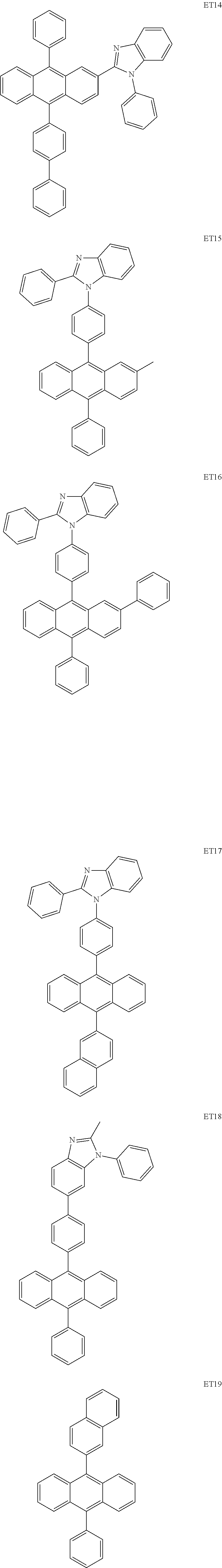

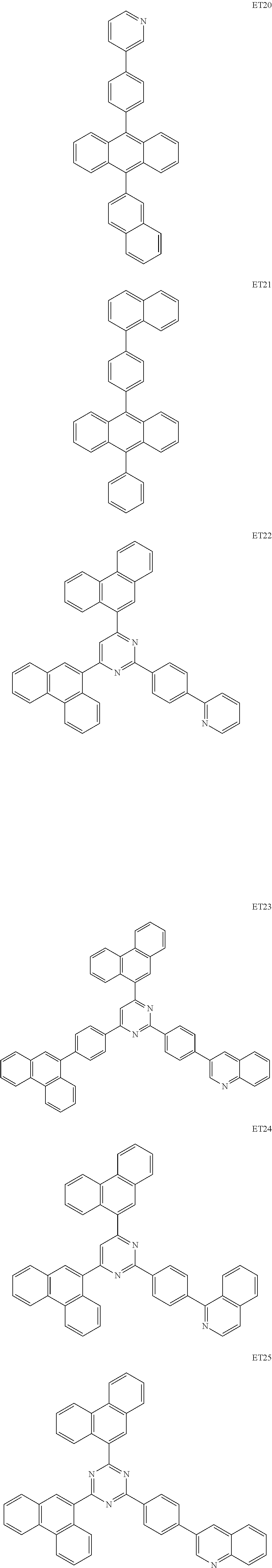

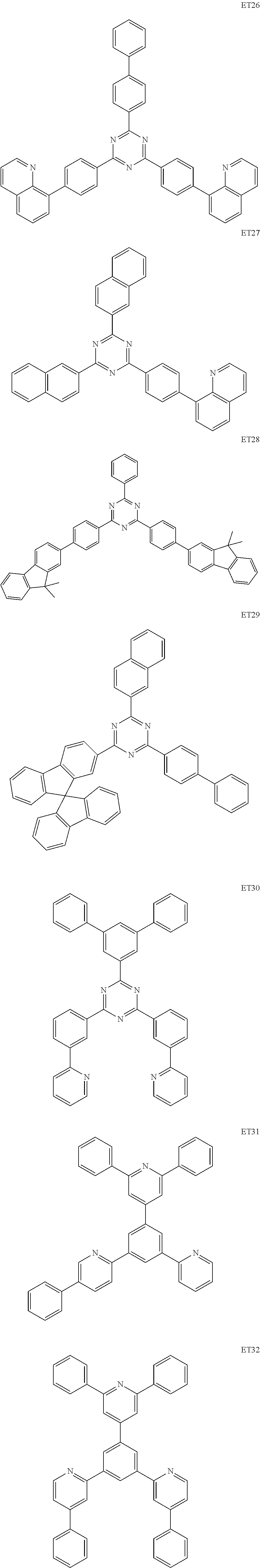

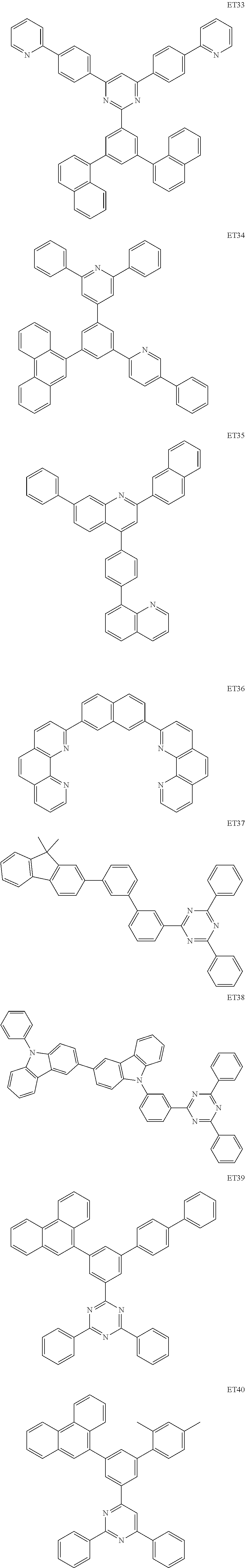

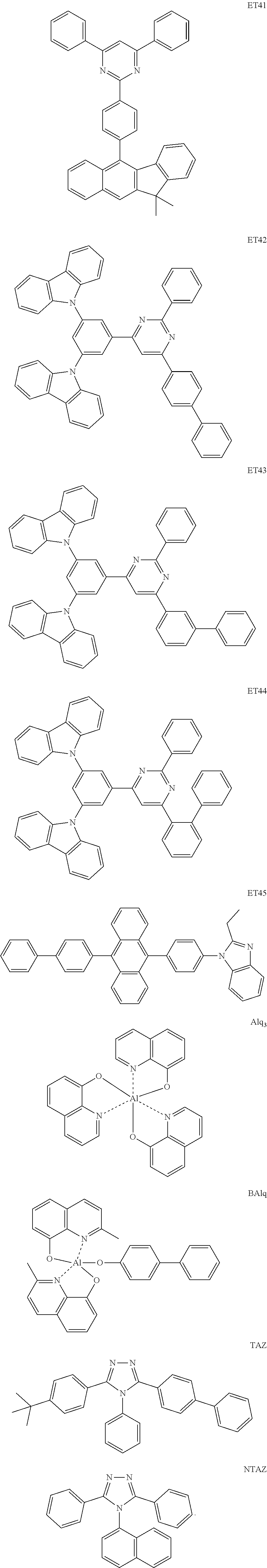

A thickness of the electron transport region 140 may be in a range of about 100 Å to about 5,000 Å, for example, about 160 Å to about 4,000 Å. In an example in which the electron transport region 140 includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. In an example in which the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region 140 (e.g., the electron transport layer in the electron transport region 140) may further include, in addition to the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) or ET-D2:

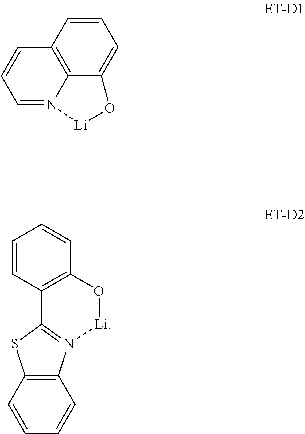

The electron transport region 140 may include an electron injection layer that facilitates the injection of electrons from the second electrode 150. The electron injection layer may be in direct contact with the second electrode 150.

The electron injection layer may have: i) a single-layer structure consisting of a single layer consisting of a single material, ii) a single-layer structure consisting of a single layer consisting of multiple layers that are different from each other, or iii) a multi-layer structure including multiple layers including multiple materials that are different from each other.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (e.g., fluorides, chlorides, bromides, or iodides), or tellurides of the alkali metal, the alkaline earth metal, and the rare earth metal, or any combination thereof.

The alkali metal-containing compound may include: an alkali metal oxide, such as, for example, Li₂O, Cs₂O, K₂O, or the like; alkali metal halides, such as, for example, LiF, NaF, CsF, KF, Lil, NaI, CsI, KI, or the like; or any combination thereof. The alkaline earth metal-containing compound may include an alkaline earth metal compound, such as, for example, BaO, SrO, CaO, BaxSr₁₋ₓO (wherein x is a real number satisfying 0<x<1), BaₓCa₁₋ₓO (wherein x is a real number satisfying 0<x<1), and the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include i) one of metal ions of the alkali metal, the alkaline earth metal, and the rare earth metal, and ii) as a ligand bonded to the metal ions, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described herein. In one or more embodiments, the electron injection layer may further include an organic material (e.g., the compound represented by Formula 601).

In one or more embodiments, the electron injection layer may consist of i) an alkali metal-containing compound (e.g., an alkali metal halide), or ii) a) an alkali metal-containing compound (e.g., an alkali metal halide), and b) an alkali metal, an alkaline earth metal, a rare earth metal, or any combination thereof. In an embodiment, the electron injection layer may be a KI:Yb co-deposited layer, an RbI:Yb co-deposited layer, a LiF:Yb co-deposited layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

A thickness of the electron injection layer may be in a range of about 1 Å to about 100 Å, and, for example, about 3 Å to about 90 Å. In an example in which the thickness of the electron injection layer is within these ranges, satisfactory electron injection characteristics may be obtained without a substantial increase in driving voltage.

### [Second Electrode 150]

The second electrode 150 may be arranged on the electron transport region 140. The second electrode 150 may be a cathode, which is an electron injection electrode, and as a material for forming the second electrode 150, a metal, an alloy, an electrically conductive compound, or any combination thereof, each having a low-work function, may be used.

The second electrode 150 may include Li, Na, Ag, Mg, Al, Ag—Li, Ag—Na, Al—Li, Ca, Mg—In, Mg—Ag, Yb, Ag—Yb, ITO, IZO, or any combination thereof. The second electrode 150 may be a transmissive electrode, a semi-transmissive electrode, or a reflective electrode.

The second electrode 150 may have a single-layer structure or a multi-layer structure including multiple layers.

### [Capping Layer]

The light-emitting device 11 may further include a capping layer arranged outside the first electrode 110 and/or outside the second electrode 150.

In an embodiment, the light-emitting device 11 may further include a first capping layer arranged outside the first electrode 110.

In one or more embodiments, the light-emitting device 11 may further include a second capping layer arranged outside the second electrode 150.

In one or more embodiments, the light-emitting device 11 may further include both a first capping layer arranged outside the first electrode 110 and a second capping layer arranged outside the second electrode 150.

Light generated in the emission layer 130 of the light-emitting device 11 may be extracted toward the outside through the first electrode 110 which is a transflective electrode or a transmissive electrode, and the first capping layer. Light generated in the emission layer 130 of the light-emitting device 11 may be extracted toward the outside through the second electrode 150 which is a transflective electrode or a transmissive electrode, and the second capping layer.

The first capping layer and the second capping layer may serve to increase external emission efficiency according to the principle of constructive interference.

Accordingly, the light extraction efficiency of the light-emitting device 11 may be increased, and accordingly, the luminescence efficiency of the light-emitting device 11 may be improved.

Each of the first capping layer and the second capping layer may include a material having a refractive index of about 1.2 or more (at 420 nm).

The first capping layer and the second capping layer may each independently be an organic capping layer including organic materials, an inorganic capping layer including inorganic materials, or an organic-inorganic composite capping layer including organic materials and inorganic materials.

At least one of the first capping layer or the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer or the second capping layer may each independently include an amine group-containing compound.

In one or more embodiments, at least one of the first capping layer or the second capping layer may each independently include the compound represented by Formula 201, the compound represented by Formula 202, or any combination thereof.

In one or more embodiments, at least one of the first capping layer or the second capping layer may each independently include one of Compounds HT28 to HT33, one of Compounds CP1 to CP6, β-NPB, or any combination thereof:

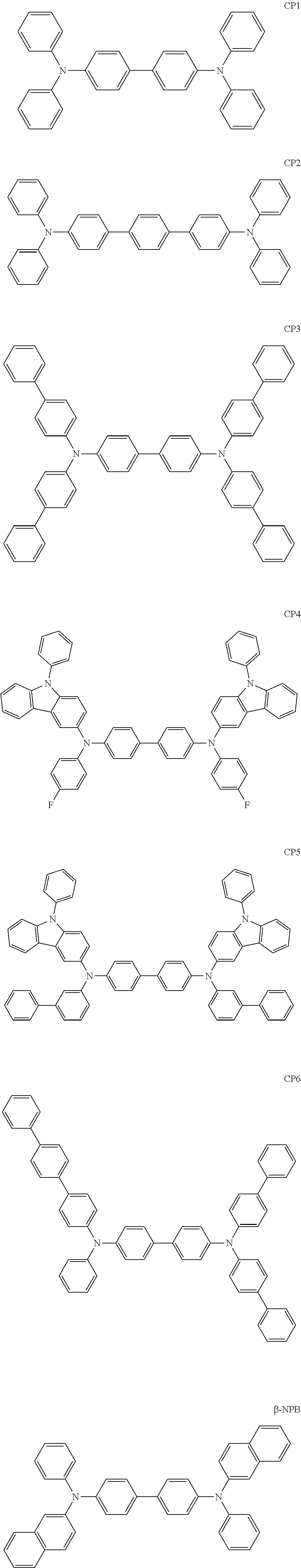

### [Film]

The display apparatus may further include a film. The film may be, for example, an optical member (or a light control means) (e.g., a color filter, a color conversion layer, a capping layer, a light extraction efficiency enhancement layer, a selective light absorbing layer, a polarizing layer, a quantum dot-containing layer, or like), a light blocking member (e.g., a light reflective layer, a light absorbing layer, or the like), a protective member (e.g., an insulating layer, a dielectric layer, or the like).

### [Display Apparatus]

The light-emitting device 11 may be included in various display apparatuses.

The display apparatus may further include i) a color filter, ii) a color conversion layer, or iii) a color filter and a color conversion layer, in addition to the light-emitting device 11. The color filter and/or the color conversion layer may be arranged in at least one traveling direction of light emitted from the light-emitting device 11. For example, light emitted from the light-emitting device 11 may be blue light or white light. Aspects of the light-emitting device 11 are provided by the descriptions of the light-emitting device 11 as provided herein.

The display apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining film may be arranged among the plurality of subpixel areas to define each of the subpixel areas.

The color filter may further include a plurality of color filter areas and light-shielding patterns thereon, and the color conversion layer may further include a plurality of color conversion areas and light-shielding patterns thereon.

The plurality of color filter areas (or the plurality of color conversion areas) may include: a first area emitting first-color light; a second area emitting second-color light; and/or a third area emitting third-color light, wherein the first-color light, the second-color light, and/or the third-color light may have different maximum emission wavelengths from one another. In an embodiment, the first-color light may be blue light, the second-color light may be green light, and the third-color light may be red light. In an embodiment, the plurality of color filter areas (or the plurality of color conversion areas) may include quantum dots. In particular, the first area may include red quantum dots, the second area may include green quantum dots, and the third area may not include quantum dots. The quantum dots may be understood by referring to the description of the quantum dots described herein. Each of the first area, the second area, and/or the third area may further include a scatter.

In an embodiment, the light-emitting device 11 may emit first light, the first area may absorb the first light to emit first-1 color light, the second area may absorb the first light to emit second-1 color light, and the third area may absorb the first light to emit third-1 color light. Here, the first-1 color light, the second-1 color light, and the third-1 color light may have different maximum emission wavelengths from one another. In particular, the first light may be blue light, the first-1 color light may be red light, the second-1 color light may be green light, and the third-1 color light may be blue light.

The display apparatus may further include a thin-film transistor, in addition to the light-emitting device 11. The thin-film transistor may include a source electrode, a drain electrode, and an activation layer, wherein any one of the source electrode and the drain electrode may be electrically connected to any one of the first electrode 110 and the second electrode 150 of the light-emitting device 11.

The thin-film transistor may further include a gate electrode, a gate insulating film, and the like.

The active layer may include crystalline silicon, amorphous silicon, an organic semiconductor, an oxide semiconductor, and the like.

The display apparatus may further include an encapsulation unit for sealing the light-emitting device 11. The sealing portion may be arranged between the color filter and/or the color conversion layer and the light-emitting device 11. The sealing portion allows light from the light-emitting device 11 to pass through to the outside, and simultaneously prevents ambient air and moisture from penetrating into the light-emitting device 11. The sealing portion may be a sealing substrate including a transparent glass substrate or a plastic substrate. The sealing portion may be a thin-film encapsulation layer including at least one layer of an organic layer and/or an inorganic layer. In an example in which the sealing portion is a thin-film encapsulation layer, the display apparatus may be flexible.

Various functional layers may be additionally arranged on the sealing portion, in addition to the color filter and/or the color conversion layer, according to the use of the display apparatus. Examples of the functional layers may include a touch screen layer and a polarizing layer. The touch screen layer may be a pressure-sensitive touch screen layer, a capacitive touch screen layer, or an infrared touch screen layer. The display apparatus may include, for example, a biometric authentication apparatus that authenticates an individual by using biometric information of a living body (e.g., fingertips, pupils, or the like).

The authentication apparatus may further include, in addition to the light-emitting device, a biometric information collector.

### [Electronic Apparatus]

The light-emitting device 11 may be included in various electronic apparatuses. For example, the display apparatus including the light-emitting device 11 may be included in various types of electronic apparatuses.

For example, the electronic apparatus including the light-emitting device 11 may be one of a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle gauge, a center information display (CID) in a vehicle, a head-up display for a vehicle, a room mirror display, a video wall including multiple displays tiled together, a theater or stadium screen, a phototherapy device, and a signboard.

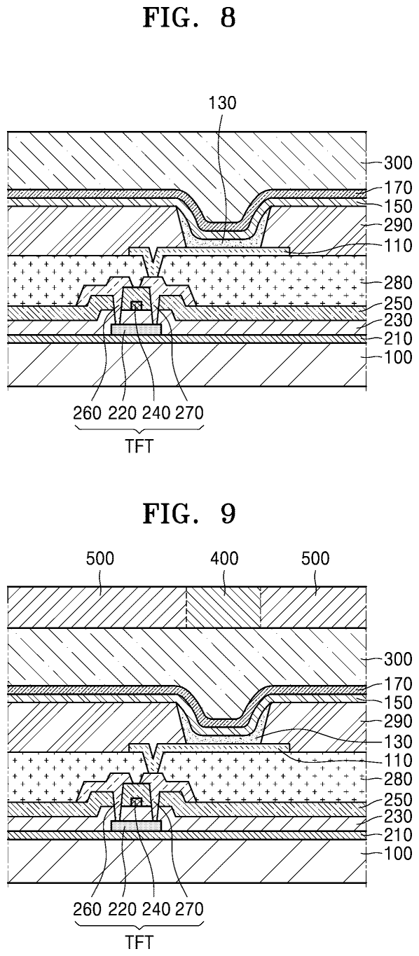

### [Description of FIGS. 8 and 9]

FIG. 8 is a cross-sectional view of a display apparatus including a light-emitting device according to an embodiment.

A display apparatus of FIG. 8 may include a substrate 100, a thin-film transistor (TFT), a light-emitting device, and an encapsulation portion 300.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

The TFT may be arranged on the buffer layer 210. The TFT may include an activation layer 220, a gate electrode 240, a source electrode 260, and a drain electrode 270.

The activation layer 220 may include an inorganic semiconductor, such as, for example, silicon or polysilicon, an organic semiconductor, or an oxide semiconductor, and may include a source region, a drain region, and a channel region.

A gate insulating film 230 for insulating the activation layer 220 from the gate electrode 240 may be disposed on the activation layer 220, and the gate electrode 240 may be disposed on the gate insulating film 230.

An interlayer insulating film 250 may be arranged on the gate electrode 240. The interlayer insulating film 250 may be located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose the source region and the drain region of the active layer 220, and the source electrode 260 and the drain electrode 270 may be arranged in contact with the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device includes the first electrode 110, the interlayer, and the second electrode 150.

The first electrode 110 may be arranged on the passivation layer 280. The passivation layer 280 may be arranged to expose a portion of the drain electrode 270 without fully covering the drain electrode 270, and the first electrode 110 may be arranged to be connected to the exposed portion of the drain electrode 270.

The pixel-defining layer 290 including an insulating material may be arranged on the first electrode 110. The pixel defining layer 290 may expose a certain region of the first electrode 110, and the interlayer may be formed in the exposed region of the first electrode 110. The pixel defining layer 290 may be a polyimide-based organic film or a polyacrylic-based organic film. Although not illustrated in FIG. 8, at least some layers of the interlayer may extend to the upper portion of the pixel defining layer 290 and may be arranged in the form of a common layer.

The second electrode 150 may be arranged on the interlayer, and a capping layer 170 may be additionally formed on the second electrode 150. The capping layer 170 may be formed such that the capping layer 170 covers the second electrode 150.

The encapsulation portion 300 may be arranged on the capping layer 170. The encapsulation portion 300 may be disposed on the light-emitting device to protect the light-emitting device from moisture or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, or the like), an epoxy-based resin (e.g., aliphatic glycidyl ether (AGE), or the like), or any combination thereof; or any combination of the inorganic films and the organic films.

FIG. 9 is a cross-sectional view of another display apparatus including a light-emitting device according to an embodiment.

A display apparatus of FIG. 9 is the same as the display apparatus of FIG. 8, except that light-shielding patterns 500 and a functional region 400 are additionally arranged on the encapsulation portion 300. The functional region 400 may include i) a color filter area, ii) a color conversion area, or iii) a combination of a color filter area and a color conversion area. In an embodiment, a light-emitting device included in the display apparatus of FIG. 9 may be a tandem light-emitting device.

### [Description of FIG. 10]

FIG. 10 is a schematic perspective view of an electronic apparatus 1 including the light-emitting device according to an embodiment. The electronic apparatus 1 may be, as an apparatus that displays a moving image or a still image, portable electronic equipment, such as, for example, a mobile phone, a smart phone, a tablet personal computer (PC), a mobile communication terminal, an electronic notebook, an electronic book, a portable multimedia player (PMP), a navigation, or a ultra-mobile PC (UMPC), as well as various products or a part thereof, such as, for example, a television, a laptop, a monitor, a billboard, or an Internet of things (IOT). In some aspects, the electronic apparatus 1 may be a wearable device or a part thereof, such as, for example, a smart watch, a watch phone, a glasses-type display, or a head mounted display (HMD). However, embodiments are not limited thereto. In an embodiment, the electronic apparatus 1 may be a dashboard of a vehicle, a center information display (CID) arranged on a center fascia or dashboard of a vehicle, a room mirror display instead of a side-view mirror of a vehicle, an entertainment for the back seat of a vehicle, or a display arranged on the back of the front seat of a vehicle, a head up display (HUD) installed on the front of a vehicle or projected on a front window glass, or a computer generated hologram augmented reality head up display (CGH AR HUD). FIG. 10 illustrates an embodiment in which the electronic apparatus 1 is a smart phone for convenience of description.

The electronic apparatus 1 may include a display area DA and a non-display area NDA outside the display area DA. The electronic apparatus 1 may implement an image through an array of a plurality of pixels that are two-dimensionally arranged in the display area DA.

The non-display area NDA is an area that does not display an image, and may entirely surround the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

The electronic apparatus 1 may have different lengths in the x-axis direction and in the y-axis direction. In an embodiment, as illustrated in FIG. 10, the length in the x-axis direction may be shorter than the length in the y-axis direction. In an embodiment, the length in the x-axis direction may be the same as the length in the y-axis direction. In one or more embodiments, the length in the x-axis direction may be greater than the length in the y-axis direction.

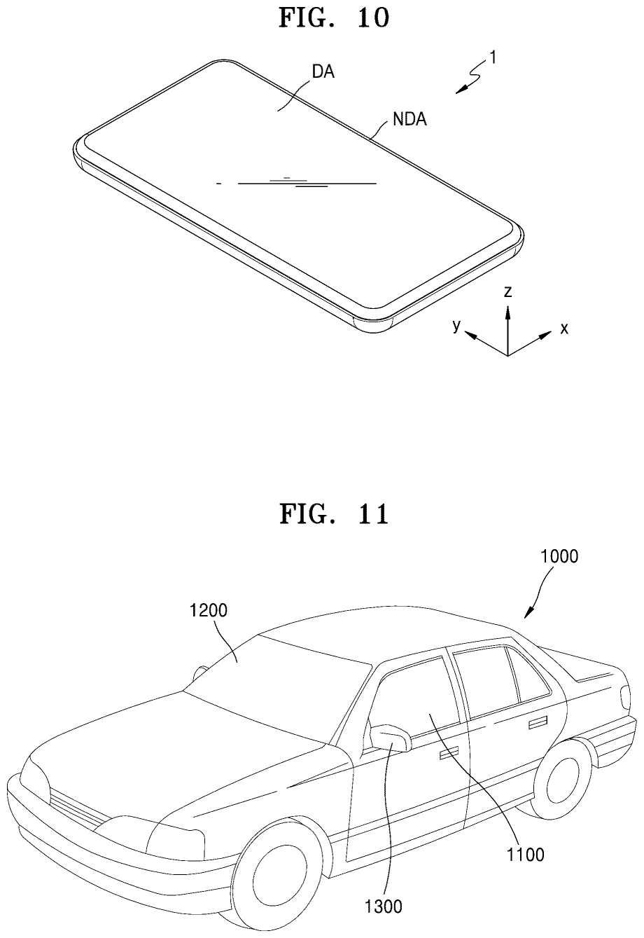

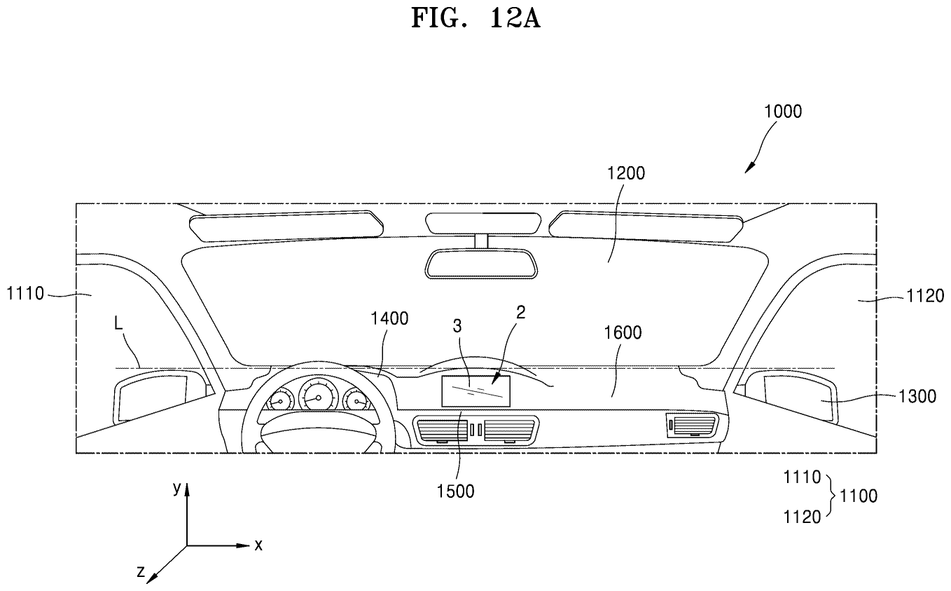

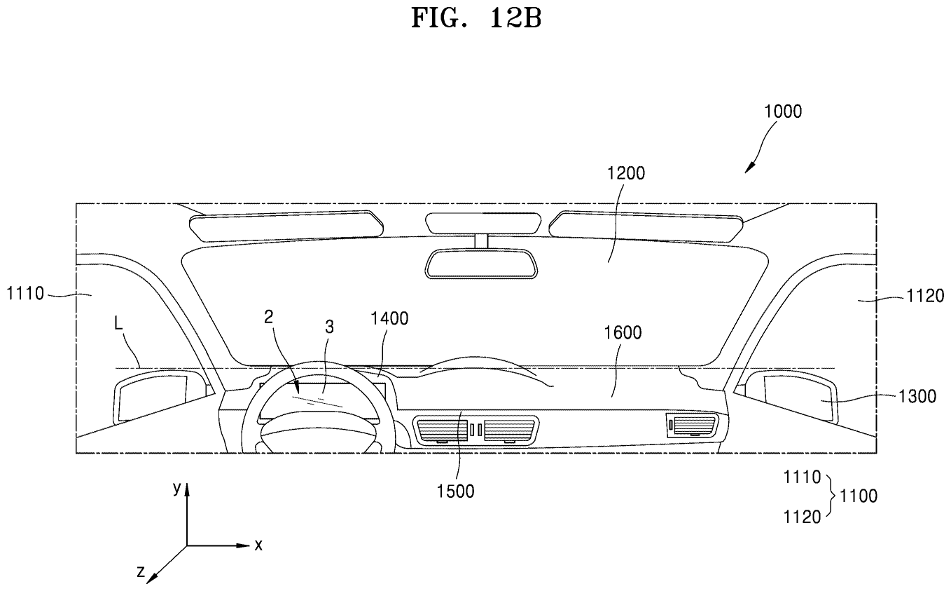

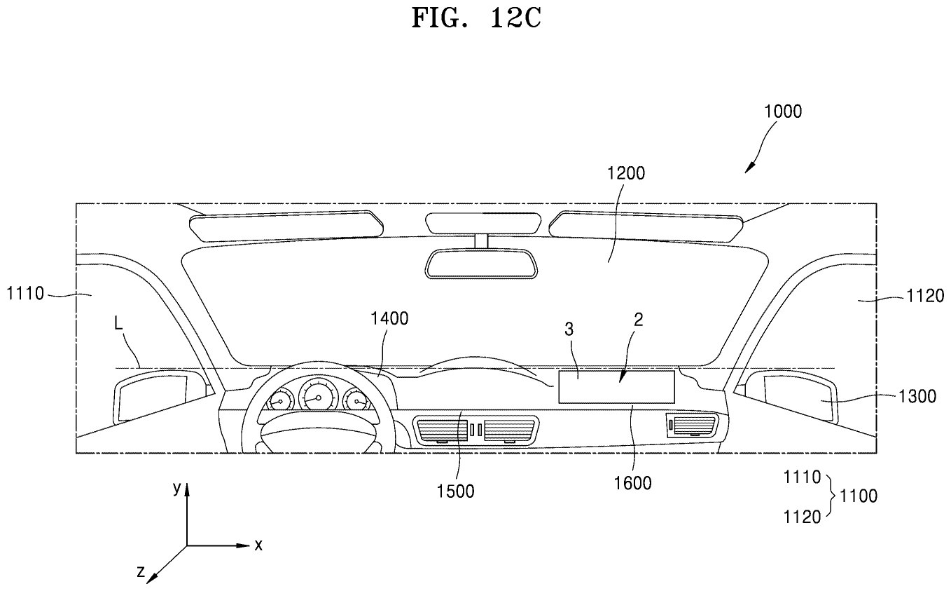

### [Descriptions of FIGS. 11 and 12A to 12C]

FIG. 11 is a schematic view of the exterior of a vehicle 1000 as an electronic apparatus including the light-emitting device according to an embodiment. FIGS. 12A to 12C are each a schematic view of the interior of the vehicle 1000 according to one or more embodiments.

Referring to FIGS. 11, 12A, 12B, and 12C, the vehicle 1000 may refer to various apparatuses for moving a subject to be transported, such as, for example, a human, an object, or an animal, from a departure point to a destination point. The vehicle 1000 may include a vehicle traveling on a road or a track, a vessel moving over the sea or river, an airplane flying in the sky using the action of air, and the like.

The vehicle 1000 may travel on a road or a track. The vehicle 1000 may move in a certain direction according to rotation of at least one wheel. In an embodiment, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses supportive of driving are installed as other parts except for the body of the vehicle 1000. The exterior of the body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on the side of the vehicle 1000. In an embodiment, the side window glass 1100 may be installed on a door of the vehicle 1000. A plurality of side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400. The second side window glass 1120 may be arranged adjacent to the passenger seat dashboard 1600.

In an embodiment, the side window glasses 1100 may be spaced apart from each other in an x direction or a−x direction. In an embodiment, the first side window glass 1110 and the second side window glass 1120 may be spaced apart from each other in the x direction or the−x direction. In other words, an imaginary straight line L connecting the side window glasses 1100 may extend in the x direction or the−x direction. In an embodiment, an imaginary straight line L connecting the first side window glass 1110 and the second side window glass 1120 to each other may extend in the x direction or the−x direction.

The front window glass 1200 may be installed in front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior of the body of the vehicle. In an embodiment, a plurality of side-view mirrors 1300 may be provided. Any one of the plurality of side-view mirrors 1300 may be arranged outside the first side window glass 1110. Another of the plurality of side mirrors 1300 may be arranged outside the second side window glass 1120.

The cluster 1400 may be arranged in front of a steering wheel. The cluster 1400 may include a tachometer, a speedometer, a coolant thermometer, a fuel gauge turn indicator, a high beam indicator, a warning lamp, a seat belt warning lamp, an odometer, a tachograph, an automatic shift selector indicator lamp, a door open warning lamp, an engine oil warning lamp, and/or a low fuel warning light.

The center fascia 1500 may include a control panel on which a plurality of buttons for adjusting an audio device, an air conditioning device, and a seat heater are disposed. The center fascia 1500 may be arranged on one side of the cluster 1400.

The passenger seat dashboard 1600 may be spaced apart from the cluster 1400, and the center fascia 1500 may be arranged between the cluster 1400 and the passenger seat dashboard 1600. In an embodiment, the cluster 1400 may be arranged to correspond to a driver seat (not illustrated), and the passenger seat dashboard 1600 may be arranged to correspond to a passenger seat (not illustrated). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged on at least one of the cluster 1400, the center fascia 1500, or the passenger seat dashboard 1600.

The display apparatus 2 may include an organic light-emitting display device, an inorganic light-emitting display device, a quantum dot display device, and the like. Hereinafter, as the display apparatus 2 according to an embodiment, an organic light-emitting display apparatus including the aforementioned light-emitting device according to an embodiment will be described as an example, but various types of the aforementioned display apparatus may be used in embodiments.

Referring to FIG. 12A, the display apparatus 2 may be arranged on the center fascia 1500. In an embodiment, the display apparatus 2 may display navigation information. In an embodiment, the display apparatus 2 may display information regarding audio settings, video setting, or vehicle settings.

Referring to FIG. 12B, the display apparatus 2 may be arranged on the cluster 1400. In this case, the cluster 1400 may display driving information and the like through the display apparatus 2. That is, the cluster 1400 may digitally implement driving information and the like. The cluster 1400 may digitally implement vehicle information and driving information as images. In an embodiment, a needle and a gauge of a tachometer and various warning light icons may be displayed by a digital signal.

Referring to FIG. 12C, the display apparatus 2 may be arranged on the passenger seat dashboard 1600. The display apparatus 2 may be embedded in the passenger seat dashboard 1600 or arranged on the passenger seat dashboard 1600. In an embodiment, the display apparatus 2 arranged on the passenger seat dashboard 1600 may display an image related to information displayed on the cluster 1400 and/or information displayed on the center fascia 1500. In an embodiment, the display apparatus 2 arranged on the passenger seat dashboard 1600 may display information different from information displayed on the cluster 1400 and/or information displayed on the center fascia 1500.

### [Manufacturing Method]

Constituent layers included in the hole transport region 120, the emission layer 130 including the first emission layer 131 and the second emission layer 132, and constituent layers included in the electron transport region 140 may be formed in a certain region by using various methods, such as, for example, vacuum deposition, spin coating, casting, a Langmuir-Blodgett (LB) method, inkjet printing, laser printing, laser-induced thermal imaging, and the like.

When constituent layers included in the hole transport region 120, the emission layer 130 including the first emission layer 131 and the second emission layer 132, and constituent layers included in the electron transport region 140 are formed by vacuum deposition, the deposition conditions may be selected, for example, to include a deposition temperature in a range of about 100° C. to about 500° C., a vacuum degree in a range of about 10⁻⁸ torr to about 10⁻³ torr, and a deposition speed in a range of about 0.01 Å/sec to about 100 Å/sec, according to the material and structure of a layer to be formed.

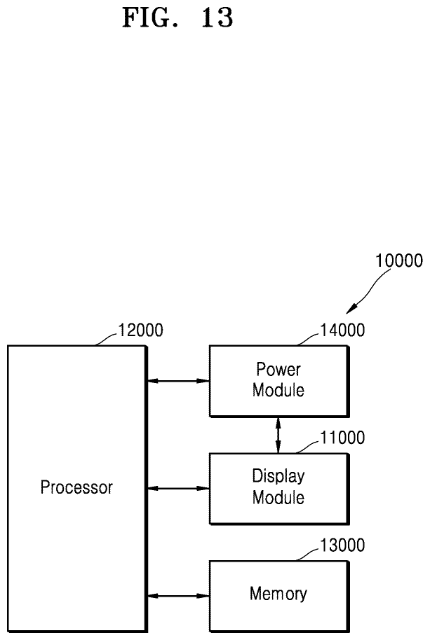

FIG. 13 is a block diagram of an electronic apparatus including the display apparatus according to an embodiment.

The display apparatus including the light-emitting device may be applied to various electronic apparatuses. An electronic apparatus 10000 according to an embodiment includes the aforementioned display apparatus, and may further include, in addition to the display apparatus, a module or an apparatus having additional functions.

Referring to FIG. 13, the electronic apparatus 10000 according to an embodiment may include a display module 11000, a processor 12000, a memory 13000, and a power module 14000.

The processor 12000 may include at least one of a central processing unit (CPU), an application processor (AP), a graphic processing unit (GPU), a communication processor (CP), an image signal processor (ISP), and a controller.

Data information supportive of the operation of the processor 12000 or the display module 11000 may be stored in the memory 13000. In an example in which the processor 12000 executes an application stored in the memory 13000, an image data signal and/or an input control signal is transmitted to the display module 11000, and the display module 11000 can process the received signal and output image information through a display screen.

The power module 14000 may include: a power supply module, such as, for example, a power adapter or a battery device; and a power conversion module that converts power supplied by the power supply module to generate power for the operation of the electronic apparatus 10000.

At least one of components of the electronic apparatus 10000 may be included in the display apparatus according to the aforementioned embodiments. In an embodiment, some of individual modules functionally included in a single module may be included in the display apparatus, and others may be provided separately from the display apparatus. For example, the display apparatus may include the display module 11000, and the processor 12000, the memory 13000, and the power module 14000 may be provided in the form of other apparatuses in the electronic apparatus 10000 other than the display apparatus.

In an embodiment, the electronic apparatus 10000 may be one of a flat panel display, a curved display, a computer monitor, a medical monitor, a television, a billboard, an indoor light, an outdoor light, a signal light, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle gauge, a center information display (CID) in a vehicle, a head-up display for a vehicle, a room mirror display, a video wall including multiple displays tiled together, a theater or stadium screen, a phototherapy device, and a signboard.

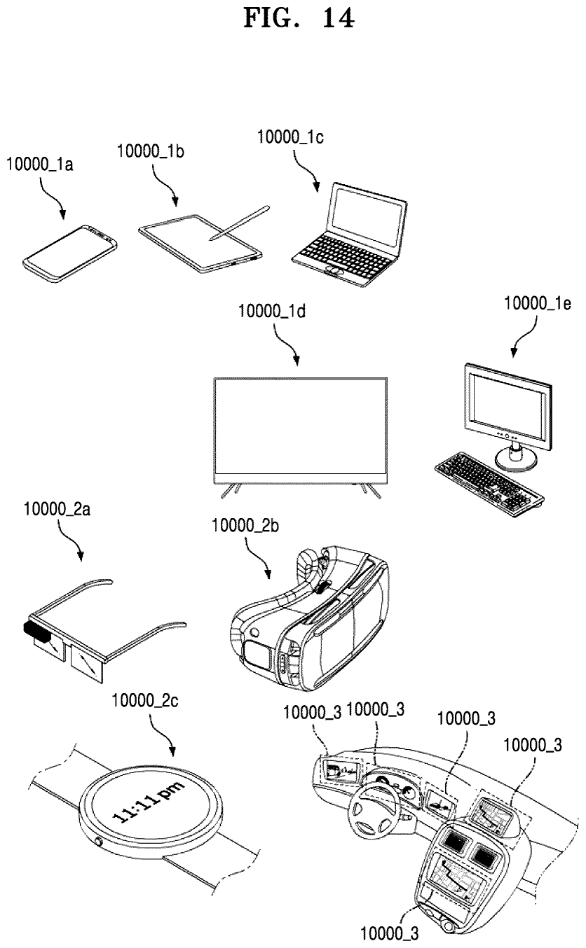

FIG. 14 is a schematic diagram of the electronic apparatuses 10000 according to various embodiments.

Referring to FIG. 14, various electronic apparatuses 10000 to which the display apparatus according to embodiments may include: an electronic apparatuses for displaying an image, such as, for example, a smart phone 10000_1a, a tablet PC10000_1b, a laptop 10000_1c, a TV 10000_1d, a desk monitor 10000_1e, and the like; a wearable electronic apparatus including a display module, such as, for example, smart glasses 10000_2a, a head-mount display 10000_2b, a smart watch 10000_2c, and the like; and an automotive electronic apparatus 10000_3 including a display module, such as, for example, a vehicle gauge, a centre fascia, a center information display (CID) on a dashboard, a room mirror display, and the like.

### Definition of Terms

The term “C₅-C₆₀ carbocyclic group” as used herein refers to a cyclic group consisting of carbon atoms as the only ring-forming atoms and having 5 to 60 carbon atoms.

The term “C₃-C₆₀ heterocyclic group” as used herein refers to a cyclic group that has 3 to 60 carbon atoms and further has, in addition to carbon atoms, a heteroatom as a ring-forming atom.

The C₅-C₆₀ carbocyclic group and the C₃-C₆₀ heterocyclic group may each be a monocyclic group consisting of one ring or a polycyclic group in which two or more rings are condensed with each other. For example, the C₃-C₆₀ heterocyclic group has 4 to 61 ring-forming atoms.

The “cyclic group” as used herein may include the C₅-C₆₀ carbocyclic group, and the C₅-C₆₀ heterocyclic group.

The term “π electron-rich C₃-C₆₀ cyclic group” as used herein refers to a cyclic group that has 3 to 60 carbon atoms and does not include *—N═*′ as a ring-forming moiety.

The term “π electron-deficient nitrogen-containing C₁-C₆₀ cyclic group” as used herein refers to a heterocyclic group that has 1 to 60 carbon atoms and includes *—N═*′ as a ring-forming moiety.

In an embodiment,
the C₅-C₆₀ carbocyclic group may be i) Group T1 or ii) a condensed cyclic group in which two or more of Group T1 are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group), and
the C₃-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, a xanten group, or the like).
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, or the like), and
the π electron-deficient nitrogen-containing C₁-C₆₀ cyclic group may be i) Group T4, ii) a condensed cyclic group in which two or more Groups T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like).

Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

Group T3 may be a furan group, a thiophene group, a 1H-pyrrole group, a silole group, or a borole group.

Group T4 may include a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group,” “the C₃-C₆₀ carbocyclic group,” “the C₁-C₆₀ heterocyclic group,” “the Tr electron-rich C₃-C₆₀ cyclic group,” or “the π electron-deficient nitrogen-containing C₁-C₆₀ cyclic group,” as used herein, refer to a monovalent or polyvalent group (for example, a divalent group, a trivalent group, a tetravalent group, or the like) that is condensed with (e.g., combined together with) a cyclic group.

In an embodiment, the “benzene group” may be a benzo group, a phenyl group, a phenylene group, or the like, which may be easily understood by those of ordinary skill in the art according to the structure of a formula including the “benzene group.”

Examples of the monovalent C₅-C₆₀ carbocyclic group and monovalent C₃-C₆₀ heterocyclic group may include a C₅-C₁o cycloalkyl group, a C₃-C₁o heterocycloalkyl group, a C₅-C₁o cycloalkenyl group, a C₃-C10 heterocycloalkenyl group, a C₆-C₆₀ aryl group, a C₃-C₆₀ heteroaryl group, a monovalent non-aromatic condensed polycyclic group, and a monovalent non-aromatic condensed heteropolycyclic group.

Examples of the divalent C₅-C₆₀ carbocyclic group and the divalent C₃-C₆₀ heterocyclic group may include a C₅-C₁₀ cycloalkylene group, a C₃-C₁₀ heterocycloalkylene group, a C₅-C₁₀ cycloalkenylene group, a C₃-C₁₀ heterocycloalkenylene group, a C₆-C₆₀ arylene group, a C₃-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has 1 to 60 carbon atoms, and specific examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group.

The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof may include an ethenyl group, a propenyl group, a butenyl group, and the like.

The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof may include an ethynyl group, a propynyl group, and the like.

The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like.

The term “C₃-C₁o cycloalkylene group” as used herein refers to a divalent group having the same structure as the C₃-C₁o cycloalkyl group.

The term “C₁-C₁o heterocycloalkyl group” as used herein refers to a monovalent cyclic group of 1 to 10 carbon atoms, further including, in addition to carbon atoms, at least one heteroatom as ring-forming atoms, and specific examples thereof may include a 1,2,3,4-oxatriazolidinyl group, a tetrahydrofuranyl group, a tetrahydrothiophenyl group, and the like.

The term “C₁-C₁o heterocycloalkylene group” as used herein refers to a divalent group having the same structure as the C₁-C₁o heterocycloalkyl group.

The term “C₃-C₁o cycloalkenyl group” as used herein refers to a monovalent cyclic group that 3 to 10 carbon atoms, at least one carbon-carbon double bond in the ring thereof, and no aromaticity, and specific examples thereof may include a cyclopentenyl group, a cyclohexenyl group, a cycloheptenyl group, and the like.

The term “C₃-C₁o cycloalkenylene group” as used herein refers to a divalent group having the same structure as the C₃-C₁o cycloalkyl group.

The term “C₁-C₁o heterocycloalkenyl group” as used herein refers to a monovalent cyclic group of 1 to 10 carbon atoms, further including, in addition to carbon atoms, at least one heteroatom as ring-forming atoms and at least one carbon-carbon double bond in the cyclic structure thereof. Examples of the C₁-C₁o heterocycloalkenyl group may include a 4,5-dihydro-1,2,3,4-oxatriazolyl group, a 2,3-dihydrofuranyl group, a 2,3-dihydrothiophenyl group, and the like.

The term “C₁-C₁o heterocycloalkenylene group” as used herein refers to a divalent group having the same structure as the C₁-C₁o heterocycloalkenyl group.

The term “C₆-C₆₀ aryl group” as used herein refers to a monovalent group having a carbocyclic aromatic system of 6 to 60 carbon atoms.

The term “C₆-C₆₀ arylene group” as used herein refers to a divalent group having a carbocyclic aromatic system of 6 to 60 carbon atoms.

Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like.

When the C₆-C₆₀ aryl group and the C₆-C₆₀ arylene group each include two or more rings, the two or more rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms.

Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like.

When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in the entire molecular structure. Examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like.

The term “divalent non-aromatic condensed polycyclic group” as used herein refers to a divalent group having the same structure as the monovalent non-aromatic condensed polycyclic group.

The term “monovalent non-aromatic hetero-condensed polycyclic group” as used herein refers to a monovalent group (e.g., having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic hetero-condensed polycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group.

The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein indicates —OA₁₀₂ (wherein A₁₀₂ is the C₆-C₆₀ aryl group).

The term “C₆-C₆₀ arylthio group” as used herein indicates —SA₁₀₃ (wherein A₁₀₃ is the C₆-C₆₀ aryl group).

The term “C₇-C₆₀ arylalkyl group” as used herein refers to -A₁₀₄A₁₀₅ (wherein A₁₀₄ is a C₁-C₅₄ alkylene group, and A₁₀₅ is a C₆-C₅₉ aryl group).

The term “C₂-C₆₀ heteroarylalkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁), —S(═O)₂(Q₁₁), —P(═O)(Q₁)(Q₁₂), or a combination thereof;
a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, or a C₃-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₃-C₆₀ heterocyclic group, a C₆-C₆₀ aryloxy group, a C₆-C₆₀ arylthio group, a C₇-C₆₀ aryl alkyl group, a C₃-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, or a C₃-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom and a hydrogen atom. Examples of the heteroatom may include O, S, N, P, Si, B, Ge, Se, and any combination thereof.

The term “transition metal” as used herein may include Hf, Ta, W, Re, Os, Ir, Pt, Au, and the like.

In the specification, “D” may refer to deuterium, “Ph” may refer to a phenyl group, “Me” may refer to a methyl group, “Et” may refer to an ethyl group, “tert-Bu”, “^{t}Bu”, or “Bu^{t}” may refer to a tert-butyl group, and “OMe” may refer to a methoxy group.

For example, a group represented by

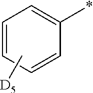

may refer to a group represented by

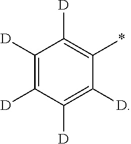

In some aspects, a group represented by

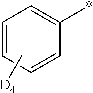

may refer to a group represented by

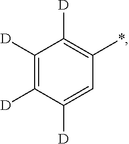

a group represented by

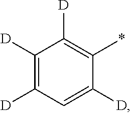

or a group represented by

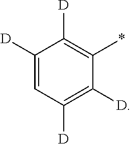

The term “biphenyl group” as used herein refers to “a phenyl group that is substituted with a phenyl group.” In other words, the “biphenyl group” may be a substituted phenyl group having a C₆-C₆₀ aryl group as a substituent.

The term “terphenyl group” as used herein refers to “a phenyl group substituted with a biphenyl group.” The “terphenyl group” may belong to i) “a substituent phenyl group” which is “a C₆-C₆₀ aryl group in which a substituent is substituted with a C₆-C₆₀ aryl group”, or ii) “a substituted phenyl group” having two substituents, each of which is “a C₆-C₆₀ aryl group.”

* and *′ as used herein, unless defined otherwise, each refer to a binding site to a neighboring atom in a corresponding formula or moiety.

In the specification, the x-axis, y-axis, and z-axis are not limited to three axes in an orthogonal coordinate system, and may be interpreted in a broad sense including these axes. For example, the x-axis, y-axis, and z-axis may describe axes that are orthogonal to each other, or may describe axes that are in different directions that are not orthogonal to each other.

Hereinafter, a light-emitting device according to embodiments will be described in detail with reference to Examples.

### Comparative Example 1 (Single Emission Layer)

ITO 300 Å/Ag 50 Å/ITO 300 Å (anode) was cut to a size of 50 mm×50 mm×0.7 mm, sonicated with isopropyl alcohol and pure water each for 5 minutes, and then cleaned by exposure to ultraviolet rays and ozone for 30 minutes. The resultant glass substrate was placed in a vacuum deposition apparatus.

HAT-CN was vacuum-deposited on the glass substrate to form a hole injection layer having a thickness of 150 Å. Next, NPB as a hole-transporting compound was vacuum-deposited to form a hole transport layer having a thickness of 1100 Å.

EBL1 was vacuum-deposited on the hole transport layer to form an electron blocking layer having a thickness of 50 Å.

BH11 as a host and BD1 as a dopant were deposited on the electron blocking layer to form an emission layer having a thickness of 20 nm (host weight:dopant weight=9.8:0.2).

TPM-TAZ and LiQ were deposited on the emission layer at a weight ratio 5:5 to form an electron transport layer having a thickness of 300 Å.

Yb was vacuum-deposited on the electron transport layer to a thickness of 10 Å, and AgMg was continuously vacuum-deposited to a thickness of 100 Å (5 wt % of Mg doping), thereby forming a cathode. Then, CP1 was deposited on the cathode to form a capping layer having a thickness of 700 Å, thereby completing the manufacture of a light-emitting device.

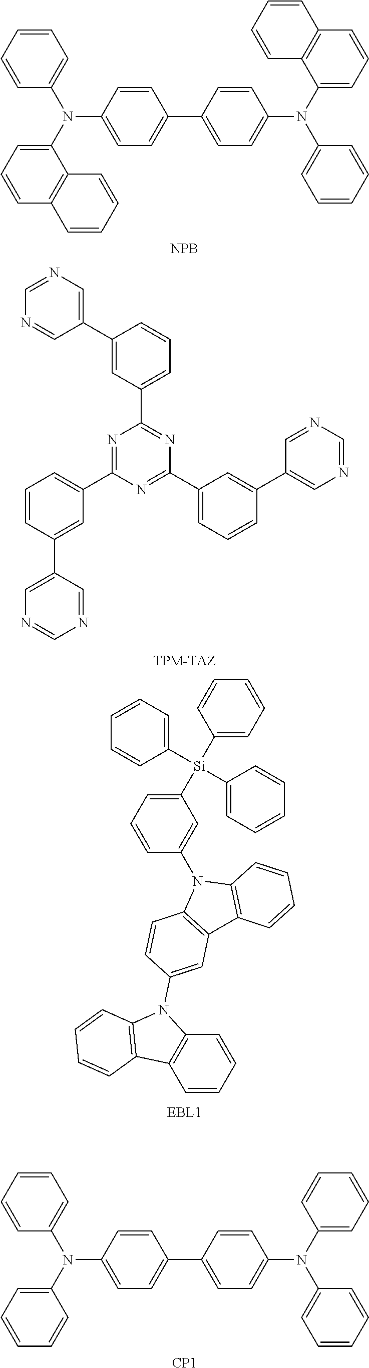

### Comparative Examples 2 to 7

Light-emitting devices were manufactured in substantially the same manner as in Comparative Example 1, except that a host and a dopant illustrated in Table 1 were used.

### Comparative Examples 8 to 18 and Examples 1 to 7 (Two-Layer Emission Layer)

Light-emitting devices were manufactured in substantially the same manner as in Comparative Example 1, except that, instead of forming a single-layer emission layer having a thickness of 20 nm, a 10 nm-thick first emission layer and a 10 nm-thick second emission layer on the first emission layer were formed, wherein each of the first emission layer and the second emission layer used a host and a dopant illustrated in Table 2.

### Evaluation Example 1 (Giant Surface Potential Measurement)

Giant surface potential was measured by a known method in the art. For example, the giant surface potential may be measured in two ways as follows. The giant surface potential of the light-emitting devices of Comparative Examples and Examples are illustrated in Tables 1 and 2.

### 1) Kelvin Probe Measurement

A compound to be measured was deposited on a substrate coated with a metal film (e.g., ITO) (vacuum degree <10⁻³ torr). Here, a first sample deposited with a thickness of 5 nm, a second sample deposited with a thickness of 10 nm, a third sample deposited with a thickness of 12 nm, and a fourth sample deposited with a thickness of 20 nm were prepared. Next, a Kelvin probe was brought within 120 μm of each sample, and the surface potential was measured while vibrating a piezo actuator at 85 Hz under non-contact conditions. Here, the measurement value was calibrated based on the Au film having a work function of 5.2 eV, and the surface potential was measured for multiple samples of different thicknesses, such that the giant surface potential value (including sign) could be measured.

### 2) Impedance Spectroscopy Measurement or Displacement Current Measurement (DCM)

After depositing a non-polar organic material (e.g., α-NPD) to a thickness of 100 nm, a compound to be measured was deposited thereon according to a thickness (e.g., 10 nm to 100 nm) to confirm that the turn-on voltage of the capacitance (or displacement current) changes in the opposite direction to the emission layer. The turn-on voltage change for the change in thickness is the giant surface potential value (including sign).

### Evaluation Example 2 (light-emitting device characteristics)

To evaluate characteristics of the light-emitting devices of Comparative Examples and Examples, the driving voltage at 1000 nit, color purity (CIEy color coordinates), external quantum efficiency (FOE), and lifespan were measured by using a source meter (Keithley Instrument, 2400 series) and a luminance meter PR650, and the results are illustrated in Tables 1 and 2.

The lifespan was measured as the number of hours (T95, hr) until a given light-emitting device reached 95% of the initial luminance, and was expressed as a relative value based on the lifespan of Comparative Example 1.

TABLE 1

| | | | | Light-emitting device characteristics | | | |
|---|---|---|---|---|---|---|---|
| | Single-layer emission layer (20 nm) | | | Driving | | | |
| | | | GSP | voltage | | | Lifespan |
| No. | Host | Dopant | (mV/nm) | (V) | CIEy | EQE | (T₉₅) |
| Comparative | BH11 | BD1 | 1 | 3.5 | 0.10 | 8% | 100% |
| Example 1 | | | | | | | |
| Comparative | BH21 | BD1 | 12 | 3.5 | 0.10 | 8% | 105% |
| Example 2 | | | | | | | |
| Comparative | BH22 | BD1 | 23 | 3.4 | 0.10 | 8% | 101% |
| Example 3 | | | | | | | |
| Comparative | BH23 | BD1 | 35 | 3.4 | 0.10 | 8% | 95% |
| Example 4 | | | | | | | |
| Comparative | BH21 | BD2 | 12 | 3.5 | 0.15 | 8% | 98% |
| Example 5 | | | | | | | |
| Comparative | BH22 | BD2 | 23 | 3.4 | 0.16 | 8% | 95% |
| Example 6 | | | | | | | |
| Comparative | BH23 | BD2 | 35 | 3.4 | 0.18 | 8% | 90% |
| Example 7 | | | | | | | |

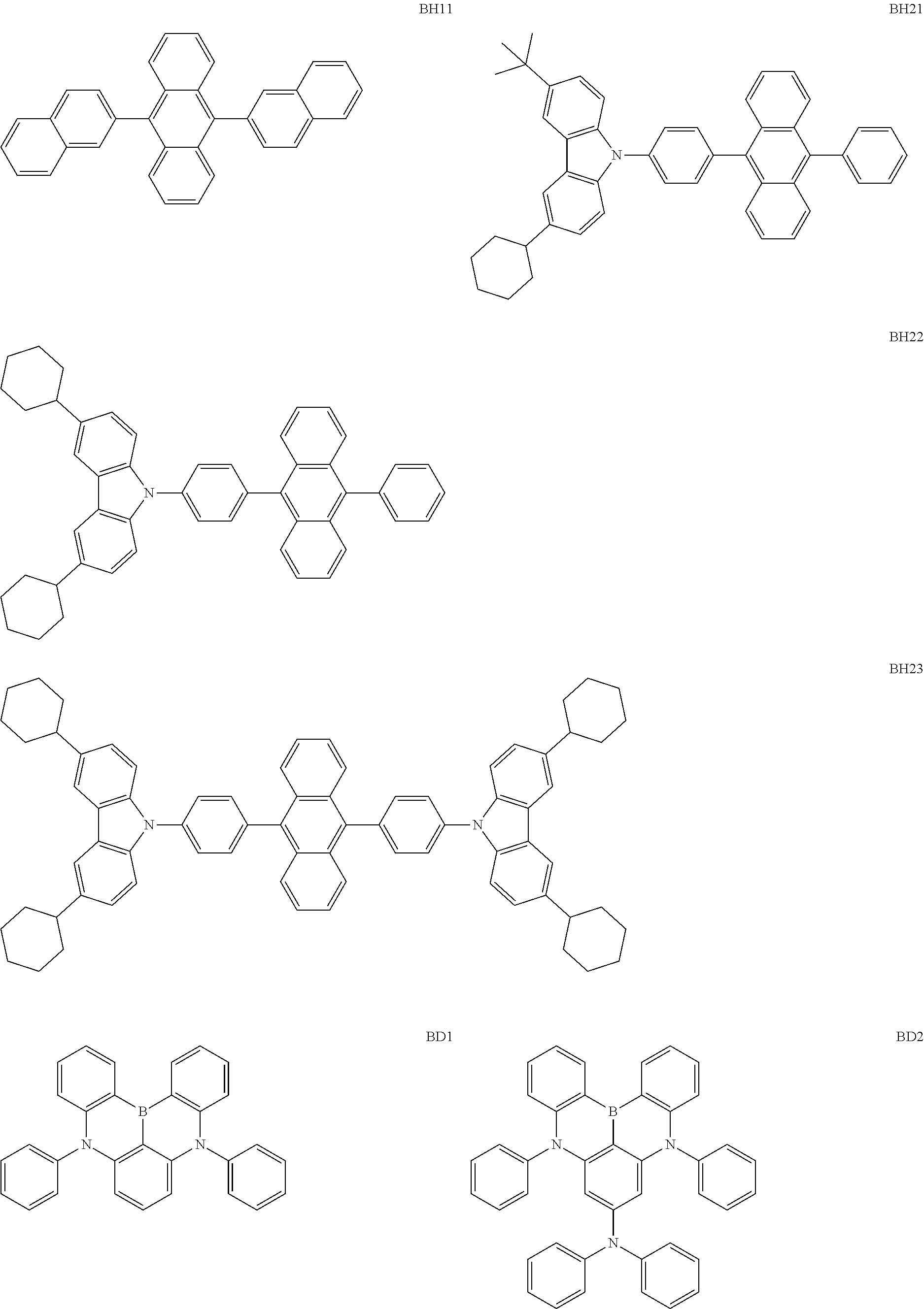

Referring to Table 1, it was confirmed that, when the host and/or dopant included in the emission layer was changed, the GSP of the emission layer was changed. The light-emitting devices of Comparative Examples 1 to 7 including the single-layer emission layer were confirmed to have a shorter lifespan than the light-emitting devices of Examples 1 to 7 described herein. In detail, even if the GSP for the single-layer emission layer was 10 mV/nm or more, the light-emitting devices of Comparative Examples 2 to 7 including the single-layer emission layer were confirmed to have a similar or even lower lifespan than the lifespan of the light-emitting device of Comparative Example 1 having the GSP of less than 10 mV/nm for the single-layer emission layer.

TABLE 2

| | | | | | | | Light-emitting device | | | |
|---|---|---|---|---|---|---|---|---|---|---|
| | First emission | | | Second emission | | | characteristics | | | |
| | layer (10 nm) | | | layer (10 nm) | | | Driving | | | |
| | | | GSP₁ | | | GSP₂ | voltage | | | Lifespan |
| No. | Host | Dopant | (mV/nm) | Host | Dopant | (mV/nm) | (V) | CIEy | EQE | (T₉₅) |
| Comparative | BH12 | BD1 | 0 | BH13 | BD2 | 0 | 3.5 | 0.13 | 8% | 95% |
| Example | | | | | | | | | | |
| 8 | | | | | | | | | | |
| Comparative | BH13 | BD1 | 0 | BH12 | BD2 | 0 | 3.5 | 0.13 | 8% | 105% |
| Example | | | | | | | | | | |
| 9 | | | | | | | | | | |
| Comparative | BH11 | BD1 | 1 | BH14 | BD1 | 6 | 3.5 | 0.11 | 8% | 105% |
| Example | | | | | | | | | | |
| 10 | | | | | | | | | | |
| Comparative | BH11 | BD1 | 1 | BH14 | BD2 | 8 | 3.5 | 0.14 | 8% | 110% |
| Example | | | | | | | | | | |
| 11 | | | | | | | | | | |
| Comparative | BH11 | BD1 | 1 | CE1 | BD1 | 1 | 3.4 | 0.14 | 8% | 90% |
| Example | | | | | | | | | | |
| 12 | | | | | | | | | | |
| Comparative | BH11 | BD1 | 1 | CE2 | BD1 | 1 | 3.4 | 0.14 | 8% | 95% |
| Example | | | | | | | | | | |
| 13 | | | | | | | | | | |
| Comparative | BH11 | BD1 | 1 | CE3 | BD1 | 2 | 3.4 | 0.14 | 8% | 90% |
| Example | | | | | | | | | | |
| 14 | | | | | | | | | | |
| Comparative | BH11 | BD1 | 1 | CE4 | BD1 | 5 | 3.5 | 0.14 | 8% | 95% |
| Example | | | | | | | | | | |
| 15 | | | | | | | | | | |
| Comparative | BH11 | BD1 | 1 | CE5 | BD1 | 5 | 3.5 | 0.14 | 8% | 90% |
| Example | | | | | | | | | | |
| 16 | | | | | | | | | | |
| Comparative | BH21 | BD1 | 10 | BH11 | BD1 | 1 | 3.3 | 0.14 | 8% | 90% |
| Example | | | | | | | | | | |
| 17 | | | | | | | | | | |
| Comparative | BH21 | BD1 | 10 | BH21 | BD1 | 10 | 3.3 | 0.14 | 9% | 85% |
| Example | | | | | | | | | | |
| 18 | | | | | | | | | | |
| Example | BH11 | BD1 | 1 | BH21 | BD1 | 12 | 3.6 | 0.12 | 9% | 130% |
| 1 | | | | | | | | | | |
| Example | BH11 | BD1 | 1 | BH22 | BD1 | 23 | 3.7 | 0.10 | 7% | 140% |
| 2 | | | | | | | | | | |
| Example | BH11 | BD1 | 1 | BH23 | BD1 | 35 | 4.1 | 0.10 | 7% | 130% |
| 3 | | | | | | | | | | |
| Example | BH11 | BD1 | 1 | BH32 | BD1 | 30 | 4.0 | 0.10 | 8% | 125% |
| 4 | | | | | | | | | | |
| Example | BH11 | BD1 | 1 | BH21 | BD2 | 12 | 3.6 | 0.14 | 9% | 140% |
| 5 | | | | | | | | | | |
| Example | BH11 | BD1 | 1 | BH22 | BD2 | 23 | 3.7 | 0.15 | 8% | 150% |
| 6 | | | | | | | | | | |
| Example | BH11 | BD1 | 1 | BH23 | BD2 | 35 | 4.1 | 0.14 | 8% | 155% |
| 7 | | | | | | | | | | |

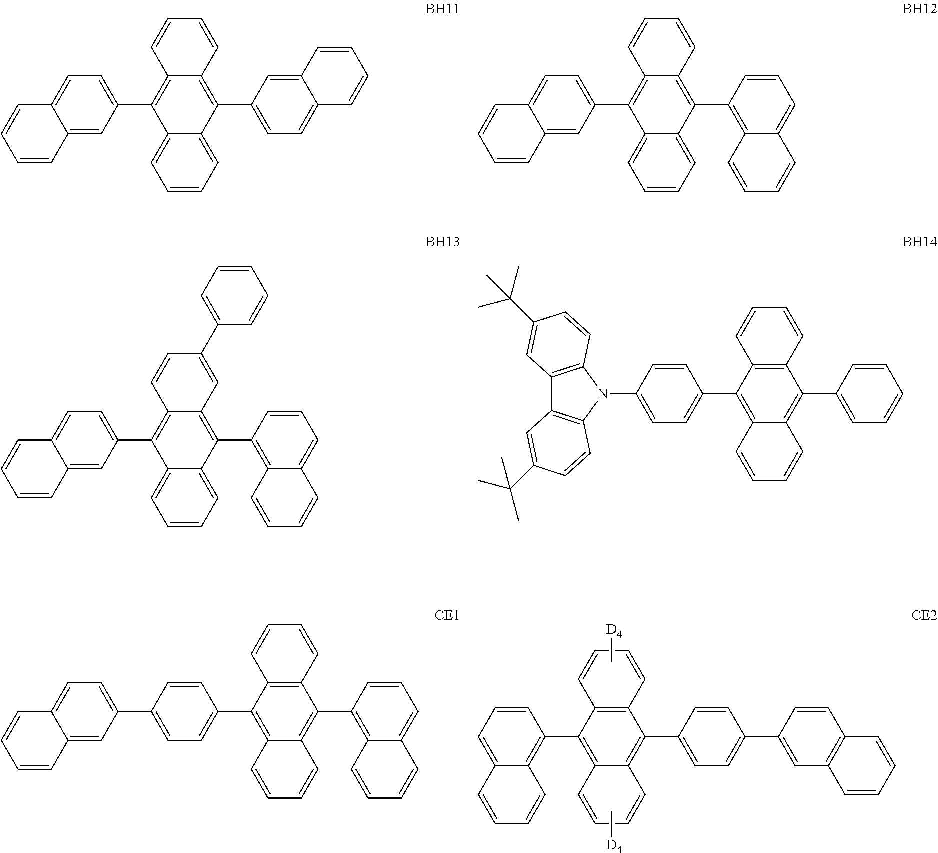

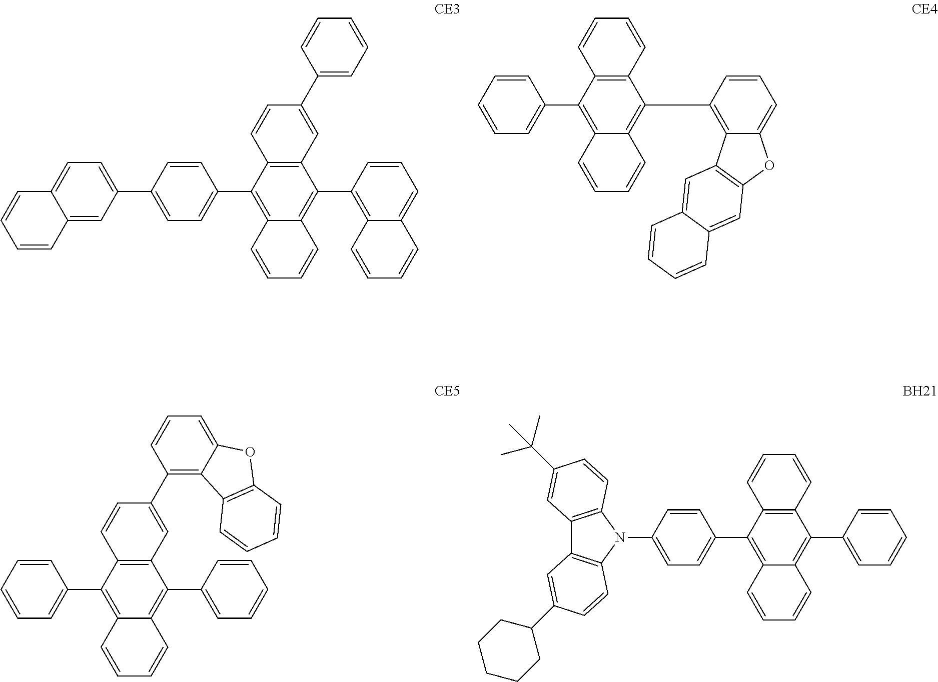

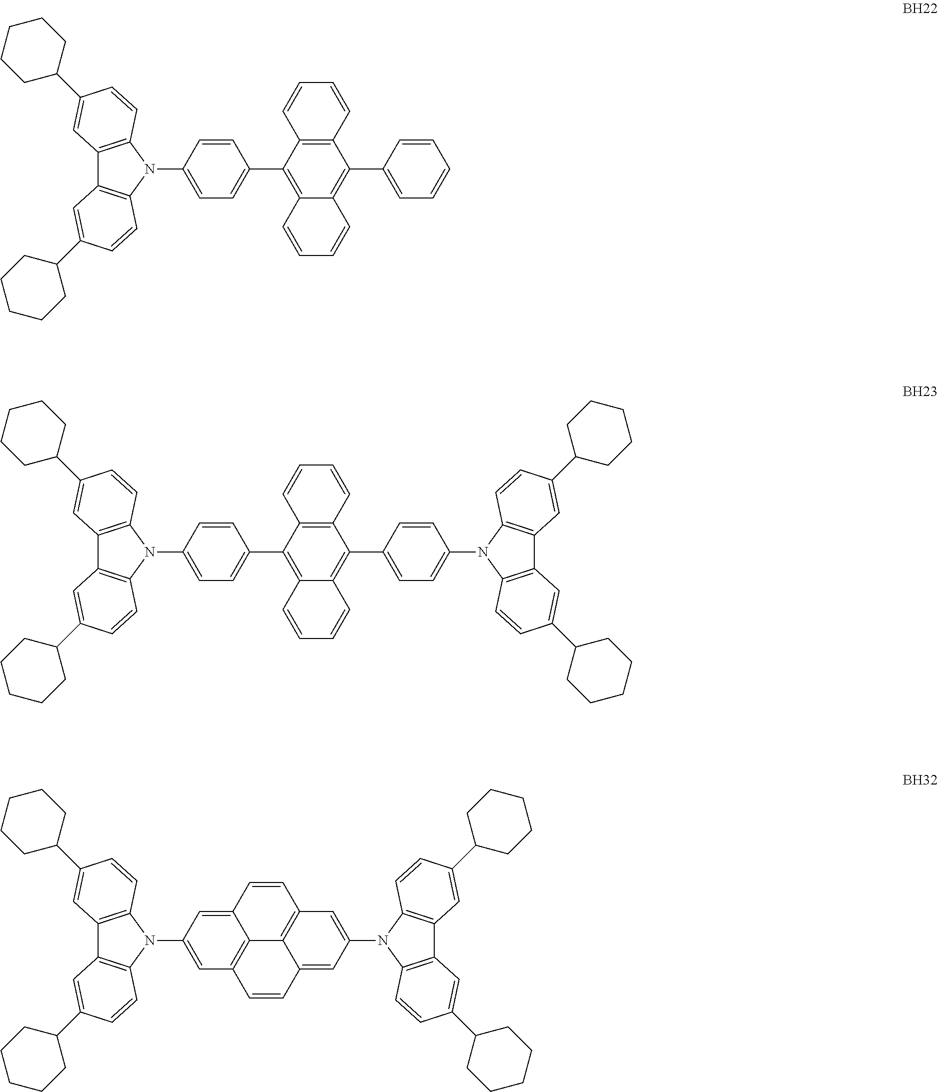 [SMILES: c1ccc(-c2c3ccccc3c(-c3ccc(-n4c5ccc(C6CCCCC6)cc5c5cc(C6CCCCC6)ccc54)cc3)c3ccccc23)cc1 ; c1ccc2c(-c3ccc(-n4c5ccc(C6CCCCC6)cc5c5cc(C6CCCCC6)ccc54)cc3)c3ccccc3c(-c3ccc(-n4c5ccc(C6CCCCC6)cc5c5cc(C6CCCCC6)ccc54)cc3)c2c1 ; c1cc2c(cc1C1CCCCC1)c1cc(C3CCCCC3)ccc1n2-c1cc2ccc3cc(-n4c5ccc(C6CCCCC6)cc5c5cc(C6CCCCC6)ccc54)cc4ccc(c1)c2c34]

Referring to Table 2, it was confirmed that, even if the emission layer had a two-layer structure, the light-emitting devices of Comparative Examples 8 to 16 having the GSP₂ of less than 10 mV/nm for the second emission layer had a similar or even lower lifespan than the light-emitting devices of Comparative Examples 1 to 7 as illustrated in Table 1.

It was confirmed that the light-emitting device of Comparative Example 17 in which the first emission layer had the GSP₁ of 10 mV/nm or more and the second emission layer had the GSP₂ of less than 10 mV/nm also had a similar or even lower lifespan than the light-emitting devices of the Comparative Examples described herein.

It was confirmed that, even if the GSP₂ for the second emission layer was 10 mV/nm or more, the light-emitting device of Comparative Example 18 having the GSP₁ of 10 mV/nm or more for the first emission layer also had a similar or even lower lifespan than the light-emitting device of the Comparative Examples described herein.

It was confirmed that the light-emitting devices of Examples 1 to 7 satisfying Condition 1 had the driving voltage, emission color coordinates, and EQE at levels similar to those of the light-emitting devices of the Comparative Examples described herein, but had an effectively improved lifespan. Referring to the Examples and the Comparative Examples above, it was confirmed that the light-emitting device in which the second emission layer had the GSP₂ of 10 mV/nm or more and the first emission layer had the GSP₁ of less than 10 mV/nm had an excellent lifespan.

According to the one or more embodiments, a light-emitting device satisfying Condition 1 may include a two-layer emission layer consisting of a first emission layer and a second emission layer, wherein the second emission layer may have a positive GSP and more specifically, a GSP of 10 mV/nm or more. Accordingly, an emission zone may be formed widely within the emission layer by preventing the emission zone from being formed narrowly at the interface between the emission layer and a hole transport region. The first emission layer may have a GSP of less than 10 mV/nm, thereby forming the emission zone effectively widely within the emission layer. In an example in which the emission zone is formed widely within the emission layer, deterioration may be prevented, and thus a light-emitting device having a long lifespan may be provided.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device comprising:
a first electrode;
a second electrode facing the first electrode; and
an interlayer arranged between the first electrode and the second electrode and comprising a first emission layer and a second emission layer that are sequentially stacked,
wherein the first emission layer and the second emission layer satisfy Condition 1:
$${GSP}_{1} < 10 mV / nm \leq {GSP}_{2} \qquad Condition 1$$
wherein, in Condition 1,
GSP₁ is a giant surface potential of the first emission layer, and
GSP₂ is a giant surface potential of the second emission layer.

2. The light-emitting device of claim 1, wherein:
the first emission layer is arranged between the first electrode and the second emission layer, and
the second emission layer is arranged between the first emission layer and the second electrode.

3. The light-emitting device of claim 1, wherein the first electrode is an anode.

4. The light-emitting device of claim 1, wherein the first emission layer and the second emission layer are in direct contact with each other.

5. The light-emitting device of claim 1, wherein:
the interlayer comprises a first stack adjacent to the first electrode and a second stack adjacent to the second electrode, and
at least one of the first stack or the second stack comprises the first emission layer and the second emission layer that satisfy Condition 1.

6. The light-emitting device of claim 1, wherein the interlayer further comprises:
a hole transport region arranged between the first electrode and the first emission layer; and
an electron transport region arranged between the second emission layer and the second electrode.

7. The light-emitting device of claim 1, wherein at least one of the first emission layer or the second emission layer emits blue light.

8. The light-emitting device of claim 1, wherein at least one of the first emission layer or the second emission layer emits fluorescence or delayed fluorescence.

9. The light-emitting device of claim 1, wherein an absolute value of GSP₁ in Condition 1 is less than 10 mV/nm.

10. The light-emitting device of claim 1, wherein at least one of the first emission layer or the second emission layer comprises at least one type of dopant which contains boron.

11. The light-emitting device of claim 10, wherein:
the first emission layer comprises a first dopant containing boron,
the second emission layer comprises a second dopant containing boron, and
the first dopant and the second dopant are identical to or different from each other.

12. The light-emitting device of claim 1, wherein at least one of the first emission layer or the second emission layer comprises a host comprising a condensed group in which 3 to 5 benzene groups are condensed with each other.

13. The light-emitting device of claim 12, wherein:
the first emission layer comprises a first host comprising the condensed group,
the second emission layer comprises a second host comprising the condensed group, and
the first host and the second host are different from each other.

14. The light-emitting device of claim 12, wherein the host further comprises a carbazole group linked to the condensed group.

15. The light-emitting device of claim 12, wherein the host further comprises a C₃-C₂₀ cycloalkyl group that is linked to the condensed group and is unsubstituted or substituted with at least one R₁₀ₐ.

16. The light-emitting device of claim 1, wherein:
the first emission layer and the second emission layer satisfy Condition 1-1:
$$0 mV / nm \leq {GSP}_{1} < 10 mV / nm \leq {GSP}_{2} \qquad Condition 1 ‐ 1$$
wherein, in Condition 1-1, GSP₁ and GSP₂ are each the same as described in connection with Condition 1.

17. A display apparatus comprising:
a light-emitting device comprising a first electrode, a second electrode facing the first electrode, and an interlayer arranged between the first electrode and the second electrode and comprising a first emission layer and a second layer that are sequentially stacked; and
a thin-film transistor electrically connected to the first electrode,
wherein the first emission layer and the second emission layer satisfy Condition 1:
$${GSP}_{1} < 10 mV / nm \leq {GSP}_{2} \qquad Condition 1$$
wherein, in Condition 1,
GSP₁ is a giant surface potential per thickness of the first emission layer, and
GSP₂ is a giant surface potential per thickness of the second emission layer.

18. The display apparatus of claim 17, further comprising a color filter, a color conversion layer, a touch screen layer, a polarizing layer, or any combination thereof.

19. An electronic apparatus comprising:
a display apparatus comprising:
a light-emitting device comprising a first electrode, a second electrode facing the first electrode, and an interlayer arranged between the first electrode and the second electrode and comprising a first emission layer and a second emission layer that are sequentially stacked; and
a thin-film transistor electrically connected to the first electrode,
wherein the first emission layer and the second emission layer satisfy Condition 1:
$${GSP}_{1} < 10 mV / nm \leq {GSP}_{2} \qquad Condition 1$$
wherein, in Condition 1,
GSP₁ is a giant surface potential per thickness of the first emission layer, and GSP₂ is a giant surface potential per thickness of the second emission layer; and
a processor which transmits a signal to the display apparatus.

20. The electronic apparatus of claim 19, wherein the electronic apparatus is one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, smart glasses, a head-mounted display, a smart watch, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle gauge, a center information display (CID) in a vehicle, a head-up display in a vehicle, a room mirror display, a video wall with multiple displays tiled together, a theater or stadium screen, a phototherapy device, and a signboard.
